(19) United States
(12) Patent Application Publication
(10) Pub. No.: US 2015/0348633 A1
(43) Pub. Date: Dec. 3, 2015

(54) NONVOLATILE MEMORY DEVICES AND METHODS OF PROGRAMMING NONVOLATILE MEMORY DEVICES

(71) Applicant: SAMSUNG ELECTRONICS CO., LTD., Suwon-si (KR)

(72) Inventors: YOUNGSUN SONG, Hwaseong-si (KR); BOGEUN KIM, Suwon-si (KR); OHSUK KWON, Seoul (KR); KITAE PARK, SEONGNAM-SI (KR); SEUNG-HWAN SHIN, Seongnam-si (KR); SANGYONG YOON, Seoul (KR); MOOSUNG KIM, Yongin-si (KR); HYUNJUN YOON, Seongnam-si (KR)

(21) Appl. No.: 14/747,786

(22) Filed: Jun. 23, 2015

Related U.S. Application Data
(63) Continuation-in-part of application No. 14/316,023, filed on Jun. 26, 2014, now Pat. No. 9,064,582.
Application No. 14/316,023 is a continuation of application No. 13/477,161, filed on May 22, 2012, now Pat. No. 8,773,908.
Application No. 13/477,161 is a continuation-in-part of application No. 14/726,927, filed on Jun. 1, 2015.
Application No. 14/726,927 is a continuation of application No. 13/841,503, filed on Mar. 15, 2013, now Pat. No. 9,076,534.
Application No. 13/841,503 is a continuation of application No. 12/963,867, filed on Dec. 9, 2010, now Pat. No. 8,411,502.

(30) Foreign Application Priority Data
Feb. 11, 2010 (KR) 10-2010-0012894
Jun. 8, 2011 (KR) 10-2011-0055134

(51) Int. Cl. G11C 16/12; G11C 16/34

(52) U.S. Cl. CPC G11C 16/12; G11C 16/3459

(57) ABSTRACT

A nonvolatile memory device includes a memory cell array, a page buffer unit which output a verify-read result, a reference current generating unit which generates a reference current signal, a page buffer decoding unit which outputs currents according to the verify-read result. The nonvolatile memory device further includes an analog bit counting unit which counts the currents, a digital adding unit which calculates an accumulated sum of the counting result, a pass/fail checking unit which outputs a pass signal or fail signal according to the calculation result, and a control unit controlling a program operation.

### CROSS-REFERENCE TO RELATED APPLICATIONS

This U.S. non-provisional patent application is a continuation-in-part of U.S. Pat. No. 9,064,582 filed on Jun. 26, 2014, which is a continuation application of U.S. Pat. No. 8,773,908 filed May 22, 2012, which claims priority under 35 U.S.C. §119 to Korean Patent Application No. 10-2011-0055134, filed on Jun. 8, 2011, in the Korean Intellectual Property Office (KIPO), the entire contents of which are hereby incorporated by reference. This U.S. non-provisional patent application is a continuation-in-part of U.S. patent application Ser. No. 14/726,927 filed on Jun. 1, 2015, which is a continuation application of U.S. Pat. No. 9,076,534 filed on Mar. 3, 2013, which is a continuation application of U.S. Pat. No. 8,411,502 filed on Dec. 9, 2010, which claims priority under 35 U.S.C. §119 to Korean Patent Application No. 10-2010-0012894, filed on Feb. 11, 2010, in the Korean Intellectual Property Office (KIPO), the entire contents of which are hereby incorporated by reference.

### BACKGROUND

Example embodiments relate to semiconductor memory devices, and more particularly, to nonvolatile memory devices and to methods of programming nonvolatile memory devices.

A semiconductor memory device is a memory device which is fabricated at least in part from semiconductors such as silicon (Si), germanium (Ge), gallium arsenide (GaAs), indium phosphide (InP), and the like. Semiconductor memory devices are generally classified as either volatile memory devices or nonvolatile memory devices.

Volatile memory devices are characterized by the loss of stored data when a power supply is interrupted. Examples of volatile memory devices include certain types of random access memory (RAM) such as static RAM (SRAM), dynamic RAM (DRAM), synchronous DRAM (SDRAM), and the like. On the other hand, nonvolatile memory devices are characterized by the retention of stored data when a power supply is interrupted. Examples of nonvolatile memory devices include read only memory (ROM), programmable ROM (PROM), electrically programmable ROM (EPROM), electrically erasable and programmable ROM (EEPROM), flash memory devices (including NOR type and NAND type), phase-change RAM (PRAM), magnetic RAM (MRAM), resistive RAM (RRAM), ferroelectric RAM (FRAM), and the like.

### SUMMARY

In one embodiment, the nonvolatile memory device includes a memory cell array, and a page buffer unit connected to the memory cell array via bit lines and configured to store a verify-read result during a verify read, to divide the verify-read result into a plurality of groups, and to sequentially output the plurality of groups of the verify-read result. The nonvolatile memory device further includes a reference current generating unit configured to generate a reference current signal, a page buffer decoding unit configured to output currents sequentially according to a number of fail bits of each of the plurality of groups based on the reference current signal, an analog bit counting unit configured to count the currents sequentially output from the page buffer decoding unit based on the reference current signal, a digital adding unit configured to calculate an accumulated sum of the counting result of the analog bit counting unit, a pass/fail checking unit configured to output a pass signal or fail signal according to the calculation result of the digital adding unit, and a control unit configured to control a program operation.

### BRIEF DESCRIPTION OF THE FIGURES

Example embodiments will become understood from the detailed description that follows, with reference to accompanying drawings which represent non-limiting, example embodiments. In the drawings:

FIG. 1 is a block diagram illustrating a nonvolatile memory device according to a first embodiment of the inventive concepts;

FIG. 2 is a schematic diagram illustrating a memory cell array according to the inventive concepts;

FIG. 3 illustrates an embodiment of a page buffer unit according to the inventive concepts;

FIG. 4 is a circuit diagram illustrating a first embodiment of a page buffer decoding unit according to an embodiment of the inventive concepts;

FIG. 5 is a circuit diagram illustrating a first embodiment of a current generating unit according to an embodiment of the inventive concepts;

FIG. 6 is a circuit diagram illustrating a first embodiment of an analog bit counting unit according to the inventive concepts;

FIG. 7 is a block diagram illustrating a digital adding unit according to an embodiment of the inventive concepts;

FIG. 8 is a block diagram illustrating an embodiment of a pass/fail checking unit according to the inventive concepts;

FIG. 9 is a schematic diagram illustrating a portion of the page buffer decoding unit and the analog bit counting unit according to an embodiment of the inventive concepts;

FIG. 10 is a timing diagram illustrating a portion of control signals of the nonvolatile memory device according to an embodiment of the inventive concepts;

FIG. 11 illustrates a first embodiment of the sizes of s sink transistors and operations of the page buffer decoding unit and analog bit counting unit according to the inventive concepts;

FIG. 12 illustrates a second embodiment of the sizes of sink transistors and operations of the page buffer decoding unit and analog bit counting unit according to the inventive concepts;

FIG. 13 illustrates an embodiment of sink transistors providing a multi resolution;

FIG. 14 is a timing diagram illustrating an first embodiment of counting a number of the program-failed memory cells;

FIG. 15 is a timing diagram illustrating a second embodiment of counting a number of the program-failed memory cells;

FIG. 16 is a flow chart illustrating a first embodiment of a programming method according to the inventive concepts;

FIG. 17 is a flow chart illustrating an embodiment of generating a current and decoding the generated current into a digital value shown in the step S140 of FIG. 16;

FIG. 18 is a timing diagram illustrating a first example of the program method of the inventive concepts;

FIG. 19 is a timing diagram illustrating a second example of the program method of the inventive concepts;

FIG. 20 is a flow chart illustrating an example of an operating method of the current generating unit 150 and control unit 190 shown in FIG. 1;

FIG. 21 is a circuit diagram illustrating a second embodiment of the current generating unit according to the inventive concepts;

FIG. 22 is a circuit diagram illustrating a second embodiment of the analog bit counting unit according to the inventive concepts;

FIG. 23 is a circuit diagram illustrating a third embodiment of the analog bit counting unit according to the inventive concepts;

FIG. 24 is a circuit diagram illustrating a fourth embodiment of the analog bit counting unit according to the inventive concepts;

FIG. 25 is a flow chart illustrating a second embodiment of the programming method according to the inventive concepts;

FIG. 26 is a flow chart illustrating a third embodiment of the programming method according to the inventive concepts;

FIG. 28 illustrates an embodiment of the page buffer decoding unit shown in FIG. 27;

FIG. 29 is a block diagram illustrating an embodiment of the ripple and carry calculator shown in FIG. 28;

FIG. 30 is a diagram illustrating a first embodiment of logic states programmed to the memory cells according to inventive concepts;

FIG. 31 is a flow chart illustrating a first embodiment of a verification method according to the inventive concepts;

FIG. 32 is a diagram illustrating a second embodiment of logic states programmed to the memory cells according to inventive concepts;

FIG. 33 is a flow chart illustrating a second embodiment of the verification method according to the inventive concepts;

FIG. 34 is a block diagram illustrating a first embodiment of a counter according to the inventive concepts;

FIG. 35 is a flow chart illustrating an embodiment of an operating method of the counter shown in FIG. 34;

FIG. 36 is a block diagram illustrating a second embodiment of a counter according to the inventive concepts;

FIG. 37 is a flow chart illustrating an embodiment of an operating method of the counter shown in FIG. 36;

FIG. 38 is a block diagram illustrating a third embodiment of the counter according to the inventive concepts;

FIG. 39 is a flow chart illustrating an embodiment of an operating method of the counter 400 shown in FIG. 38;

FIG. 40 is a block diagram illustrating memory systems according to example embodiments of the inventive concepts;

FIG. 41 is a block diagram illustrating applications of memory systems shown in FIG. 40; and

FIG. 42 is a block diagram illustrating computing systems including memory systems illustrated in FIG. 41.

FIG. 43 is a block diagram illustrating a flash memory device according to an embodiment of the inventive concept.

FIG. 44 is a diagram illustrating a flash memory device comprising a memory cell array with memory blocks having an all bitline architecture or an odd-even bitline architecture.

FIGS. 45A through 45C are diagrams illustrating threshold voltage distributions of memory cells storing different numbers of bits.

FIG. 46 is a diagram illustrating a series of programming pulses used to program memory cells connected to a selected wordline.

FIGS. 47A through 47C are threshold voltage diagrams illustrating a method of programming a flash memory device according to an embodiment of the inventive concept.

FIGS. 48 and 49 are diagrams illustrating a method of verifying a programming operation of FIG. 47A.

FIGS. 50 and 51 are diagrams illustrating a method of verifying a programming operation of FIG. 47B.

FIGS. 52 and 53 are diagrams illustrating a method of verifying a programming operation of FIG. 47C.

FIGS. 54A through 54C are voltage diagrams showing program voltages and verification voltages for the methods of FIGS. 47A through 47C.

FIG. 55 is a diagram illustrating a method of programming a flash memory device according to another embodiment of the inventive concept.

FIG. 56 is a diagram illustrating a method of programming a flash memory device according to another embodiment of the inventive concept.

FIG. 57 is a diagram illustrating a method of programming a flash memory device according to another embodiment of the inventive concept.

FIG. 58 is a flowchart illustrating a method of programming a flash memory device according to another embodiment of the inventive concept.

FIG. 59 is a threshold voltage diagram for memory cells storing multi-bit data.

FIG. 60 is a diagram illustrating a verification scheme used in the method of FIG. 58 according to an embodiment of the inventive concept.

FIG. 61 is a diagram illustrating a verification scheme used in the method of FIG. 58 according to another embodiment of the inventive concept.

FIG. 62 is a flowchart illustrating a method of programming a flash memory device according to another embodiment of the inventive concept.

FIG. 63 is a diagram illustrating a verification scheme used in the method of FIG. 62 according to an embodiment of the inventive concept.

FIG. 64 is a block diagram illustrating a flash memory device capable of performing the method of FIG. 62.

FIGS. 65A and 65B are flowcharts illustrating a method of programming a flash memory device according to another embodiment of the inventive concept.

FIGS. 66A and 66B are flowcharts illustrating a method of programming a flash memory device according to another embodiment of the inventive concept.

FIGS. 67A and 67B are flowcharts illustrating a method of programming a flash memory device according to another embodiment of the inventive concept.

FIGS. 68A and 68B are flowcharts illustrating a method of programming a flash memory device according to another embodiment of the inventive concept.

FIG. 69 is a flowchart illustrating a method of programming a flash memory device according to yet another embodiment of the inventive concept.

FIG. 70 is a diagram illustrating a verification scheme used in the method of FIG. 69 according to an embodiment of the inventive concept.

FIG. 71 is a flowchart illustrating a method of programming a flash memory device according to yet another embodiment of the inventive concept.

FIG. 72 is a flowchart illustrating a method of programming a flash memory device according to yet another embodiment of the inventive concept.

FIG. 73 is a diagram illustrating a verification scheme used in the method of FIG. 72 according to an embodiment of the inventive concept.

FIG. 74 is a flowchart illustrating a method of programming a flash memory device according to yet another embodiment of the inventive concept.

FIG. 75 is a block diagram illustrating an integrated circuit card comprising a flash memory device according to an embodiment of the inventive concept.

FIG. 76 is a block diagram illustrating a computing system comprising a flash memory device according to an embodiment of the inventive concept.

FIG. 77 is a block diagram illustrating a memory controller of the computing system of FIG. 76 according to an embodiment of the inventive concept.

It should be noted that these figures are intended to illustrate the general characteristics of methods, structure and/or materials utilized in certain example embodiments and to supplement the written description provided below. These drawings are not, however, drawn to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EMBODIMENTS

Example embodiments will now be described more fully with reference to the accompanying figures, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the figures, the thicknesses of layers and regions may be exaggerated for clarity. Like reference numerals in the figures may denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers may indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein may have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

The term “selected bit line” or “selected bit lines” is used to indicate a bit line or bit lines, connected with a cell transistor to be programmed or read, among a plurality of bit lines. The term “unselected bit line” or “unselected bit lines” is used to indicate a bit line or bit lines, connected with a cell transistor to be program-inhibited or read-inhibited, among a plurality of bit lines.

The term “selected string selection line” is used to indicate a string selection line connected with a cell string, which includes a cell transistor to be programmed or read, among a plurality of string selection lines. The term “unselected string selection line” or “unselected string selection lines” is used to indicate a remaining string selection line or remaining string selection lines other than the selected string selection line among a plurality of string selection lines. The term “selected string selection transistors” is used to indicate string selection transistors connected with a selected string selection line. The term “unselected string selection transistors” is used to indicate string selection transistors connected with an unselected string selection line or unselected string selection lines.

The term “selected ground selection line” is used to indicate a ground selection line connected with a cell string, which includes a cell transistor to be programmed or read, among a plurality of ground selection lines. The term “unselected ground selection line” is used to indicate a remaining ground selection line or remaining ground selection lines other than the selected ground selection line among a plurality of ground selection lines. The term “selected ground selection transistors” is used to indicate ground selection transistors connected with a selected ground selection line. The term “unselected ground selection transistors” misused to indicate ground selection transistors connected with an unselected ground selection line or unselected ground selection lines.

The term “unselected word line” is used to indicate a word line, connected with a cell transistor to be programmed or read, among a plurality of word lines. The term “unselected word line” or “unselected word lines” is used to indicate a remaining word lines or remaining word lines other than a selected word line among a plurality of word lines. The term “selected memory cell” or “selected memory cells” is used to designate memory cells to be programmed or read among a plurality of memory cells. The term “unselected memory cell” or “unselected memory cells” is used to indicate a remaining memory cell or remaining memory cells other than a selected memory cell or selected memory cells among a plurality of memory cells.

The term “page” is used to indicate a minimum basis of memory cells for a reading and writing. For example, when k bits are written into a memory cell, k page(s) may be written to the memory cells of a same word line. In the case where k is two (multi-level cells), each memory cell may store a least significant bit and a most significant bit of data. In the case where k is three or more (multi-level cells), each memory cell may store a least significant bit, one or more central significant bits, and a most significant bit of data.

The term “least significant page” is used to indicate a page including least significant bits of data of multi-level cells. The term “central significant page” may be used to indicate a page including central significant bits of data of multi-level cells. The term “most significant page” may be used to indicate a page including most significant bits of data of multi-level cells.

Embodiments of the inventive concepts may be described referring to NAND flash memory devices. However, the inventive concepts are not limited to NAND flash memory devices. The inventive concepts may be applied to various nonvolatile memory devices, such as EEPROM, NOR flash memory devices, PRAM, MMRAM, RRAM and FRAM.

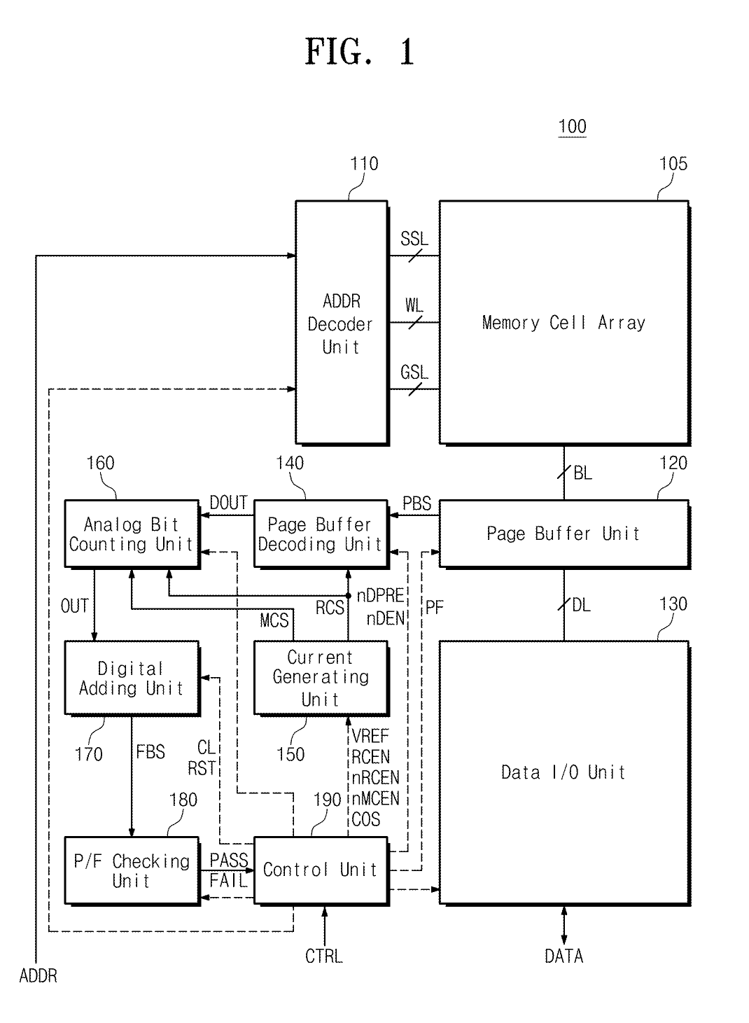

FIG. 1 is a block diagram illustrating a nonvolatile memory device 100 according to a first embodiment of the inventive concepts. Referring to FIG. 1, the nonvolatile memory device 100 of this example includes a memory cell array 105, an address decoding unit 110, a page buffer unit 120, a data input/output unit 130, a page buffer decoding unit 140, a current generating unit 150, an analog bit counting unit 160, a digital adding unit, a pass/fail checking unit 180 and a control unit 190. The memory cell array 105 includes a plurality of memory cells. For example, the memory cell array 105 may include a plurality of cell strings which may be arranged in a row direction and a column direction. Each of the plurality of memory cells of the memory cell array 105 may store one or more bits of data.

The address decoding unit 110 may be coupled with the memory cell array 105 via word lines WL, string selection lines SSL, and ground selection lines GSL. The address decoding unit 110 may be configured to operate responsive to the control of the control unit 190. The address decoding unit 110 may receive an address ADDR from an external device. The address decoding unit 110 may be configured to decode the received address.

The page buffer unit 120 may be coupled with the memory cell array 105 via bit lines BL and coupled with the data input/output unit 130 via data lines DL. The page buffer unit 130 may operate responsive to the control of the control unit 190.

The page buffer unit 120 may receive data from the data input/output unit 130 to write it in the memory cell array 105. The page buffer unit 120 may read data from the memory cell array 105 to output it to the data input/output unit 130. The page buffer unit 120 may read data from a first storage area of the memory cell array 105 to store it in a second storage area thereof. The page buffer unit 120 may perform a copy-back operation.

The page buffer unit 120 may output a page buffer signal PBS to the page buffer decoding unit 140. The page buffer unit 120 may output information of a verify-read result as the page buffer signal PBS responsive to a transmission signal PF from the control unit 190. The page buffer unit 120 may output the verify-read result through a plurality of iterations in response to the transmission signal PF.

The data input/output circuit 130 may be coupled with the page buffer unit 120 via the data lines DL. The data input/output unit 130 may operate responsive to the control unit 190. The data input/output unit 130 may exchange data with the external device. The data input/output circuit 130 may receive data from the external device to transfer it to the page buffer unit 120. The data input/output unit 130 may receive data from the page buffer unit 120 to transfer it to the external device.

The page buffer decoding unit 140 may operate responsive to a decoder enable signal nDEN and a decoder precharge signal nDPRE from the control unit 190. The page buffer decoding unit 140 may receive the page buffer signal PBS from the page buffer unit 120 and receive a reference current signal RCS and a maximum current signal MCS from the current generating unit 150. The page buffer decoding unit 140 may detect fail bits from the received page buffer signal PBS to output the detection result as a decoder output signal DOUT.

The page buffer decoding unit 140 may detect a number of fail bits from the page buffer signal PBS. The page buffer decoding unit 140 may output a current which has an amount corresponding to multiples of reference current RC as the decoder output signal DOUT. The multiples may correspond to the number of the detected fail bits. When the page buffer signal PBS indicates two fail bits, the page buffer decoding unit 140 may output a current which has an amount corresponding to two times of the reference current RC as the decoder output signal DOUT. The reference current RC may be current flowing through a normal transistor when the reference current signal RCS is applied to a gate of the normal transistor.

The current generating unit 150 may operate responsive to a reference voltage VREF, a reference current enable signal RCEN, a maximum current enable signal nMCEN and a current option signal COS from the control unit 190. The current generating unit 150 may generate the reference current signal RCS in response to the reference current enable signal RCEN, the reference voltage VREF and the inverted reference current enable signal nRCEN. The current generating unit 150 may generate the maximum current signal MCS in response to the reference current signal RCS and the maximum current enable signal nMCEN.

The reference current signal RCS may be provided to the page buffer decoding unit 140 and the analog bit counting unit 160. The reference current signal RCS may correspond to a state of the decoding output signal DOUT when the page buffer signal PBS indicates a single fail bit. The maximum current signal MCS may be transferred to the analog bit counting unit 160. The maximum current signal MCS may correspond to a maximum amount of a current flowing within the analog bit counting unit 160.

The analog bit counting unit 160 may operate responsive to a load enable signal LEN and a count enable signal CEN from the control unit 190. The analog bit counting unit 160 may receive the decoding output signal DOUT from the page buffer decoding unit 140 and the reference current signal RCS and the maximum current signal MCS from the current generating unit 150. The analog bit counting unit 160 may count the decoding output signal DOUT (e.g., analog count) and output the counting result OUT.

The analog bit counting unit 160 may count the decoding output signal DOUT using the reference current signal RCS. For example, the analog bit counting unit 160 may count at what times is the decoding output signal DOUT from the reference current RC using the reference current signal RCS.

The analog bit counting unit 160 may control an amount of maximum current in response to the maximum current signal MCS. For example, the amount of the maximum current may be an amount of current flowing through a normal transistor when the maximum current signal MCS is applied to its gate.

The digital adding unit 190 may operate responsive to a latch signal CL and a reset signal RST from the control unit 190. The digital adding unit 170 may receive the counting result OUT from the analog bit counting unit. The digital adding unit 170 may digitalize the counting result OUT and store the digitalized result. The digital adding unit 170 may digitalize a plurality of output signals from the analog bit counting unit 160 and calculate an accumulated sum of the digitalized values. The stored value may be output as a fail bit signal FBS. The fail bit signal FBS may indicate a number of fail bits of the verify-read result. The fail bit signal FBS may be a digital value.

The pass/fail checking unit 180 may operate responsive to the control unit 190. The pass/fail checking unit 180 may receive the fail bit signal FBS from the digital adding unit 170. The pass/fail checking unit 180 may output a pass signal PASS or a fail signal FAIL based on the received fail bit signal FBS. When the fail bit signal FBS indicates a value less than or equal to a specific value, the pass/fail checking unit 180 may output the pass signal PASS. When the fail bit signal FBS indicates a value more than the specific value, the pass/fail checking unit 180 may output the fail signal FAIL.

The control unit 190 may control various operations of the nonvolatile memory device 100. For example, signal paths from the control unit 190 are shown as broken lines. The control unit 190 may operate responsive to control signals CTRL from an external device. The control unit 190 may receive the pass signal PASS or the fail signal FAIL from the pass/fail checking unit 180. When the pass signal PASS is received, the control unit 190 may determine a program pass. When the fail signal FAIL is received, the control unit 190 may determine a program fail.

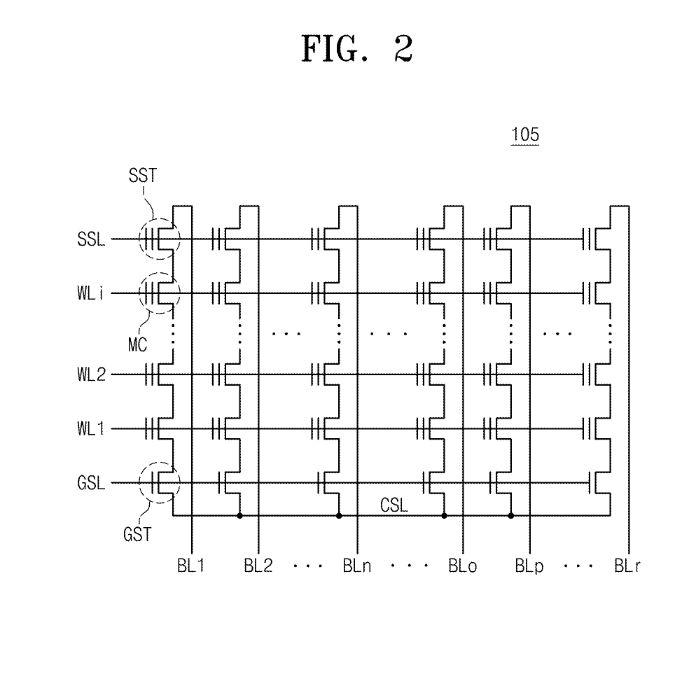

FIG. 2 is a schematic diagram illustrating an example of the memory cell array 105 according to the inventive concepts. Referring to FIG. 2, a plurality of memory cells MCS may be coupled in series to constitute a plurality of strings. String select transistors SST and ground select transistors GST may be coupled with each node of the plurality of strings. A string select line SSL may be coupled with gates of the string select transistors SST. A ground select line may be coupled with gate of ground select transistors GST. A common source line may be coupled with of the ground select transistors GST. Word lines WL1 through WLi may be coupled with control gates of the plurality of memory cells MCS arranged in a direction of columns respectively. Bit lines BL1 through BLr may be coupled with the string select transistors SST.

During the verify-read, a power supply voltage VCC may be charged to the bit lines BL1 through BLr. A verify voltage may be applied to a select word line, and a high voltage may be applied to the string select line SSL, the ground select line GSL and unselected word lines. A ground voltage VSS may be applied to the common source line CSL. Memory cells coupled with the unselected word lines, the string select transistors SST and the ground select transistors may be turned on. Memory cells coupled with the selected word line may be turned on or off.

When threshold voltages of the selected memory cells are higher than the verify voltage, the selected memory cells may be turned on. Thus, bit lines coupled with the selected memory cells may be floated and maintain the charged power supply voltage VCC. When the threshold voltages of the selected memory cells are lower than the verify voltage, the selected memory cells may be turned on. Thus, the bit lines coupled with the selected memory cells may be grounded via the common source line CSL.

Bit lines coupled with program-passed memory cells may have the ground voltage VSS to indicate logic low. Bit lines coupled with program-failed memory cells may have the power supply voltage VCC to indicate logic high.

Example voltages (or logic states) of the bit lines BL1 through BLr are shown in following Table 1.

TABLE 1

| | Program pass | Program fail |
|---|---|---|
| Bit line | High | Low |

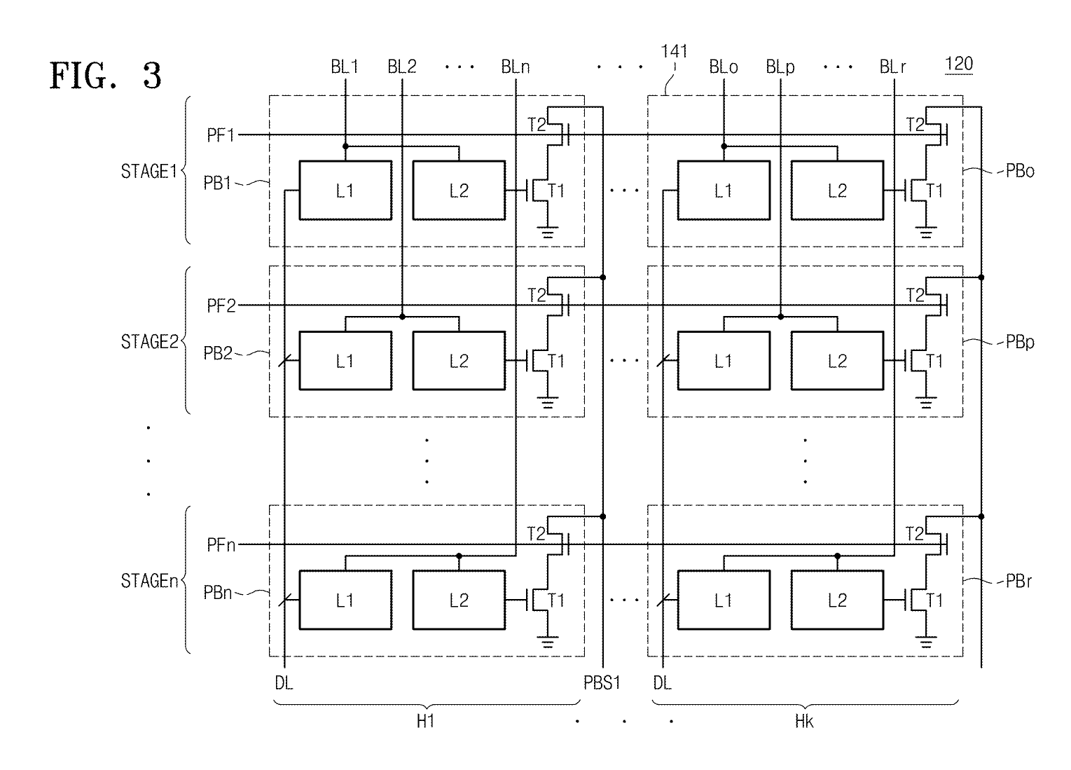

FIG. 3 illustrates an embodiment of the page buffer unit 120 according to the inventive concepts. Referring to FIGS. 1 and 3, the page buffer unit 120 includes a plurality of page buffers PB1 through PBr. The plurality of page buffers PB1 through PBr may constitute a plurality of hierarchical structures H1 through Hk. The first through nth page buffers PB1 through PBn may constitute the first hierarchical structure H1. The oth through rth page buffers may constitute the kth hierarchical structure Hk. A number of the page buffers in each hierarchical structure may be the same.

The page buffers in each hierarchical structure may be coupled each other. For example, the first through nth page buffers PB1 through PBn may be coupled by a WIRED-OR structure to output the first page buffer signal PBS1 in a first hierarchical structure H1. The oth through rth page buffers PBo through PBr may be coupled by a WIRED-OR structure to output the kth page buffer signal PBSk.

Each of the page buffers PB1 through PBr may include a first latch L1, a second latch L2, a first transistor T1 and a second transistor L2. The first and second latches L1 and L2 may be coupled with a corresponding one of the bit lines BL1 through BLr. For example, the first and second latches L1 and L2 of the first page buffer PB1 may be coupled with the first bit line BL1. The first and second latches L1 and L2 of the nth page buffer PBn may be coupled with the nth bit line BLn. The first and second latches L1 and L2 of the rth page buffer PBr may be coupled with the rth bit lines BLr.

The first latches L1 may be data latches storing data to be programmed, the read result and the verify-read result. The first latches L1 may be coupled with the data lines DL.

The second latches L2 may operate independently from the first latches L1. The second latches L2 may store the verify-read result. The second latches L2 may invert stored values and transfer them to gates of the first transistors T1.

The first transistors T1 may operate responsive to values stored in the second latches L2. One node of the first transistors may be supplied with the ground voltage VSS, and another node of the first transistors may be coupled with the second transistors T2.

The second transistors T2 may operate responsive to transfer signals PF1 through PFn. One node of the second transistors T2 may be coupled with the first transistors T1, and another node of the second transistors T2 may output the first through kth page buffer signals PBS1 through PBSk.

When the verify-read is executed, the verify-read result is stored in the page buffers PB1 through PBr. According to the verify-read result, the page buffers PB1 through PBr may output the first through kth page buffer signals PBS1 through PBSk. For example, the page buffers PB1 through PBr may output the first through kth page buffer signals PBS1 through PBSk sequentially in an order of first stages STAGE1 through nth stages STAGEn.

When the first transfer signal PF1 is activated, the page buffers PB1 and PBo of the first stage STAGE1 may output the first through kth page buffer signals PBS1 through PBSk. When the nth transfer signal PFn is activated, the page buffers PBn and PBr of the nth stage STAGEn may output the first through kth page buffer signals PBS1 through PBSk.

As shown in Table 1, a bit line coupled with a program-failed memory cell indicates logic low, and a bit line coupled with a program-failed memory cell indicates logic high. Logic values of the bit lines BL1 through BLr may be stored in the page buffers PB1 through PBr.

The second latch L2 of the first page buffer PB1 may output inverted value of the stored value to the gate of the first transistor T1. When a memory cell corresponding to the first page buffer PB1 is the program-failed memory cell, the second latch L2 may output logic high to the gate of the first transistor T1. That is, the first transistor T1 is turned on. When the memory cell corresponding to the first page buffer PB1 is the program-passed memory cell, the second latch L2 may output logic low to the gate of the first transistor T1. That is, the first transistor T1 is turned off.

When the first page buffer PB1 corresponds to the program-failed memory cell and the first transfer signal PF1 is activated, the first page buffer PB1 may output the ground voltage (or logic low) as the first page buffer signal PBS1. When the first page buffer PB1 corresponds to the program-passed memory cell and the first transfer signal PF1 is activated, the first page buffer PB1 may float the first page buffer signal PBS1. The first page buffer PB1 may output the ground voltage (or logic low) as the first page buffer signal PBS1 or float the first page buffer signal PBS1 according to whether the memory cell corresponding to the first page buffer PB1 is program-passed or program-failed.

Other page buffers PB2 through PBr may operate in an identical manner with the first page buffer PB1. Examples of the page buffer signals PBS1 through PBSk according to the verify-read result are shown in following Table 2.

TABLE 2

| | Program pass | Program fail |
|---|---|---|
| Bit line | High | Low |
| Page buffer signal | Float | Low (VSS) |

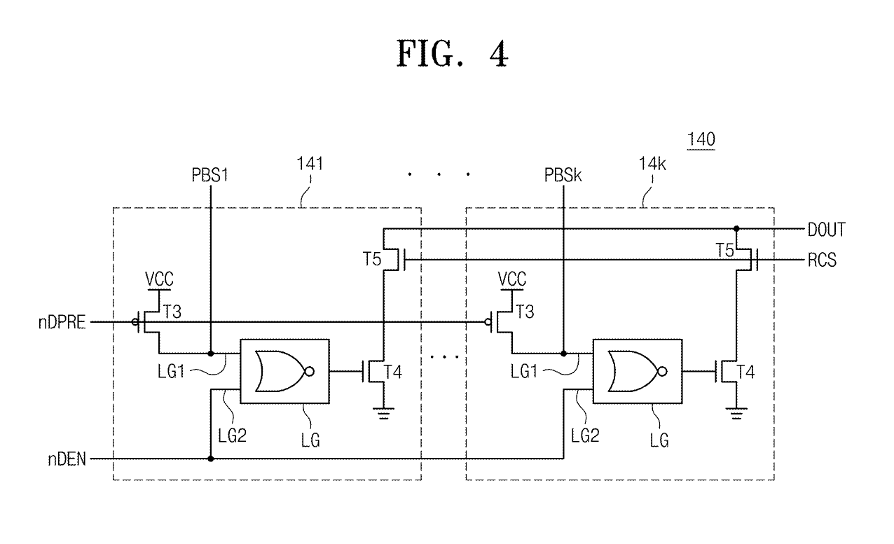

FIG. 4 is a circuit diagram illustrating a first embodiment of the page buffer decoding unit 140 according to the inventive concepts. Referring to FIGS. 1, 3 and 4, the page buffer decoding unit 140 includes a plurality of decoders 141 through 14k. The first through kth decoders 141 through 14k may receive first through kth page buffer signals PBS1 through PBSk from the page buffer unit respectively. The decoder enable signal nDEN and the decoder precharge signal nDPRE are provided to first through kth decoders 141 through 14k commonly. The first through kth decoders 141 through 14k may output the decoder output signal DOUT responsive to the first through kth page buffer signals PBS1 through PBSk. Each of the first through kth decoders 141 through 14k may include a first transistor T3, a second transistor T4, a fifth transistor T5 and a logic gate LG.

First input nodes LG1 of the logic gates LG may be coupled with the third transistors T3 and supplied with the first through kth page buffer signal PBS1 through PBSk respectively. The third transistors T3 may precharge the first input nodes LG1 of the logic gates LG to the power supply voltage VCC in response to the decoder precharge signal nDPRE. Second input nodes LG2 of the logic gates LG may be supplied with the decoder enable signal nDEN. The logic gates LG may be elements performing NOR operation.

The fourth transistors T4 may operate responsive to outputs of the logic gates LG. First nodes of the fourth transistors T4 may be supplied with the ground voltage VSS, and second nodes of the fourth transistors may be coupled with the fifth transistors T5.

The fifth transistors T5 may operate responsive to the reference current signal RCS. First nodes of the fifth transistors T5 may be coupled with the fourth transistors T4 and second nodes of the fifth transistors T5 may be coupled commonly to output the decoder output signal DOUT.

A NOR gate may output logic high when logic low is inputted through two input nodes, and output logic high when logic high is inputted through at least one of the two input nodes. When the decoder enable signal nDEN is logic high, the logic gates LG may output logic low. That is, the decoder 140 is disabled. When the decoder enable signal nDEN is logic low, the logic gates LG may output logic high or logic low according to the values of the first input nodes LG1. That is, the decoder 140 is enabled.

When the transfer signals PFG1 through PFn is deactivated, the first through kth page buffer signals PBS1 through PBSk are floated. The third transistors may precharge the first input nodes LG1 to the power supply voltage VCC in response to the decoder precharge signal nDPRE. Then, the decoder precharge signal nDPRE is deactivated, and the first input nodes LG1 of the logic gates LG may be floated.

One of the transfer signals PF1 through PFn is activated, page buffers of one stage of the first through nth stages STAGE1 through STAGEn may output the first through kth page buffer signals PBS1 through PBSk.

When a memory cell corresponding to the first page buffer signal PBS1 is the program-passed memory cell, the first page buffer signal PBS1 may be floated. The first input node LG1 of the logic gate LG of the first decoder 141 may maintain the precharged power supply voltage VCC (i.e., logic high). The logic gate LG of the first decoder 141 may output logic low. The fourth transistor T4 of the first decoder may be turned off, and an output node of the first decoder 141 is floated.

When the memory cell corresponding to the first page buffer signal PBS1 is the program-failed memory cell, the first page buffer signal PBS1 is the ground voltage. A voltage of the first input node LG1 of the logic gate LG of the first decoder 141 may be discharged to the ground voltage (i.e., transit to logic low). The logic gate LG of the first decoder 141 may output logic high. The fourth transistor T4 of the first decoder 141 may be turned on, and the first decoder 141 may operate as a current sink pulling (i.e., drawing negative charges to ground) a current from the output node of the first decoder 141. An amount of the current pulled by the first decoder 141 is controlled by the reference current signal RCS. The current pulled by the first decoder 141 in response to the reference current signal RCS may be the reference current RC.

Each of the second through kth decoders 142 through 14k may operate in an identical manner with the first decoder 141. Output examples of the decoders 141 through 14k according to the verify-read result may be shown in following Table 3.

TABLE 3

| | Program pass | Program fail |
|---|---|---|
| Bit line | High | Low |
| Page buffer signal | Float | Low (VSS) |
| Output of decoder | Float | Current sink (RC) |

The output nodes of the first through kth decoders 141 through 14k are coupled commonly with an output node of the page buffer decoding unit 140. The decoder output signal DOUT may be a total current pulled by the first through kth decoders 141 through 14k. For example, each of the first through kth decoders 141 through 14k may pull the reference current RC. According to the number of the fail bits indicated by the page buffer signals PBS1 through PBSk, a number of decoders which pull the reference current RC is determined Thus, the decoder output signal DOUT may be a current having an amount which is a multiple of the reference current RC. The decoder output signal DOUT may be a current having a negative value. The page buffer decoding unit 140 may be a current sink which pulls a current having an amount corresponding to the number of the program-failed memory cells.

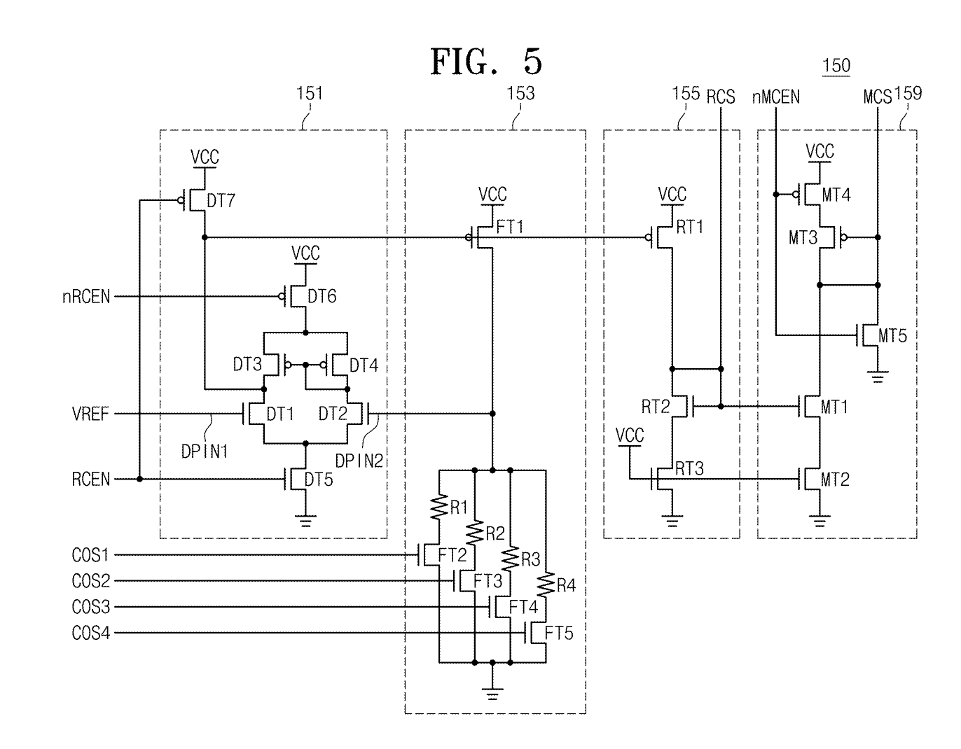

FIG. 5 is a circuit diagram illustrating a first embodiment of the current generating unit 150 according to the inventive concepts. Referring to FIGS. 1 and 5, the current generating unit 150 may include a differential amplifier 151, a feedback variable resistor 153, a reference current signal generator 155 and a maximum current signal generator 159.

The differential amplifier 151 may include first through seventh differential amplifier transistors DT1 through DT7. The first and second differential amplifier transistors DT1 and DT2 may constitute first and second differential inputs DPIN1 and DPIN2. The third and fourth differential amplifier transistors DT3 and DT4 may constitute a current mirror.

The fifth differential amplifier transistor DT5 may supply the ground voltage VSS to the differential amplifier 151 in response to the reference current enable signal RCEN. The sixth differential amplifier transistor DT6 may supply the power supply voltage VCC to the differential amplifier 151 in response to the inverted reference current enable signal nRCEN. That is, when the reference current enable signal RCEN is logic low and the inverted reference current enable signal nRCEN is logic high, the differential amplifier 151 is disabled.

The seventh differential amplifier transistor DT7 may supply the power supply voltage VCC to an output node DPOUT of the differential amplifier 151 in response to the reference current enable signal RCEN. When the differential amplifier 151 is disabled, the seventh differential amplifier transistor DT7 may output the power supply voltage VCC to the output node DPOUT of the differential amplifier 151.

The first input node DPIN1 of the differential amplifier 151 is supplied with a reference voltage VREF, and the second input node DPIN2 is supplied with a voltage divided by the feedback variable resistor 153. For example, the reference voltage VREF may be the power supply voltage or one of various voltages used in the nonvolatile memory device 100.

The feedback variable resistor 153 may include first through fifth feedback transistors FT1 through FT5 and first through fourth resistors R1 through R4.

The first feedback transistor FT1 may operate responsive to an output signal of the differential amplifier 151. A first node of the first feedback transistor FT1 may be supplied with the power supply voltage VCC, a second node may be coupled with the second input node DPIN2 of the differential amplifier 151. The first feedback transistor FT1 may operate as a current driver supplying a current in response to the output of the differential amplifier 151.

First nodes of the first through fourth resistors R1 through R4 may be coupled with the second input node DPIN2, and second nodes may be coupled with the second through fifth feedback transistors FT2 through FT4 respectively. First nodes of the second through fifth feedback transistors FT2 through FT5 may be coupled with the first through fourth resistors R1 through R4 respectively, and second nodes may be supplied with the ground voltage VSS. The second through fifth feedback resistors FT2 through FT5 may operate in response to the first through fourth current option signals COS1 through COS4 respectively.

The first through fourth resistors R1 through R4 and the second through fifth feedback transistors FT2 through FT5 may constitute a variable resistor which operates responsive to the first through fourth current option signals COS1 through COS4. A voltage supplied to the second input node DPIN2 of the differential amplifier 151 may be varied according to the first through fourth current option signals COS1 through COS4. That is, the output signal of the differential amplifier 151 may be varied by the first through fourth current option signals COS1 through COS4.

The reference current generator 155 may include first through third reference transistors RT1 through RT3. The first reference transistor RT1 may operate in response to the output signal of the differential amplifier 151. A first node of the first reference transistor RT1 may be supplied with the power supply voltage VCC, and a second node may be coupled with the second reference transistor RT2.

A first node of the second reference transistor RT2 may be coupled with the first reference transistor RT1, and a second node may be coupled with the third reference transistor RT3. The first node and a gate of the second reference transistor RT2 may be coupled in common and output the reference current signal RCS.

A first node of the third reference transistor RT3 may be coupled with the second reference transistor RT2, and a second node may be supplied with the ground voltage VSS. A gate of the third reference transistor RT3 may be supplied with the power supply voltage VCC. The third transistor RT3 may maintain a turned on state.

When the reference current enable signal RCEN is activated, the output signal of the differential amplifier 151 may be formed by the differential amplifier 151 and the feedback variable resistor 153. The output signal of the differential amplifier 151 may be adjusted by the first through fourth current option signals COS1 through COS4. The reference current generator 155 may output the reference current signal RCS in response to the output signal of the differential amplifier 151. Thus, the reference current signal RCA may be adjusted by the first through fourth current option signals COS1 through COS4.

When the current enable signal RCEN is deactivated, the output signal of the differential amplifier 151 may be determined regardless of the feedback variable resistor 153. Thus, even though the first through fourth current option signals COS1 through COS4 are adjusted, the reference current generator 155 may maintain the reference current signal RCS without any variation.

The maximum current signal generator 159 may include first through fifth maximum current transistors MT1 through MTS. The first maximum current transistor MT1 may operate as a current mirror with the second maximum current transistor MT2. The second maximum current transistor MT2 may be coupled between the first maximum current transistor MT1 and a ground node. A gate of the second maximum current transistor MT2 is supplied with the power supply voltage VCC. The second maximum current transistor may maintain a turned on state.

A first node of the third maximum current transistor MT3 may be coupled with the first maximum current transistor MT1, and a second node may be coupled with the fourth maximum current transistor MT4. The fourth maximum current transistor MT4 may be coupled between the third maximum current transistor MT3 and a power supply node. The fourth maximum current transistor MT4 may supply the power supply voltage VC to the maximum current signal generator 159 responsive to the maximum current enable signal nMCEN. A first node of the fifth maximum current transistor MT5 may be coupled with the third maximum current transistor MT3, and a second node may be supplied with the ground voltage. The fifth maximum current transistor MT5 may supply the ground voltage VSS to the maximum current signal generator 159 in response to the maximum current enable signal nMCEN.

A first node of the first maximum current transistor MT1, the first node and a gate of the third maximum current transistor MT3 and a first node of the fifth maximum current transistor MT5 may be coupled in common and output the maximum current signal MCS.

When the maximum current enable signal nMCEN is activated, the fourth maximum current transistor MT4 may be turned on, and the fifth maximum current transistor MT5 may be turned off. The maximum current signal generator 159 may output the maximum current signal MCS responsive to the reference current signal RCS. When the maximum current enable signal nMCEN is deactivated, the fourth maximum current transistor MT4 may be turned off, and the fifth maximum current transistor MT5 may be turned on. The maximum current signal generator 159 may output the ground voltage as the maximum current signal MCS in regardless of the reference current signal RCS.

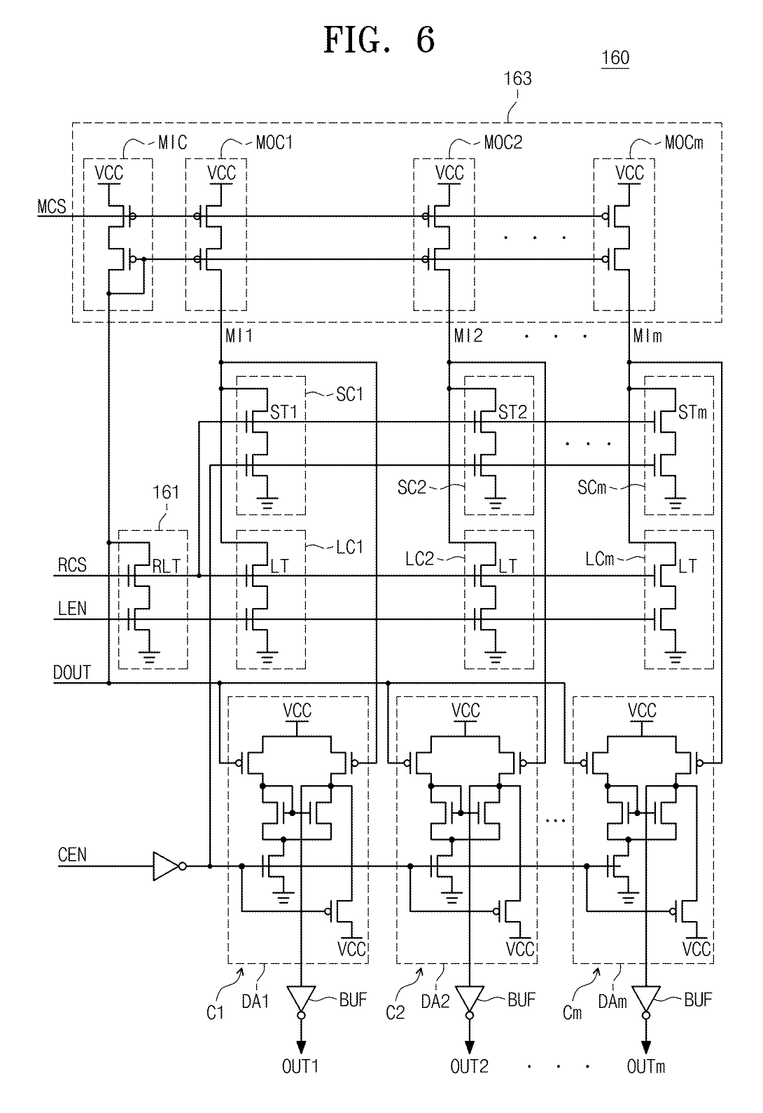

FIG. 6 is a circuit diagram illustrating a first embodiment of the analog bit counting unit 160 according to the inventive concepts. Referring to FIGS. 1 and 6, the analog bit counting unit 160 may include a reference load circuit 161, a current mirror 163, first through mth sink circuits SC1 through SCm, first through mth load circuits LC1 through LCm and first through mth differential amplifiers DA1 through DAm.

The reference load circuit 161 may be electrically coupled with a ground node in response to the load enable signal LEN. The reference load circuit 161 may be enabled or disabled responsive to the load enable signal LEN.

The reference load circuit 161 may include a reference load transistor RLT. The reference load transistor RLT may operate in response to the reference current signal RCS. For example, a size of the reference load transistor RLT may be larger than a size of a normal transistor. When the size of the reference load transistor RLT may be n-times larger than the size of the normal transistor, the reference load transistor RLT may pull an n-times larger current than the reference current RC responsive to the reference current signal RCS. The reference load transistor RLT may operate as a current sink.

The current mirror 163 may mirror an input signal to output a plurality of mirrored signals. The input signal may be a total current of the decoder output signal DOUT and the current pulled by the reference load circuit 161. The current mirror 163 may include a mirror input circuit MIC and first through mth mirror output circuits MOC1 through MOCm.

The mirror input circuit MIC may receive the input signal. The first through mth mirror output circuits MOC1 through MOCm may mirror the input signal to output first through mth mirrored signals MI1 through MIm respectively.

The first through mth load circuits may be current sinks which pull current from the first through mth mirrored signals MI1 through MIm. The first through mth load circuits may be electrically coupled with ground nodes in response to the load enable signal LEN. The first through mth load circuits LC1 through LCm may be enabled or disabled responsive to the load enable signal LEN.

The first through mth load circuits LC1 through LCm may include load transistors LT respectively. The load transistors LT may operate in response to the reference current signal RCS. Each of the load transistors LT may have the same structure and size to the reference load transistor RLT. That is, each of the first through mth load circuits LC1 through LCm may be a current sink pulling an identical current with the reference load circuit 161.

The reference load circuit 161 may pull a current from the input signal of the current mirror 163. The first through mth load circuits LC1 through LCm may pull currents from the first through mth mirrored signals MI1 through MIm respectively. The reference load circuit 161 and the first through mth load circuits LC1 through LCm may be used to provide offset to the analog bit counting unit 160. For example, each of the reference load circuit 161 and the first through mth load circuits LC1 through LCm may substantially pull a 5-times larger current than the reference current RC. That is, each of the reference load transistor RLT and load transistors LT may have a 5-times larger size than the size of the normal transistor.

The first through mth sink circuits SC1 through SCm may be current sinks which pull currents from the first through mth mirrored signals MI1 through MIm respectively. The first through mth sink circuits SC1 through SCm may be electrically coupled with ground nodes responsive to the count enable signal CEN. The first through mth sink circuits SC1 through SCm may be enabled or disabled in response to the count enable signal CEN.

The first through mth sink circuits SC1 through SCm may include first through mth sink transistors ST1 through STm respectively. The first through mth sink transistors ST1 through STm may have different sizes than each other. When the first through mth sink transistors ST1 through STm have different sizes, amounts of currents pulled by the first through mth sink transistors ST1 through STm may be different than each other.

The first through mth differential amplifiers DA1 through DAm may enabled or disabled in response to the count enable signal CEN. When the count enable signal CEN is logic low, the first through mth differential amplifiers DA1 through DAm may be supplied with the ground voltage, and enabled. When the count enable signal CEN is logic high, the first through mth differential amplifiers DA1 through DAm may not be supplied with the ground voltage, and disabled. When the first through mth differential amplifiers DA1 through DAm are disabled, the power supply voltage may be output as outputs of the first through mth differential amplifiers DA1 through DAm in response to the count enable signal CEN.

The first through mth differential amplifiers DA1 through DAm may compare a voltage generated by the input signal of the current mirror 163 with voltages generated by first through mth differential amplifiers DA1 through DAm respectively. The first through mth differential amplifiers DA1 through DAm may output the compared result as the first through mth counting results OUT1 through OUTm. The counting results OUT1 through OUT1 may be output via buffers BUF.

The first sink circuit SC1 and the first differential amplifier DA1 may constitute a first counter C1. The first differential amplifier DA1 may compare the voltage generated by the input signal of the current mirror with the voltage generated by the first mirrored signal MI1 to output the compare result as the first counting result OUT1. Similarly, the second through mth sink circuits SC2 through SCm may constitute second through mth counters C2 through Cm.

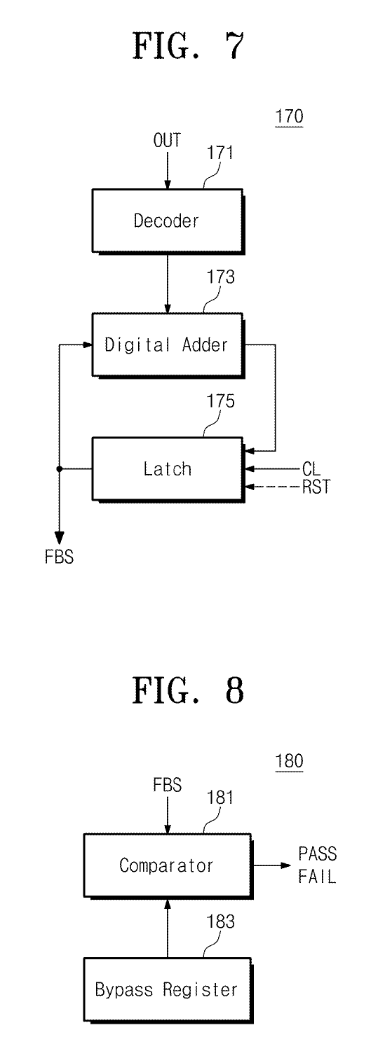

FIG. 7 is a block diagram illustrating the digital adding unit 170 according to an embodiment of the inventive concepts. Referring to FIGS. 1 and 7, the digital adding unit 170 may include a decoder 171, a digital adder 173 and a latch 175.

The decoder 171 may receive the counting results OUT1 through OUTm from the analog bit counting unit 160. The decoder 171 may convert the received counting results OUT1 through OUTm into a digital value (e.g., digital bits) of a specific number system. For example, the decoder 171 may convert the counting results OUT1 through OUTm into a digital value of one of various number systems such as a binary system, an octal system, a decimal system, a hexadecimal system, etc.

The digital adder 173 may receive the digital value from the decoder 171. The digital adder 173 may add a value stored in the latch 175 (e.g., digital bits) and the digital value received from the decoder 171.

An input node of the latch 175 may be coupled with an output node of the digital adder 173. An output node of the latch 175 may be coupled with the digital adder 173 and output as the fail bit signal FBS. The latch 175 may operate responsive to the latch signal CL or the reset signal RST. When the reset signal RST is activated, the latch 175 may be reset. When the latch signal CL is activated, the latch 175 may store an output signal of the digital adder 173.

FIG. 8 is a block diagram illustrating an embodiment of the pass/fail checking unit 180 according to the inventive concepts. Referring to FIGS. 1 and 8, the pass/fail checking unit 180 may include a comparator 181 and a bypass register 183.

The comparator 181 may receive the fail bit signal FBS from the digital adding unit 170. The bypass register 183 may be configured to store a bypass value. The bypass value may be a number of the fail bits which can be ignored during the program operation. When the value of the fail bit signal FBS is equal to or less than the bypass value, the comparator may output the pass signal PASS. When the value of the fail bit signal FBS is higher than the bypass value, the comparator 181 may output the fail signal FAIL.

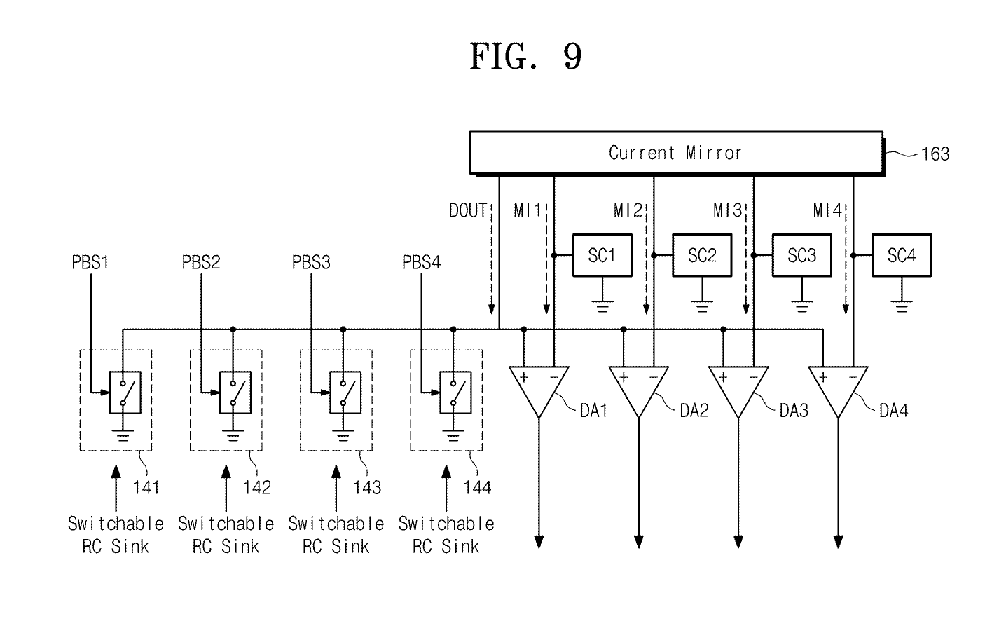

FIG. 9 is a schematic diagram illustrating a portion of the page buffer decoding unit 140 and the analog bit counting unit 160 according to an embodiment of the inventive concepts. The reference load circuit 161 and the first through mth load circuits LC1 through LCm are not shown in FIG. 9 for a convenient description. Referring to FIGS. 4, 6 and 9, the decoders 141 through 144 of the page buffer decoding unit 140 may be current sinks which operate in response to the page buffer signals PBS1 through PBS4. A number of the decoders is not limited.

Each decoder may pull the reference current RC generated in response to the reference current signal RCS. When one of the page buffer signals PBS1 through PBS4 indicates the fail bit, a corresponding decoder of the decoders 141 through 144 may pull the reference current RC. The decoder output signal DOUT may be the total current pulled by the decoders 141 through 144.

The current mirror 163 may mirror the decoder output signal DOUT and output the mirrored signals MI1 through MI4. A number of the mirrored signals MI1 through MI4 is not limited.

The sink circuits SC1 through SC4 may pull currents from the first through fourth mirrored signals MI1 through MI4 respectively. A number of the sink circuits SC1 through SC4 is not limited. An amount of a current pulled by each sink circuit may be determined by the size of the sink transistor therein.

The decoder output signal DOUT may be transferred via a positive input node of the first differential amplifier DA1. The current mirror 163 may provide the first mirrored signal MI1, which is the same to the decoder output signal DOUT, to a negative input node of the first differential amplifier DA1. The first sink circuit SC1 may pull a specific amount of current from the negative input node of the first differential amplifier DA1. When the amount of the current pulled by the first sink circuit SC1 is less than the first mirrored signal MI1, a voltage of the negative input node of the first differential amplifier DA1 may increase, and then the first differential amplifier DA1 may output logic high.

Similarly, the second through fourth differential amplifiers DA2 through DA4 may output logic high or logic low according to whether amounts of currents pulled by the second through fourth sink circuits SC2 through SC4 are larger than the decoder output signal DOUT respectively. By adjusting the amounts of the currents pulled by the sink circuits SC1 through SC4, outputs of the differential amplifiers DA1 through DA4 may be set to indicate information of the number of the fail bits.

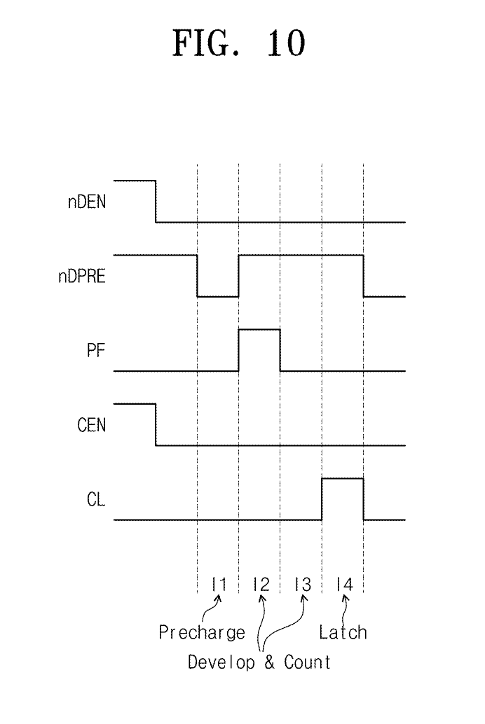

FIG. 10 is a timing diagram illustrating an example of a portion of control signals of the nonvolatile memory device 100 according to the inventive concepts. Referring to FIGS. 1 and 10, the decoder enable signal nDEN may be activated, and the page buffer decoding unit 140 may be enabled. The counting enable signal CEN may be activated, and the analog bit counting unit 160 may be enabled.

During the first interval I1, the decoder precharge signal nDPRE may be activated. The first input nodes LG1 of the logic gates LG of the decoders 141 through 14k of the page buffer decoding unit 140 may be precharged to the power supply voltage VCC. The first interval I1 may form a precharge interval.

During the second interval 12, the decoder precharge signal nDPRE may be deactivated. The first input nodes LG1 of the logic gates LG of the decoders 141 through 14k of the page buffer decoding unit 140 may be floated. The transfer signal PF is activated. For example, one of the first through nth transfer signals PF1 through PFn may be activated. That is, the page buffers of one stage of the first through nth stages STAGE1 through STAGEn may output the page buffer signals PBS1 through PBSk. Then, during the third interval I3, the transfer signal PF may be deactivated.

During the second and third intervals I2 and I3, the page buffer decoding unit 140 may output the decoder output signal DOUT according to the number of the fail bits which is indicated by the page buffer signals PBS1 through PBSk. The decoder output signal DOUT may be a current having an amount corresponding to a multiple of the amount of the reference current RC and the number of the fail bits.

The analog bit counting unit 160 may output the counting results OUT1 through OUTm responsive to the decoder output signal DOUT. The counting results OUT1 through OUTm may be converted into the digital value of the specific number system, and then added with the value stored in the latch 175.

The second and third intervals I2 and I3 may form develop and counting intervals.

During the fourth interval I4, the latch signal CL may be activated. The value added by the digital adder 173 may be stored into the latch 175.

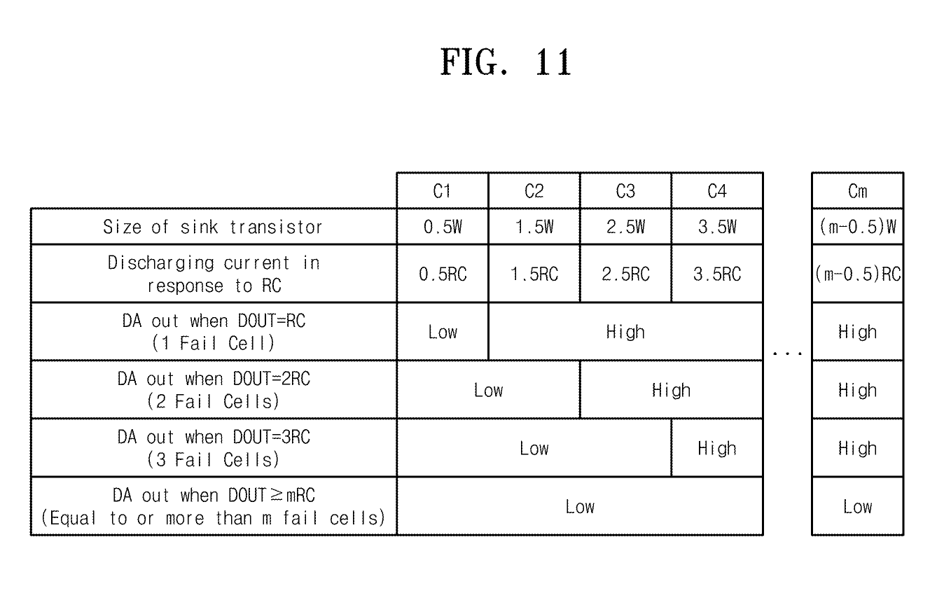

FIG. 11 illustrates a first embodiment of the sizes of the sink transistors ST1 through STm and operations of the page buffer decoding unit 140 and analog bit counting unit 160 according to the inventive concepts. The offset based on the reference load circuit 161 and the first through mth load circuits LC1 through LCm may be ignored for convenience of the description. Referring to FIGS. 6, 9 and 11, the sizes of the sink transistors ST1 through STm may be expressed referring to a size W. The size W may be a size of the normal transistor of the nonvolatile memory device 100.

The size of the first sink transistor ST1 may be 0.5 W. When the reference current signal RCS is applied to the first sink transistor, the first transistor may pull a current of 0.5RC. The size of the second sink transistor ST2 may be 1.5 W. The second sink transistor ST2 may pull a current of 1.5RC in response to the reference current signal RCS. The size of the third sink transistor ST3 may be 2.5 W. The third sink transistor ST3 may pull a current of 2.5RC in response to the reference current signal RCS. The size of the fourth sink transistor ST4 may be 3.5 W. The fourth sink transistor ST4 may pull a current of 3.5RC in response to the reference current signal RCS. The size of the mth sink transistor STm may be (m−0.5)W. The mth sink transistor STm may pull a current of (m−0.5)RC in response to the reference current signal RCS.

When the page buffer signals PBS1 through PBSk indicate that the number of the program-failed memory cells is one, the decoder output signal DOUT may be the reference current RC. Each of the 1st through mth mirrored signals MI1 through MIm are the reference current RC. An amount of current pulled through the first sink circuit SC1 is 0.5RC. Thus, charges may be accumulated on the first sink circuit SC1, and a voltage of the first sink circuit SC1 may increase and the first differential amplifier DA1 may output a logic low. Each of the second through mth sink circuits SC2 through SCm pulls a current having more amount than the reference current RC. Thus, each of the second through mth differential amplifiers DA2 through DAm may output logic high.

When the page buffer signals PBS1 through PBSk indicate that the number of the program-failed memory cells is two, the decoder output signal DOUT may be 2RC. Each of the first through mth mirrored signals is 2RC. Amounts of currents pulled by the first and second sink circuits SC1 and SC2 are 0.5RC and 1.5RC respectively, and they are less than the decoder output signal DOUT. Thus, the first and second differential amplifiers DA1 and DA2 may output a logic low, and remaining differential amplifiers DA3 through DAm may output logic high.

When the page buffer signals PBS1 through PBSk indicate that the number of the program-failed memory cells is three, the decoder output signal DOUT may be 3RC. Each of the first through mth mirrored signals is 3RC. Amounts of currents pulled via the first through third sink circuits SC1 through SC3 are 0.5RC, 1.5RC and 2.5RC respectively, and they are less than the decoder output signal DOUT. Thus, the first through third differential amplifiers DA1 through DA3 may output logic low, and remaining differential amplifiers DA4 through DAm may output logic high.

When the page buffer signals PBS1 through PBSk indicate that the number of the program-failed memory cells is equal to or more than m, the decoder output signal DOUT may be equal to or more than mRC. Amount of currents pulled by each of the first through mth sink circuits SC1 through SCm is less than mRC. Thus, the first through mth differential amplifiers DA1 through DAm may output logic low.

As described above, when the sink transistors ST1 through STm are configured to pull different currents having amounts between integer numbers of the reference current RC, the counters C1 through Cm of the analog bit counting unit 160 may output information about the number of program-failed memory cells indicated by the page buffer signals PBS1 through PBSk. For example, the sink transistors SC1 through SCm differ from each other by W in size.

When the first through mth counters C1 through Cm is activated simultaneously, the number of fail bits, which the fail bit signals PBS1 through PBSk indicate, may be counted in parallel. Thus, counting speed increases when compared with counting in series.

For example, the counters C1 through Cm may be divided into a plurality of groups, and the counters C1 through Cm may be activated sequentially in a unit of the divided group.

When the first through mth counters C1 through Cm are provided, the analog bit counting unit 160 may counts the decoder output signal DOUT to mRC. When the number of the fail bits, which the page buffer signals PBS1 through PBSk indicate, is more than m, the page buffer decoding unit 140 pulls a current larger than mRC and the current mirror 163 may output currents MI1 through MIm larger than mRC respectively. By limiting a maximum amount of current pulled by the current mirror 163 using the maximum current signal MCS, power consumption may be reduced.

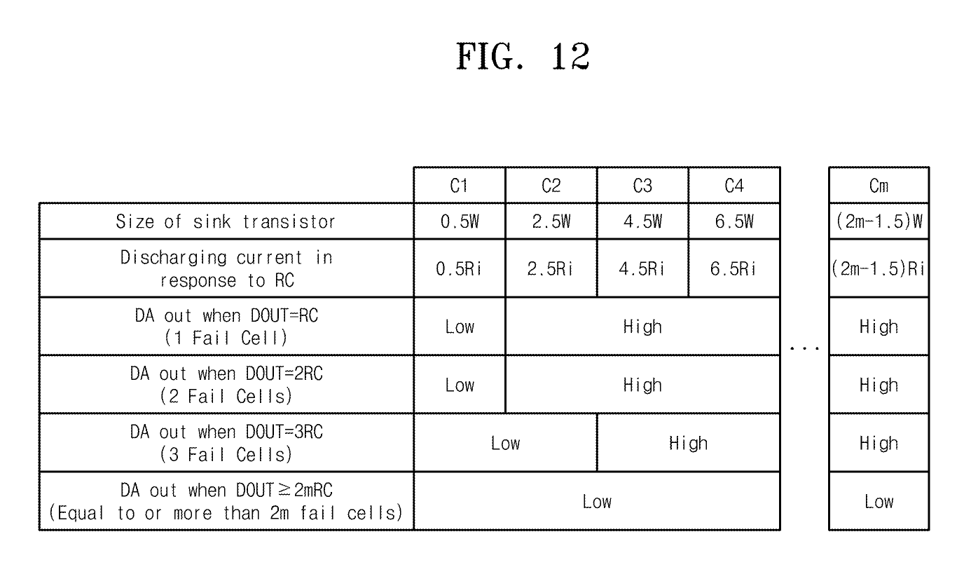

FIG. 12 illustrates a second embodiment of the sizes of the sink transistors ST1 through STm and operations of the page buffer decoding unit 140 and analog bit counting unit 160 according to the inventive concepts. For example, the offset of the reference load circuit 161 and the first through mth load circuits LC1 through LCm may be ignored. Referring to FIGS. 6, 9 and 12, the sizes of the sink transistors ST1 through STm may be expressed referring to a size W. The size W may be a size of the normal transistor of the nonvolatile memory device 100.

The size of the first sink transistor ST1 may be 0.5 W. When the reference current signal RCS is applied to the first sink transistor, the first transistor may pull a current of 0.5RC. The size of the second sink transistor ST2 may be 2.5 W. The second sink transistor ST2 may pull a current of 2.5RC in response to the reference current signal RCS. The size of the third sink transistor ST3 may be 2.5 W. The third sink transistor ST3 may pull a current of 3.5RC in response to the reference current signal RCS. The size of the fourth sink transistor ST4 may be 4.5 W. The fourth sink transistor ST4 may pull a current of 4.5RC in response to the reference current signal RCS. The size of the mth sink transistor STm may be (2m−1.5)W. The mth sink transistor STm may pull a current of (2m−1.5)RC in response to the reference current signal RCS.

When the page buffer signals PBS1 through PBSk indicate that the number of the program-failed memory cells is one, the decoder output signal DOUT may be the reference current RC. Each of the 1st through mth mirrored signals MI1 through MIm are the reference current RC. An amount of current pulled through the first sink circuit SC1 is 0.5RC. Thus, the first differential amplifier DA1 may output a logic low, and remaining differential amplifiers DA2 through DAm may output logic high.

When the page buffer signals PBS1 through PBSk indicate that the number of the program-failed memory cells is two, the decoder output signal DOUT may be 2RC. Amounts of currents pulled by the first and second sink circuits SC1 and SC2 are 0.5RC and 2.5RC respectively, and they are less than the decoder output signal DOUT. Thus, the first differential amplifier DA1 may output a logic low, and remaining differential amplifiers DA2 through DAm may output logic high.

When the page buffer signals PBS1 through PBSk indicate that the number of the program-failed memory cells is three, the decoder output signal DOUT may be 3RC. Amounts of currents pulled via the first and second sink circuits SC1 through SC2 are 0.5RC and 2.5RC respectively, and they are less than the decoder output signal DOUT. Thus, the first and second third differential amplifiers DA1 through DA2 may output logic low, and remaining differential amplifiers DA3 through DAm may output logic high.

When the page buffer signals PBS1 through PBSk indicate that the number of the program-failed memory cells is equal to or more than 2 m, the decoder output signal DOUT may be equal to or more than 2mRC. Amount of currents pulled by each of the first through mth sink circuits SC1 through SCm is less than 2mRC. Thus, the first through mth differential amplifiers DA1 through DAm may output logic low.

As described referring to FIGS. 11 and 12, a resolution and a number of a countable fail bits may be adjusted by adjusting the sized of the sink transistors ST1 through STm. The resolution may be a number of fail bits which causes a transition of a signal among the counting results OUT1 through OUTm of the counting unit 160.

For example, the analog bit counting unit 160 may have one resolution when the sink transistors ST1 through STm are configured to have size differences of W. The analog bit counting unit 160 may have two resolutions when the sink transistors ST1 through STm are configured to have size differences of 2 W. Similarly, the analog bit counting unit 160 may have n resolutions when the sink transistors ST1 through STm are configured to have size differences of nW.

In FIGS. 11 and 12, it is described that the first sink transistor ST1 has a size of 0.5 W. That is, the first counting result OUT1 of the first differential amplifier DA1 transits when the page buffer signals PBS1 through PBSk indicate one fail bit. However, the first transistor ST1 may have a size of (n−0.5)W (n is a positive integer). That is, the first counting result OUT1 may transit when the page buffer signals PBS1 through PBSk indicate n fail bits.

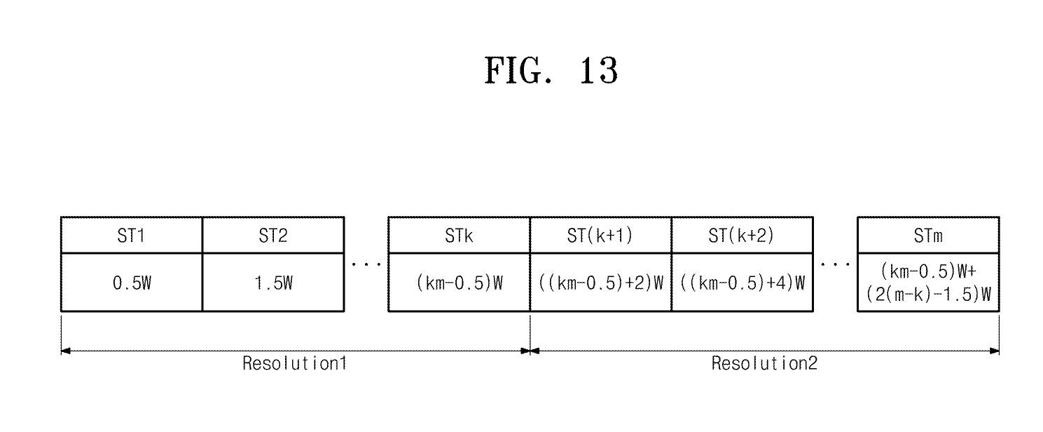

FIG. 13 illustrates an embodiment of the sink transistors ST1 through STm providing a multi resolution. Referring to FIGS. 6 and 13, the first through kth sink transistors ST1 through STk may be configured to have differences of W in the sizes. The first through kth counters C1 through Ck may have one resolution. The k+1 th through mth sink transistors STk+1 through STm may be configured to have differences of 2 W in the sizes. The k+1th through mth counters Ck+1 through Cm may have two resolutions. That is, the analog bit counting unit 160 may execute the counting with different resolutions according to the number of the fail bits.

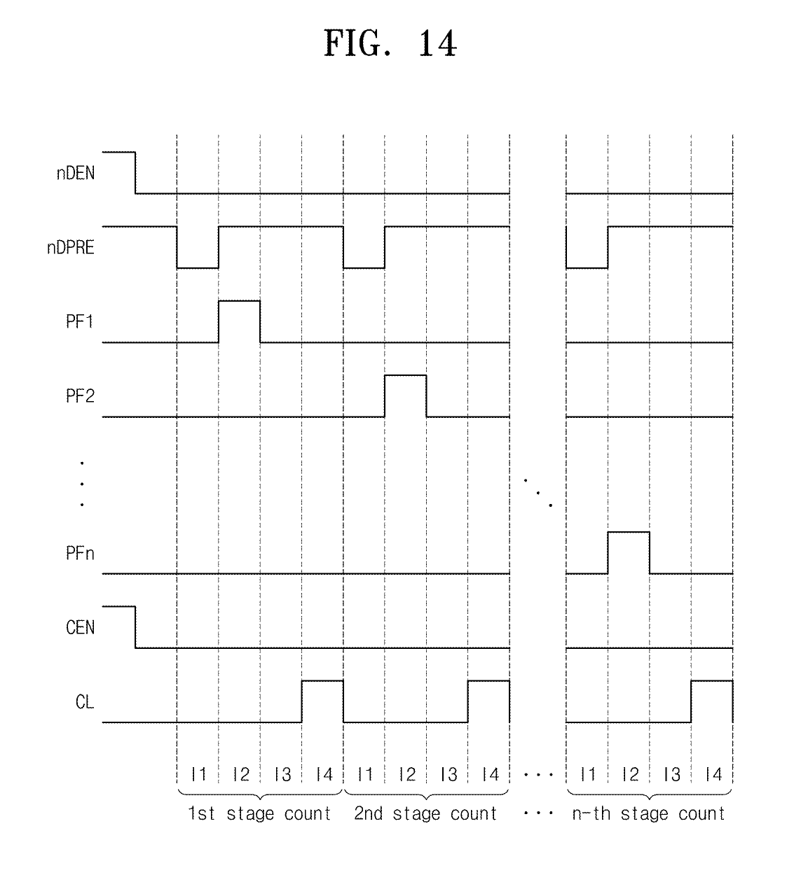

FIG. 14 is a timing diagram illustrating a first embodiment of the counting the number of the program-failed memory cells. Referring to FIGS. 1 through 10 and 14, the counting is performed in a unit of the stage of the page buffers PB1 through PBr.

The decoder enable signal nDEN and the count enable signal CEN are activated. In response to the activated decoder enable signal nDEN, the page buffer decoding unit 140 is enabled. In response to the count enable signal CEN, the analog bit counting unit 160 is enabled. For example, the reset signal RST may be activated along with the decoder enable signal nDEN and the count enable signal. The decoder enable signal nDEN and the count enable signal CEN may be activated concurrently or in a specific order.

A counting of fail bits of the verify-read result of page buffers PB1 and PBo of the first stage STAGE1 is performed. During a precharge interval I1, the decoder precharge signal nDPRE is activated. The first input nodes LG1 of the logic gates LG of the page buffer decoding unit 140 may be precharged to the power supply voltage.

During develop and count intervals I2 and I3, the first transfer signal PF1 is activated and then deactivated. The page buffers PB1 and PBo of the first stage STAGE1 may output the verify-read result as the page buffer signals PBS1 through PBSk. The page buffer decoding unit 140 may output the decoder output signal DOUT in response to the page buffer signals PBS1 through PBSk. The decoder output signal DOUT may have an amount of integer times of the reference current RC.

Based on the decoder output signal DOUT, the counters C1 through Cm of the analog bit counting unit 160 may count the number of fail bits of the verify-read result from the page buffers PB12 and PBO of the first stage STAGE1. The analog bit counting unit 160 may output the counting results OUT1 through OUTm. The decoder 171 of the digital adding unit 170 may convert the counting results OUT1 through OUTm into a digital value. The digital adder 173 may add a value output from the decoder 171 with a value stored in the latch 175.

During the latch interval I4, the latch signal CL is activated. The latch 175 may store a value added by the digital adder 173 in response to the activation of the latch signal CL.

Then, a counting of the verify-read result of the page buffers PB2 and PBp of the second stage STAGE2 is performed. During the precharge interval I1, the precharge of the page buffer decoding unit 140 is performed.

During the develop and count intervals I2 and I3, the second transfer signal PF2 is activated and then deactivated. The page buffers PB2 and PBp of the second stage STAGE2 may output the verify-read result as the page buffer signals PBS1 through PBSk. In response to the page buffer signals PBS1 through PBSk, the page buffer decoding unit 140 may output the decoder output signal DOUT. The number of the fail bits of the verify-read result from the page buffers PB2 and PBp of the second stage STAGE2 is counted according to the decoder output signal DOUT.

During the latch interval I4, the value stored in the latch 175 and the digital value output from the decoder 171 are added. That is, the number of the fail bits of the verify-read result from the page buffers PB1 and PBo of the first stage STAGE1 are added with that of the page buffers PB2 and PBp of the second stage STAGE2.

A counting of the verify-read result of the page buffers PNn and PBr of the nth stage STAGEn is performed. During the precharge interval I1, the precharge of the page buffer decoding unit 140 is executed.

During the develop and count intervals I2 and I3, the nth transfer signal PFn is activated and then deactivated. The page buffers PBn and PBr of the nth stage STAGEn may output the verify-read result as the page buffer signals PBS1 through PBSk. In response to the page buffer signals PBS1 through PBSk, the page buffer decoding unit 140 may output the decoder output signal DOUT. The number of the fail bits of the verify-read result from the page buffers PBn and PBr of the nth stage STAGEn is counted.

During the latch interval I4, the value stored in the latch 175 is added with the digital value output from the decoder 171. The numbers of the fail bits of the page buffers PB1 through PBr of the first through nth stages STAGE1 through STAGEn are added up. That is, the number of the fail bits of the page buffers PB1 through PBr is counted sequentially in an unit of the stage.

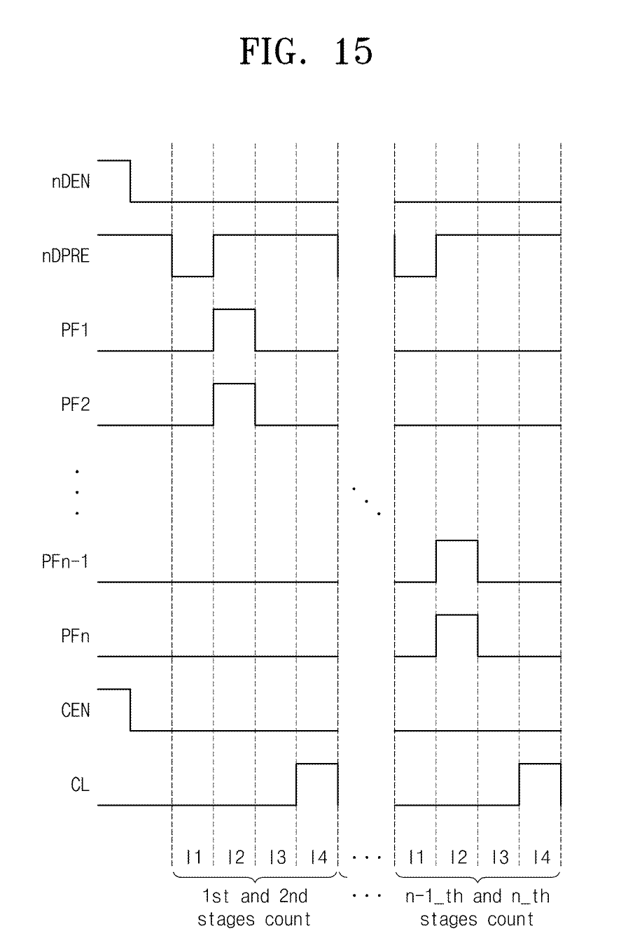

FIG. 15 is a timing diagram illustrating a second embodiment of the counting the number of the program-failed memory cells. When compared with the timing diagram shown in FIG. 14, two transfer signals (e.g., PF1 and PF2) are activated concurrently in the develop and count intervals I2 and I3. When the two transfer signals are activated simultaneously, verify-read results of page buffers of two stages counted concurrently. Thus, counting time may be reduced.

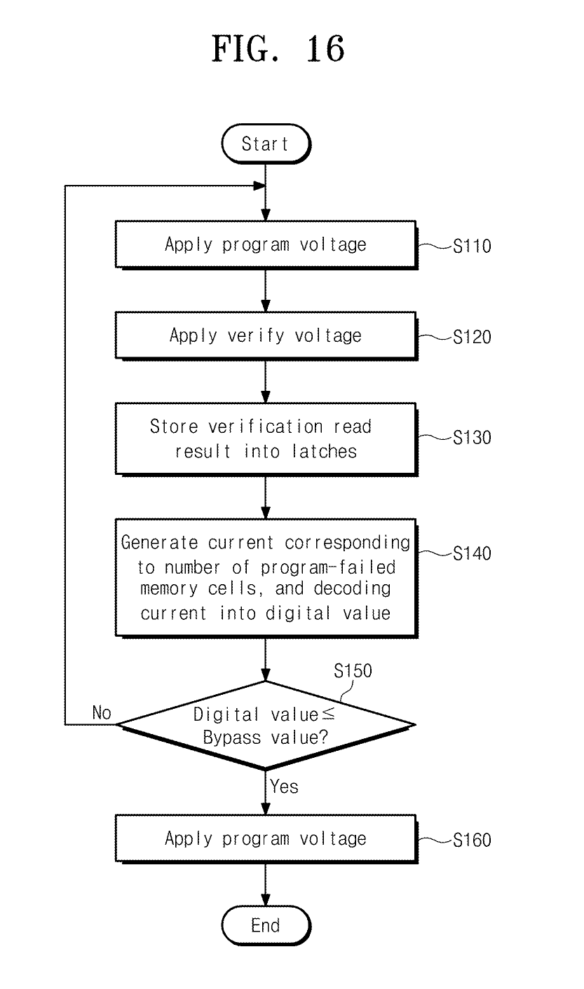

FIG. 16 is a flow chart illustrating a first embodiment of a programming method according to the inventive concepts. Referring to FIGS. 1 and 16, a program voltage is applied in a step S110. For example, the program voltage may be applied to a selected word line among the word lines WL1 through WLi (shown in FIG. 2). A verify voltage is applied in a step S120. The verify voltage may be applied to the selected word line.

The verify-read result is stored into latches in a step S130. For example, the verify-read result may be stored into the first and second latches L1 and L2 of the page buffer unit 130 (shown in FIG. 3).

A current corresponding to the number of the program-failed memory cells is generated, and the generated current is decoded into the digital value in a step S140. The page buffer decoding unit 140 may generate the current (i.e., the decoder output signal DOUT) corresponding to the number of the fail bits. The page buffer decoding unit 140 may output the decoder output signal DOUT once a stage of the stages STAGE1 through STAGEn of the page buffers PB1 through PBr.

The analog bit counting unit 160 may count the number of the fail bits from the output signal of the page buffer decoding unit 140 (i.e., the decoder output signal DOUT). The analog bit counting unit 160 may output the counting results OUT1 through OUTm once a stage of the stages STAGE1 through STAGEn of the page buffers PB1 through PBr.

The digital adding unit 170 may decode the counting results OUT1 through OUTm of the analog bit counting unit 160 into the digital value. The digital adding unit 170 may decode the counting result OUT1 through OUTm into the digital value once a stage of the stages STAGE1 through STAGEn, and may calculate a total sum. The total sum may be stored in the latch 175.

It is determined whether the digital value stored in the latch 175 (i.e., the total sum) is equal to or less than the bypass value in a step S150. The pass/fail checking unit 180 may determine whether the digital value stored in the latch 175 is equal to or less than the bypass value stored in the bypass register 183. When the digital value stored in the latch is more than the bypass value, the step S110 may be reexecuted. That is, a program loop, which includes the applying the program voltage and the applying the verify voltage, is repeated. The control unit 190 may repeat the program loop in response to the fail signal FAIL.

When the digital value stored in the latch 175 is equal to or less than the bypass value, a step S160 may be performed. In the step S160, the program voltage is applied and then the program operation is ended. For example, the pass/fail checking unit 180 may output the pass signal PASS when the digital value stored in the latch 175 is equal to or less than the bypass value. The control unit 190 may the nonvolatile memory device 100 that the program voltage is applied once more and the program operation is ended in response to the pass signal PASS.

The bypass value may be less than a number of error bits which can be corrected by the nonvolatile memory device 100 or a host thereof. That is, when error bits which can be corrected by an error correcting algorithm are detected, the nonvolatile memory device 100 may determine the program pass and end the program operation. Thus, time consumption caused by slow memory cells, which are programmed slower than normal memory cells, are reduced.

When the program pass is determined, the nonvolatile memory device 100 may apply the program voltage once more and end the program operation. Due to the program voltage applied once more, a portion of the program-failed memory cells may be programmed to be program-passed. Thus, the number of the program-failed memory cells may be reduced without an additional verify-read operation.

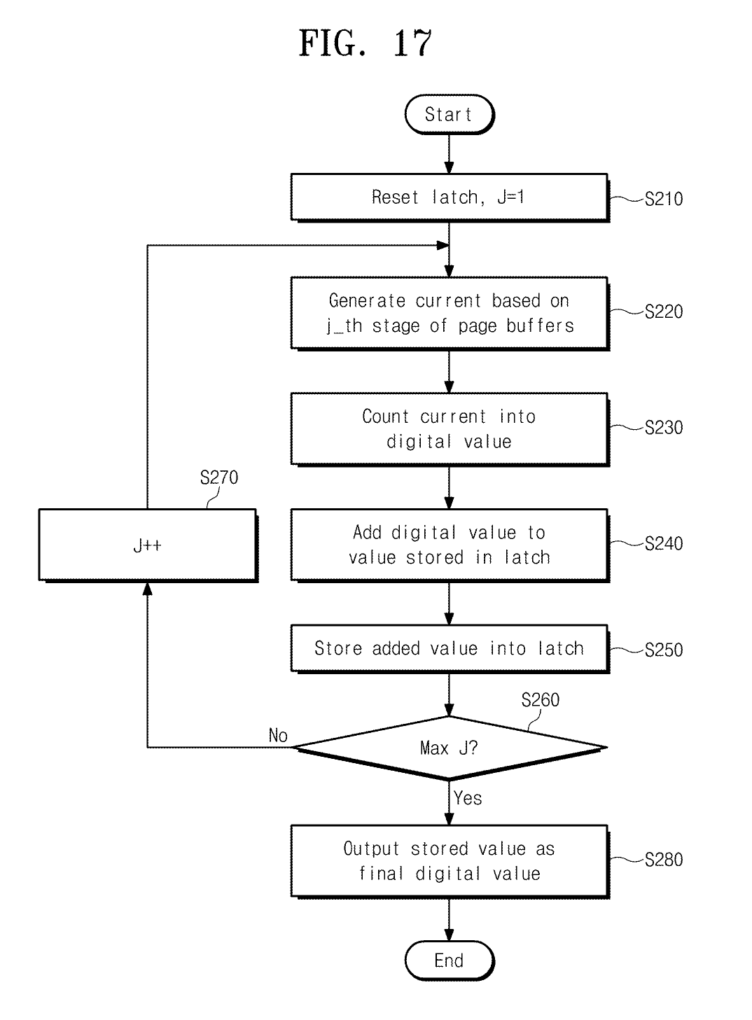

FIG. 17 is a flow chart illustrating the generating the current and decoding the generated current into the digital value shown in the step S140 of FIG. 16. Referring to FIG. 17, the latch 175 (shown in FIG. 7) is reset and a variable J is initialized to ‘1’ in a step S110.

The current (i.e., the decoder output signal DOUT) may be generated (e.g., be sunken) based on Jth stage STAGEJ of the page buffers PB1 through PBr. When the Jth transfer signal PFJ is activated in the page buffer unit 130, the page buffer decoding unit 140 may output the decoder output signal DOUT. The generated current, that is, the decoder output signal DOUT may correspond to the number of the fail bits of the verify-read result stored in the Jth stage of the page buffers PB1 through PBr.

The current is decoded into the digital value in a step S230. The analog bit counting unit 160 (shown in FIG. 6) may count the number of the fail bits from the decoder output signal DOUT, and output the counting results OUT1 through OUTm. The digital adding unit 170 (shown in FIG. 7) may decode the counting results OUT1 through OUTm into the digital value.

The digital value is added with the value stored in the latch 175 in a step S240. The digital adder 173 may add the digital value output from the decoder 171 and the value stored in the latch 175, and output the added value.

The added value is stored into the latch 175 in a step S250. The latch 175 may store the output of the adder 173 in response to the latch signal CL.

It is determined whether the variable J is max in a step S260. That is, it is determined whether the counting of the step S220 through S250 is performed to all stages of the page buffers PB1 through PBr. When the variable J is not max, the variable J increases in a step S270 and then the step S220 is reexecuted. When the variable J is max, the value stored in the latch 175 is output as the final digital value in a step S280.

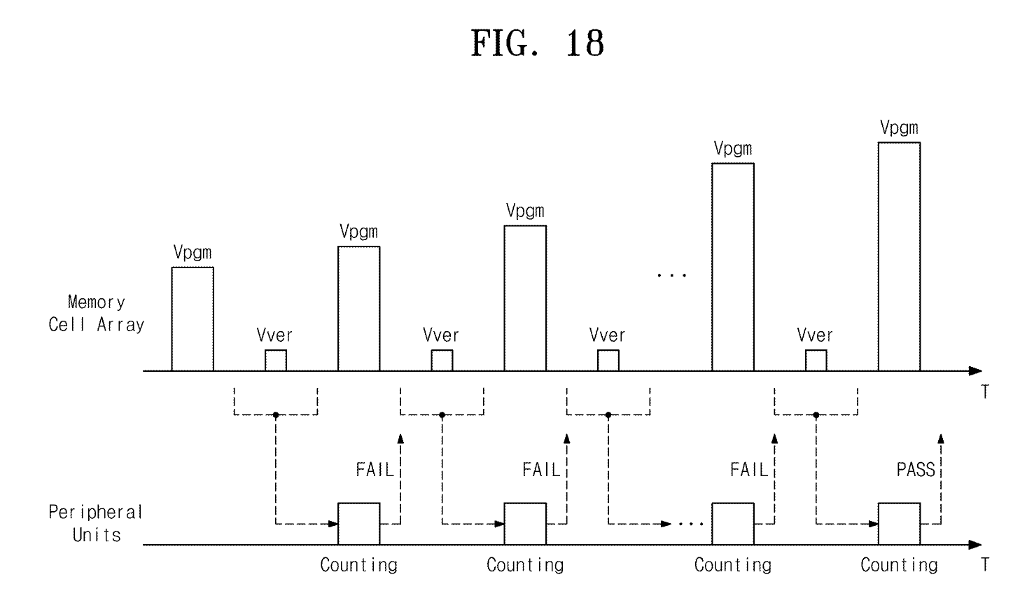

FIG. 18 is a timing diagram illustrating a first example of the program method of the inventive concepts. Referring to FIG. 18, the program voltage Vpgm is applied and the verify voltage Vver is applied to the memory cell array 105 (shown in FIG. 2). The applying of the program voltage Vpgm and the verify voltage Vver may form a program loop.

The counting is performed in a peripheral units, that is, in the page buffer decoding unit 140, analog bit counting unit 160 and digital adding unit 170 based on the verify-read result. For example, the number of the fail bits may be counted from the verify-read result. The program voltage Vpgm may be applied to the memory cell array 105 during the counting is performed in the peripheral units.

When the digital value, which is result of the counting, is more than the bypass value, that is, when the number of the fail bits is more than the bypass value, the program fail is determined. When the program fail is determined, the verify voltage Vver may be applied to the memory cell array 105 additionally. The program voltage Vpgm may be applied to the memory cell array 105 during the counting caused by the additionally applied verify voltage and the following verify-read result.

The counting of the fail bits may be performed during the program voltage Vpgm is applied. Thus, a separate time for the counting of the fail bits is not needed.

When the digital value, which is the result of the counting, is equal to or less than the bypass value, that is, when the number of the fail bits is equal to or less than the bypass value, the program pass is determined. When the program pass is determined, the verify voltage Vver may not be applied and the program operation may be ended.

When the number of the fail bits is less than the bypass value, the program pass is determined. Thus, time delay due to the slow memory cells is prevented.

The counting is performed overlapped (or concurrently) with the applying of the program voltage Vpgm. Thus, even though the program pass is determined, the program voltage Vpgm may be applied once more during execution of the determination. Thus, the number of program-failed memory cells may be reduced.

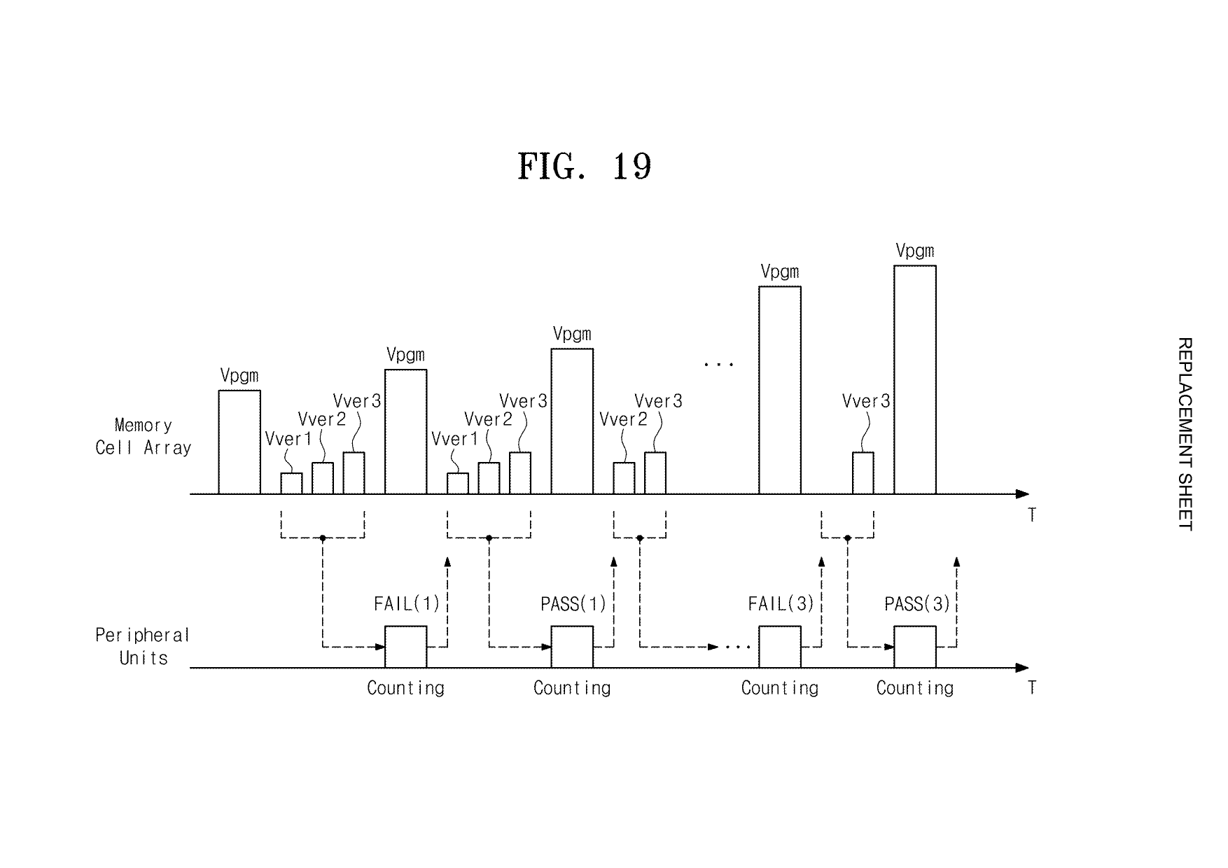

FIG. 19 is a timing diagram illustrating a second example of the program method of the inventive concepts. Referring to FIG. 19, the memory cells MC (shown in FIG. 2) may include multi-level cells MLC. The memory cells may be programmed and verified using at least one program voltage and at least one verify voltage to a plurality of program states simultaneously.

Memory cells programmed to a first program state may be verified using a first verify voltage Vver1. Memory cells programmed to a second program state may be verified using a second verify voltage Vver2. Memory cells programmed to a third program state may be verified using a third verify voltage Vver3.

The counting may be performed to a verify-read result corresponding to the lowest verify voltage Vver1 among verify-read results according to the plurality of verify voltages Vver1 through Vver3. Based on the verify-read result of the first verify voltage Vver1, the number of the fail bits to be programmed to the first program state may be compared with the bypass value. The program pass or program fail of the first program state may be determined according to the comparison result.

When the verify-read result of the first verify voltage Vver1 is determined the program fail, the program loop may be reexecuted and the counting corresponding to the first verify voltage Vver1 may be reperformed. When the verify-read result of the first verify voltage Vver1 is determined the program pass, the first verify voltage Vver1 may not be applied any more. Then, the counting may be performed to a verify-read result corresponding to the next lowest verify voltage Vver2. Based on the verify-read result of the second verify voltage Vver2, the number of the fail bits to be programmed to the second program state may be compared with the bypass value. The program pass or program fail may be determined according to the comparison result.

When the verify-read result of the second verify voltage Vver2 is determined the program fail, the program loop may be reexecuted and the counting corresponding to the second verify voltage Vver2 may be reperformed. When the verify-read result of the second verify voltage Vver2 is determined the program pass, the second verify voltage Vver2 may not be applied any more. Then, the counting may be performed to a verify-read result corresponding to the next lowest verify voltage Vver3. Based on the verify-read result of the third verify voltage Vver3 the number of the fail bits to be programmed to the third program state may be compared with the bypass value. The program pass or program fail may be determined according to the comparison result.

When the verify-read result of the third verify voltage Vver3 is determined the program fail, the program loop may be reexecuted and the counting corresponding to the third verify voltage Vver3 may be reperformed. When the verify-read result of the third verify voltage Vver2 is determined the program pass, the third verify voltage Vver3 may not be applied any more. Then, the counting may be performed to a verify-read result corresponding to the next lowest verify voltage. If there are no verify voltage applied, that is, the memory cells are program passed, the program operation may be ended.

For example, a number of program states programmed concurrently is not limited. When the memory cells are programmed to k program states simultaneously, the program operation and verify operation may be performed using k verify voltages.

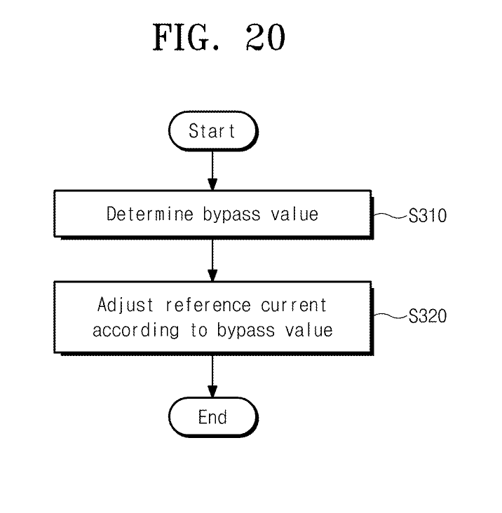

FIG. 20 is a flow chart illustrating an example of operating method of the current generating unit 150 and control unit 190 shown in FIG. 1. Referring to FIGS. 1, 5 and 20, the bypass value is determined in a step S310. For example, the bypass value may be determined by the control unit 190. The bypass value may be determined by a program circuit like a mode register set MRS (not shown).

The reference current RC is adjusted according to the determined bypass value in a step S320.

According to the determined bypass value, the number of the fail bits to be counted in the analog bit counting unit 160 may be adjusted. When the number of the fail bits to be counted in the analog bit counting unit 160 is adjusted, effects of noises may vary. By adjusting the amount of the reference current RC according to the number of the fail bits to be counted, the variation of the noises may be compensated. For example, the resistances of the feedback variable resistor 153 may be adjusted when the current option signals COS1 through COS4 are adjusted. When the resistances of the feedback variable resistor 153 is adjusted, the reference current signal RCS is adjusted and then the amount of the reference current RC may be adjusted.

For example, the control unit 190 may adjust the reference current signal RCS according to a prestored table when the bypass value is determined. The control unit 190 may adjust the reference current signal RCS adaptively.

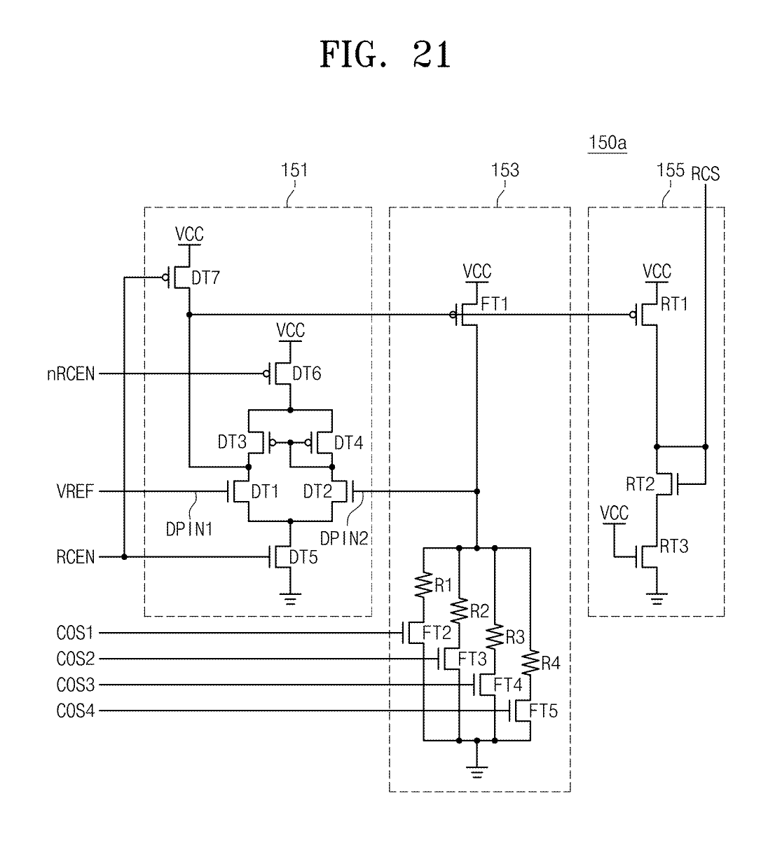

FIG. 21 is a circuit diagram illustrating a second embodiment of the current generating unit 150 according to the inventive concepts. When compared with the current generating unit 150 shown in FIG. 5, the maximum current signal generator 159 may not be provided in the current generating unit 150a according to the second embodiment. The current generating unit 150a may be configured to output the reference current signal RCS without outputting the maximum current signal MCS.

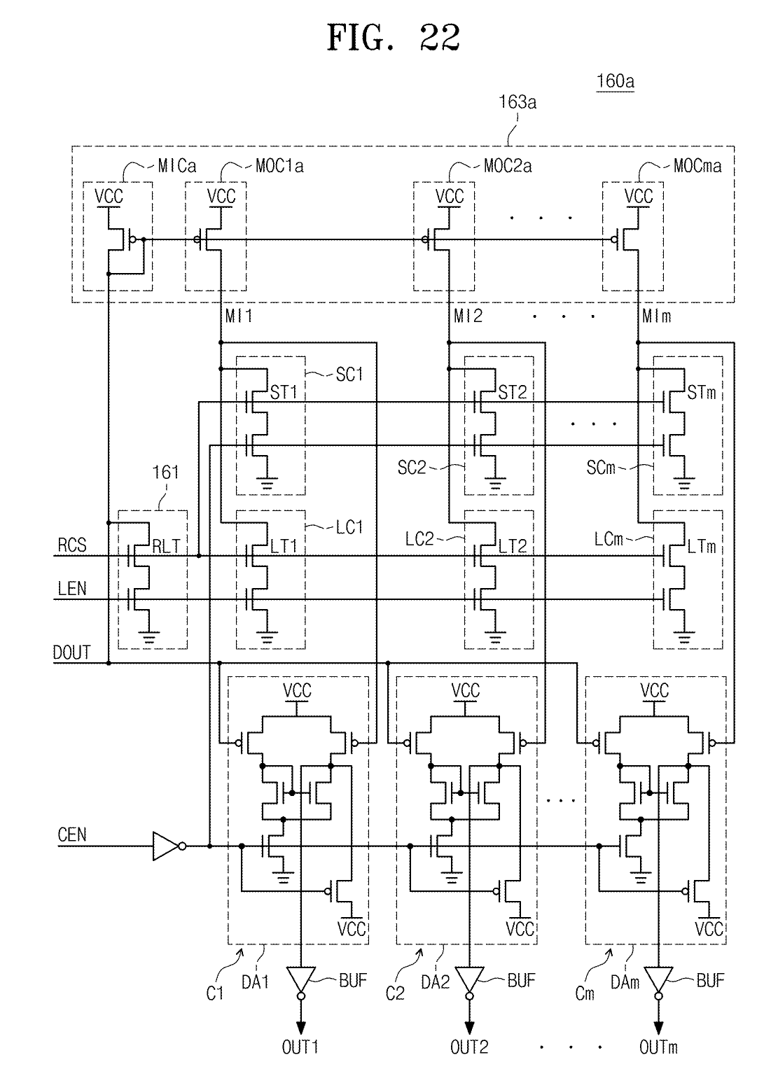

FIG. 22 is a circuit diagram illustrating a second embodiment of the analog bit counting unit 160 according to the inventive concepts. When compared with the analog bit counting unit 160 shown in FIG. 6, the transistors limiting the maximum amount of the currents may not be provided in the mirror input circuit MICa and the first through mth mirror output circuits MOC1a through MOCma of the analog bit counting unit 160a according to the second embodiments. The maximum current signal MCS may not be provided.

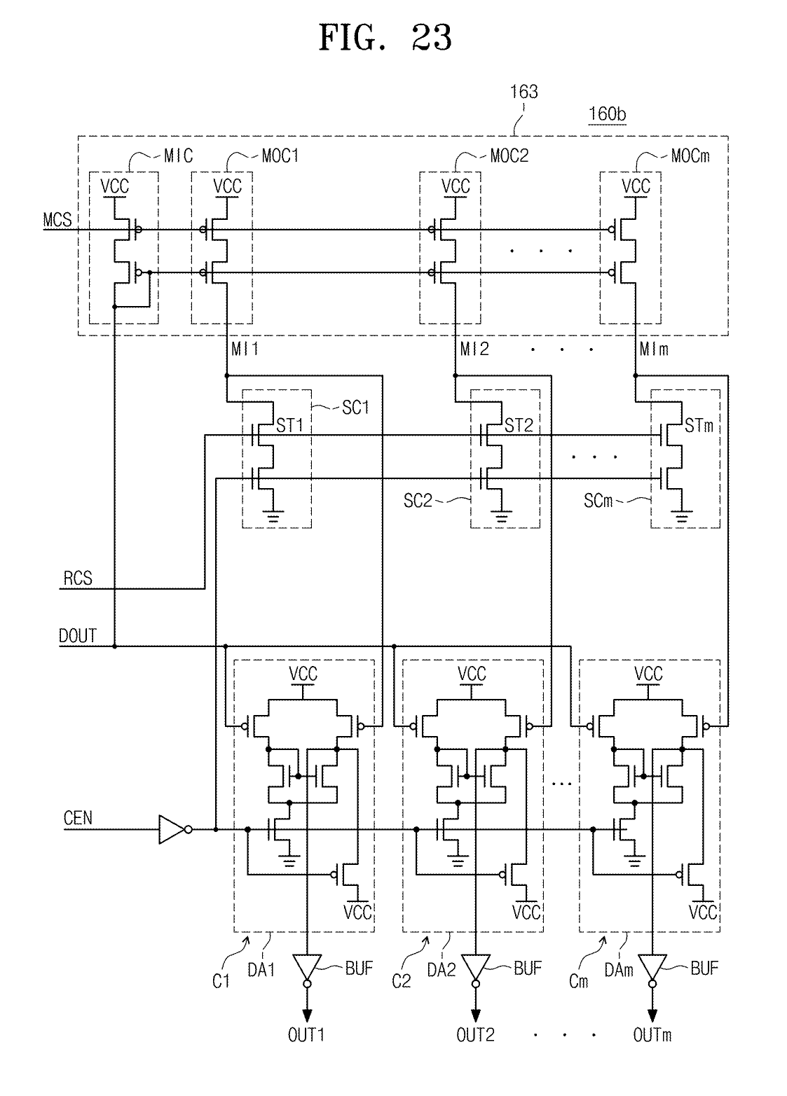

FIG. 23 is a circuit diagram illustrating a third embodiment of the analog bit counting unit 160 according to the inventive concepts. When compared with the analog bit counting unit 160 shown in FIG. 6, the reference load circuit 161 and the first through mth load circuits LC1 through LCm may not be provided in the analog bit counting unit 160b according to the third embodiment. The load enable signal LEN may not be provided.

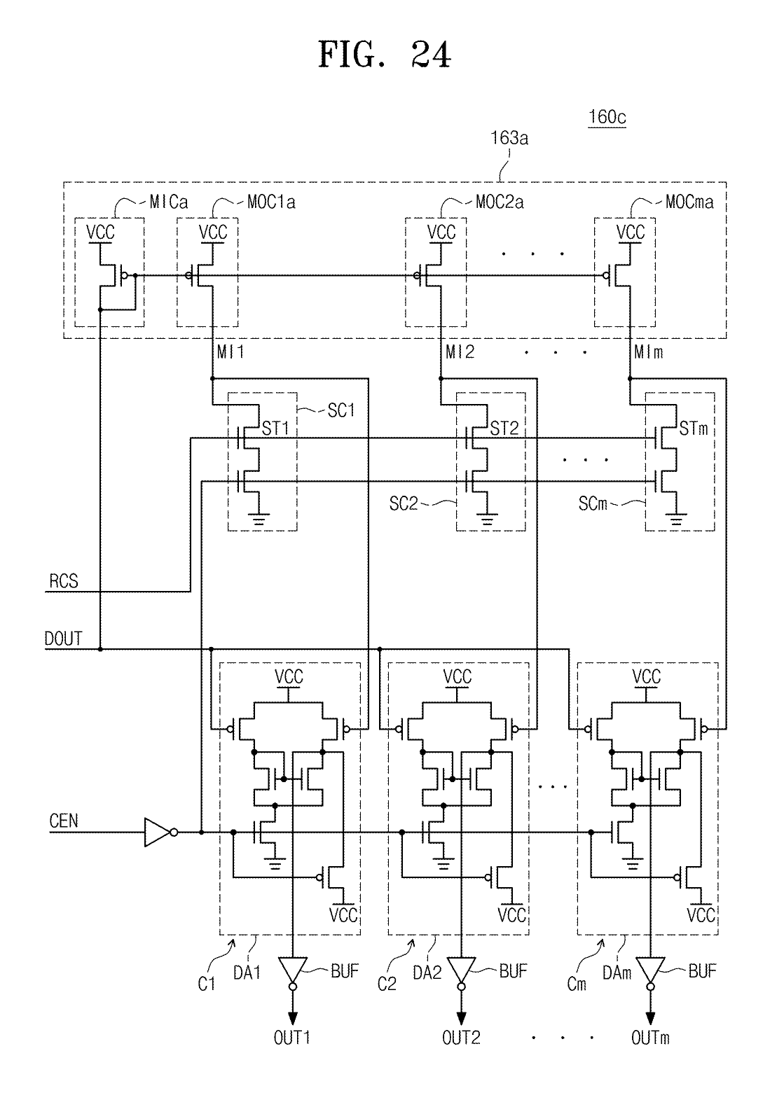

FIG. 24 is a circuit diagram illustrating a fourth embodiment of the analog bit counting unit 160 according to the inventive concepts. When compared with the analog bit counting unit 160 shown in FIG. 6, the reference load circuit 161 and the first through mth load circuits LC1 through LCm may not be provided in the analog bit counting unit 160b according to the fourth embodiment. The load enable signal LEN may not be provided.

The transistors limiting the maximum amount of the currents may not be provided in the mirror input circuit MICa and the first through mth mirror output circuits MOC1a through MOCm. The maximum current signal MCS may not be provided.

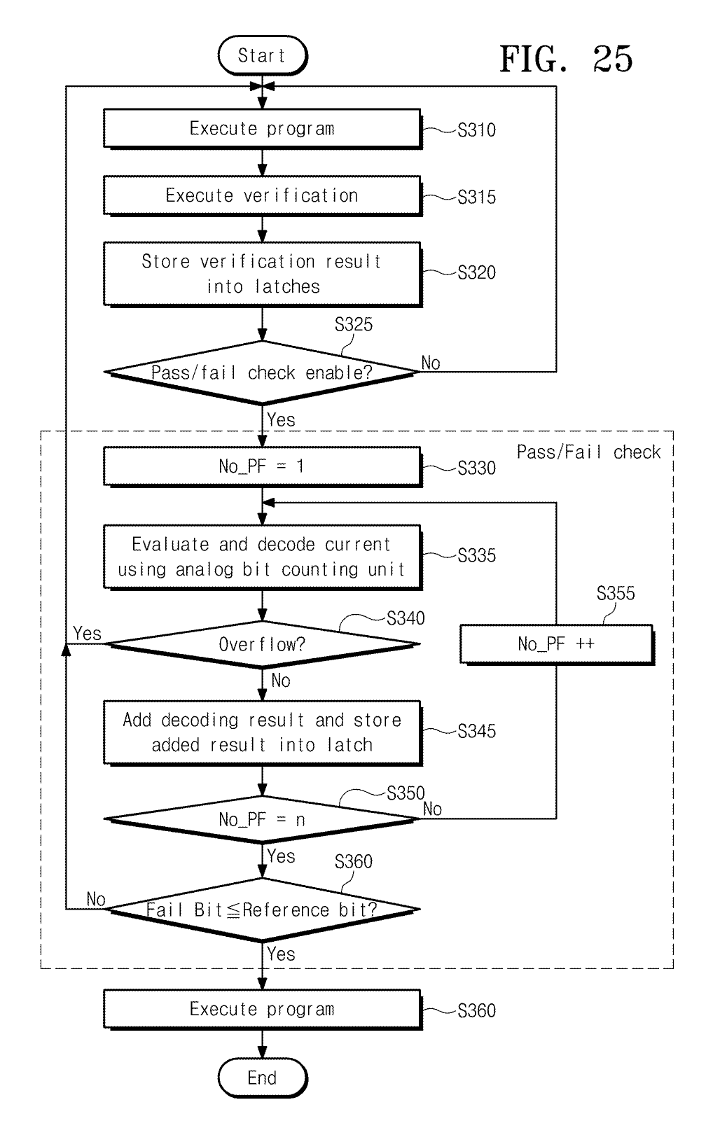

FIG. 25 is a flow chart illustrating a second embodiment of the programming method according to the inventive concepts. Referring to FIGS. 1 and 25, the program is executed in a step S310. The program voltage Vpgm may be applied to the selected word line of the memory cell array 105.

The verification is executed in a step S315. The verification may be executed to memory cells connected to the selected memory cells.

The verify-read result may be stored in the latches in a step S320. For example, the verify-read result may be stored in the second latches L2 (shown in FIG. 3).

It is determined whether a pass/fail check is enabled in a step S325. When the pass/fail check is enabled, a step S330 is performed. When the pass/fail check is not enabled, the step S310 may be reexecuted. For example, when a number of the program loop executed is equal to or less than a reference value, the pass/fail check may be disabled. When the number of the program loop executed is over the reference value, the pass/fail check may be enabled.

In the step S330, the transfer variable No_PF is initialized. For example, the transfer variable No_PG may be initialized to ‘1’. The transfer signal (e.g., PF1) corresponding to the transfer variable may be activated. Upon activation of the transfer signal (e.g., PF1), the page buffer decoding unit 140 may output the current (i.e., the decoder output signal DOUT).

The currents are evaluated and decoded using the analog bit counting unit 160 in a step S335. For example, the analog bit counting unit 160 may evaluate the currents output from the page buffer decoding unit 140 and decode the evaluation result.

It is determined whether an overflow occurs in a step S340. For example, it is determined whether the currents output from the page buffer decoding unit 140 is over a countable range of the analog bit counting unit 160. When the overflow occurs, the program may be reexecuted in the step S310. When the overflow does not occur, a step S345 may be performed.

The decoding results are added up and the added up result is stored in the latch in a step S345. The digital adding unit 170 may add the output from the analog bit counting unit 160 with the value stored in the latch 175 (shown in FIG. 7), then store the added result into the latch 175.

It is determined whether the transfer variable No_PF is max (e.g., n). That is, it is determined whether each of the transfer signals PF1 through PFn is activated once. When the transfer variable No_PF is not max, the transfer variable No_PF increases in a step S355. Then, the transfer signal (e.g., PF2) corresponding to the increased transfer variable No_PF is activated, and the page buffer decoding unit 140 may output the current. When the transfer variable No_PF is max, a step S360 is performed.

It is determined whether the fail bits are equal to or less than reference bits. The pass/fail checking unit 180 may determine whether the output from the digital adding unit 170 is equal to or less than the value stored in the bypass register 183 (shown in FIG. 8). When the fail bits (e.g., the number of the fail bits) are not equal to or less than the reference bits (e.g., a number of the reference bits), the program is reexecuted in the step S310. When the fail bits are equal to or less than the reference bits, the program is executed once more and the program is ended in a step S365.

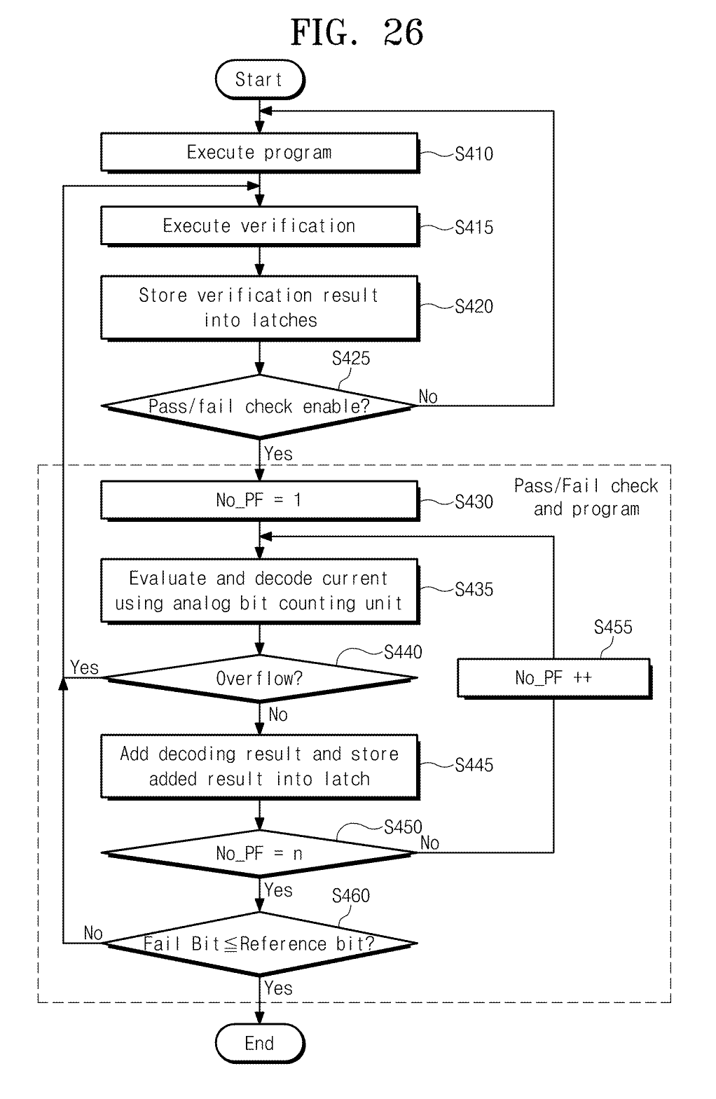

FIG. 26 is a flow chart illustrating a third embodiment of the programming method according to the inventive concepts. Steps S410 through S435 and steps s445 through S455 may be performed similarly to the steps S310 through S335 and the steps S345 through S355 shown in FIG. 25.

In steps S430 through S460, the program may be executed during the pass/fail check is performed. Thus, when the overflow occurs in the step S440, the verification of the step S415 may be executed instead of the program of the step S410. Furthermore, when the fail bits (e.g., the number of the fail bits) are not equal to or less than the reference bits (e.g., the number of the reference bits) in the step S460, the verification of the step S415 may be executed instead of the program of the step S410. If the program is executed during the pass/fail check is performed, program time may reduce.

FIG. 27 is a block diagram illustrating a nonvolatile memory device 100a according to another embodiment of the inventive concepts. The nonvolatile memory device 100a may be configured similarly to the nonvolatile memory device 100 shown in FIG. 1, except for the page buffer decoding unit 140a, the digital adding unit 170a, the pass/fail checking unit 180a and the control unit 190a.

Like the page buffer decoding unit 140 shown in FIG. 1, the page buffer decoding unit 140a may output the decoder output signal DOUT in response to the page buffer signal PBS. The page buffer decoding unit 140a may further generate a sum signal SUM and a carry signal CARRY in response to the page buffer signal PBS. The sum signal SUM may be transferred to the digital adding unit 170a and the carry signal CARRY may be transferred to the pass/fail checking unit 180a.

The digital adding unit 170a may add up the counting result OUT from the analog bit counting unit 160 or the sum signal SUM under a control of the control unit 190a. The added up result may be output as the fail bit signal FBS.

The pass/fail checking unit 180a may determine the program pass or program fail based on the fail bit signal FBS or the carry signal CARRY under a control of the control unit 190a.

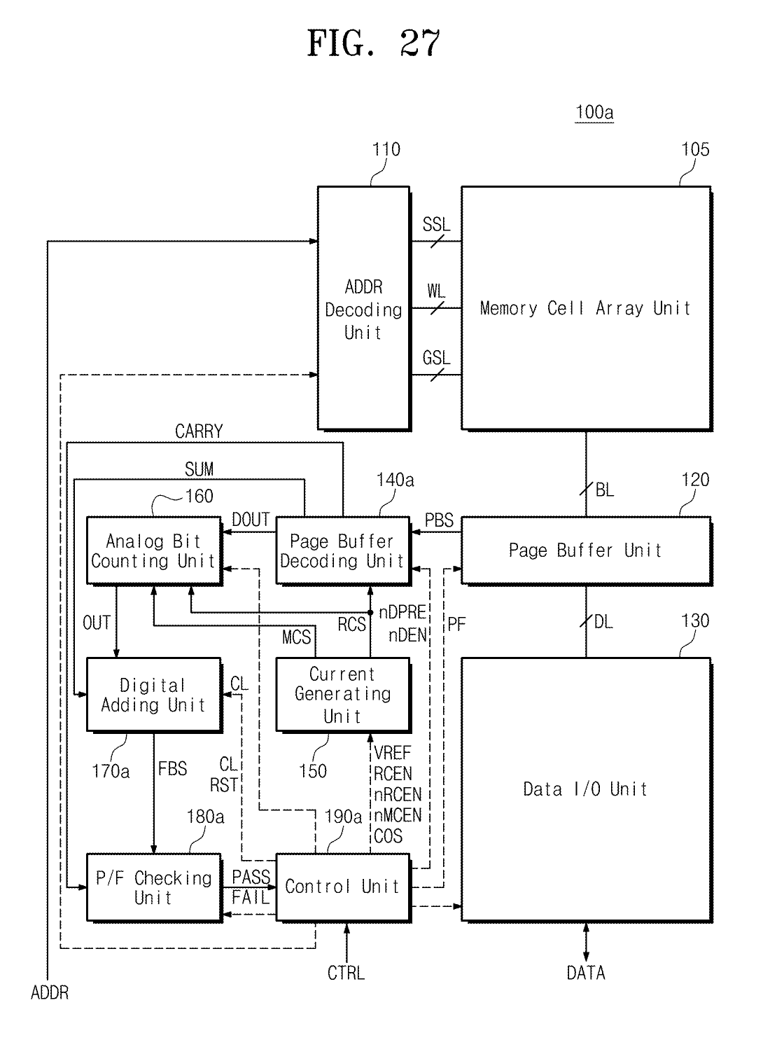

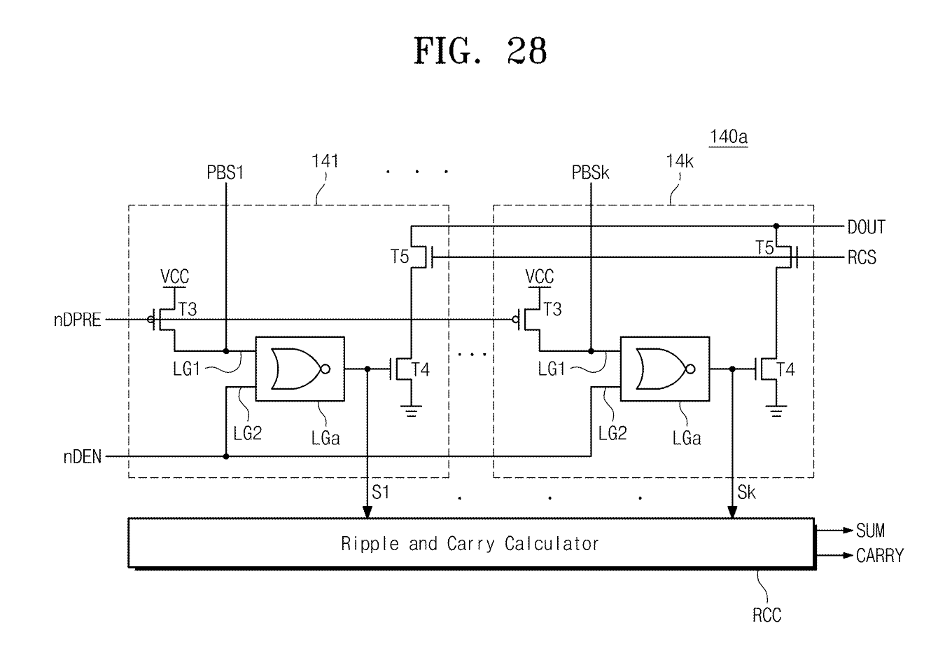

FIG. 28 illustrates an example of the page buffer decoding unit 140a shown in FIG. 27. When compared with the page buffer decoding unit 140 shown in FIG. 4, the page buffer decoding unit 140a may further include a ripple and carry calculator RCC.

The output signals of the logic gates LG may be transferred to the ripple and carry calculator RCC as first through kth signals S1 through Sk. The ripple and carry calculator may generate the sum signal SUM and the carry signal CARRY based on the first through kth signals S1 through Sk.

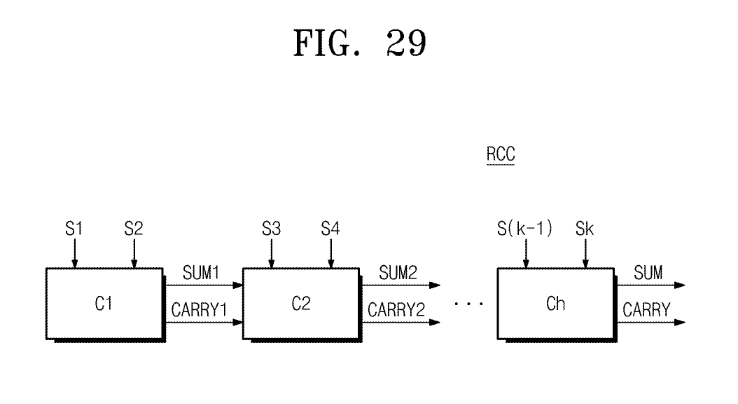

FIG. 29 is a block diagram illustrating an example of the ripple and carry calculator RCC shown in FIG. 28. Referring to FIGS. 27 through 29, signals output from directly adjacent logic gates LG of the page buffer decoding unit 140a are transferred to a calculator. For example, the first and second signals S1 and S2 are transferred to a first calculator C1, the third and fourth signals S3 and S4 are transferred to a second calculator C2, and the k−1th and kth signals Sk−1 and Sk are transferred to a hth calculator Ch.

The first calculator C1 may add the first and second signals S1 and S2, and output the added result as the first sum signal SUM. For example, the first calculator C1 may output a result of an exclusive logical sum XOR of the first and second signals S1 and S2 as the first sum signal SUM1. When the first and second signals S1 and S2 are logic high, the first calculator C1 may output logic high as a first carry signal CARRY1.

The second calculator C2 may calculate an XOR of the third and fourth signals S3 and S4. The second calculator C2 may output the XOR result as the second sum signal SUM2. When the third and fourth signals S3 and S4 are logic high or when the XOR result and the first sum signal SUM1 are logic high, the second calculator C2 may output logic high as a second carry signal CARRY2. When the first carry signal CARRY1 is logic high, the second calculator C2 may output logic high as the second carry signal CARRY2.

The hth calculator Ch may operate similar to the second calculator C2 except that the hth calculator outputs the sum signal SUM and the carry signal CARRY instead of internal sum and carry signals referred as SUM# and CARRY#. The hth calculator Ch may output the sum signal SUM and the carry signal CARRY based on output signals from the page buffer decoding unit 140a and output signals of prior calculator (e.g., the internal sum and carry signals).

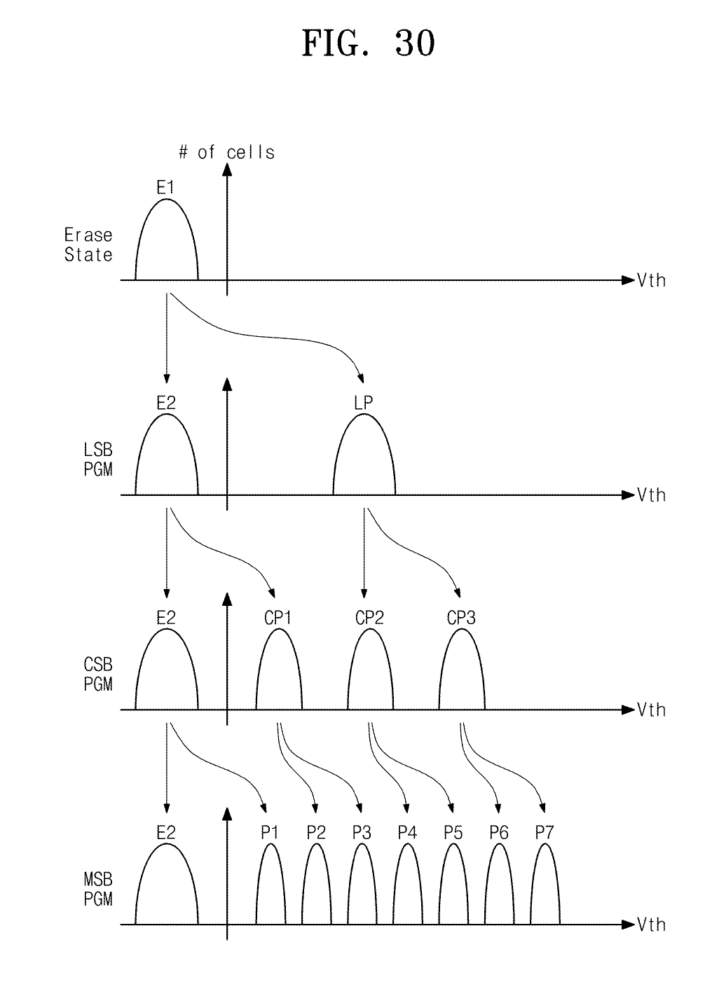

FIG. 30 is a diagram illustrating a first embodiment of logic states programmed to the memory cells according to the inventive concepts. In FIG. 30, a horizontal axis indicates logic states of the memory cells, more particularly threshold voltages of the memory cells. The logic states of the memory cells may be distinguished based on the threshold voltages. A vertical axis indicates a number of memory cells. In other words, the curved figures denote exemplary threshold voltage distributions of memory cells a each logic state.

Memory cells of a first erase state E1 may be programmed to a second erase state E2 or a least significant program state LP by a least significant bit LSB program. Threshold voltages of the second erase state E2 may be higher than that of the first erase state E1. A distribution of the threshold voltages of the second erase state E2 may be narrower than that of the second erase state E2.

Memory cells of the second erase state E2 may be programmed to a third erase state E3 or a first central significant program state CP1 by a central significant bit CSB program. Threshold voltages of the third erase state E3 may be higher than that of the second erase state E2. A distribution of the threshold voltages of the third erase state E3 may be narrower than that of the second erase state E2.

Memory cells of the least significant program state LP may be programmed to a second central significant program state CP2 or a third central significant program state CP3 by the CSB program.

Memory cells of the third erase state E3 may be programmed to a fourth erase state E4 or a first program state P1 by a most significant bit MSB program. Threshold voltages of the fourth erase state E4 may be higher than that of the third erase state E3. A distribution of the threshold voltages of the fourth erase state E4 may be narrower than that of the third erase state E3.

Memory cells of the first central significant program state CP1 may be programmed to a second program state P2 or a third program state P3 by the MSB program. Memory cells of the second central significant program state CP2 may be programmed to a fourth program state P4 or a fifth program state P4 by the MSB program. Memory cells of the third central significant program state CP3 may be programmed to a sixth program state P6 or a seventh program state P7 by the MSB program.

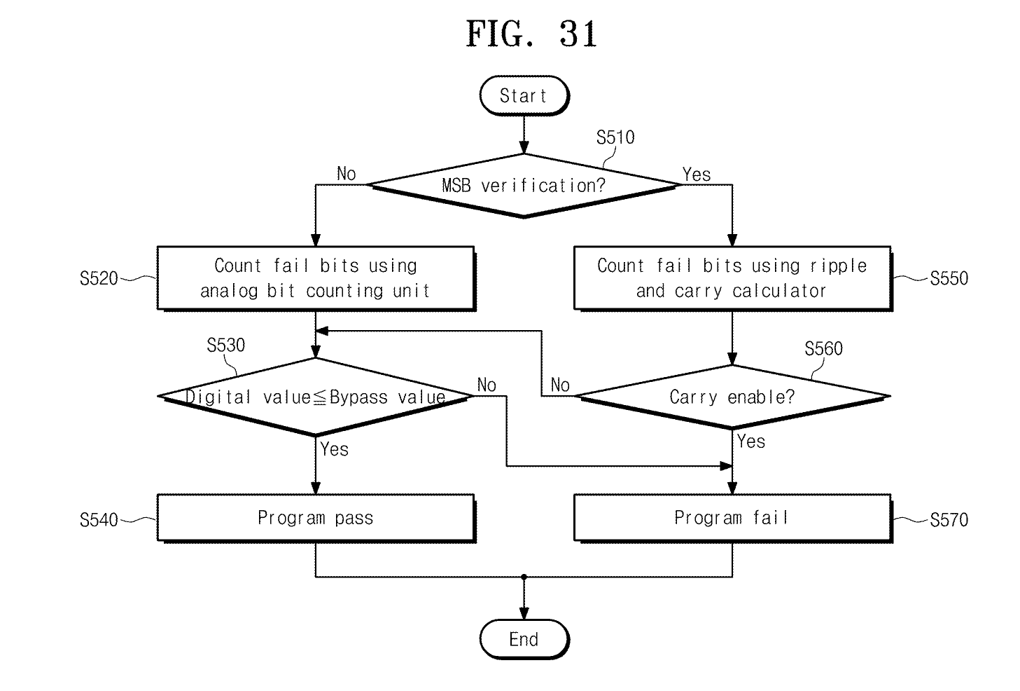

FIG. 31 is a flow chart illustrating a first embodiment of a verification method according to the inventive concepts. Referring to FIGS. 27 and 31, it is determined whether a MSB verification, which is a verification corresponding to the MSB program, is executed. In a step S510. When the MSB verification is not executed, a step S520 is performed. When the MSB verification is to be executed, a step S550 is performed.

In the step S520, the fail bits are counted using the analog bit counting unit 160. For example, the fail bits may be counted by the same method described referring to FIGS. 1 through 26. The digital value, which is the counting result, and the bypass value are compared. When the digital value is equal to or less than the bypass value, the program pass is determined in a step S540. When the digital value is over the bypass value, the program fail is determined in a step S570.

In the step S550, the fail bits are counted using the ripple and carry calculator RCC (shown in FIGS. 28 and 29). It is determined whether the carry signal CARRY is activated. When the carry signal CARRY is activated, the program fail is determined in the step S570. That is, when two or more fail bits are detected in each stage of the page buffers PB1 through PBr, the program fail is determined and the verification may be ended. When the carry signal CARRY is not activated, the step S530 is executed. For example, the digital adding unit 170a may add up the sequentially transferred sum signals SUM from the page buffer decoding unit 140a. The digital value, which is the added up result, may be compared with the bypass value and the program pass or program fail may be determined according to the comparison result.

When a LSB verification or a CSB verification, which correspond to the MSB program and CSB program respectively, is executed, the program pass or program fail may be determined based on the comparison of the number of the fail bits and the bypass value. When the MSB verification is executed, the program pass or program fail may be determined based on the activation of the carry signal CARRY and the comparison of the number of the activation of the sum signal SUM and the bypass value.

For example, the counting using the analog bit counting unit 160 or the counting using the ripple and carry calculator RCC may be selected based on whether the MSB verification is executed. For example, when the memory cells are set to store i bits data, the counting using the analog bit counting unit 160 or the counting using the ripple and carry calculator RCC may be selected whether a verification over a j bit (j is an integer equal to or less than i) is executed.

An increment of a program voltage during the MSB program may be lower than an increment of the program voltage during the LSB or CSB programs. That is, a verification mode may be selected based on the increments of the program voltage. A verify voltage (e.g., the highest verify voltage) of the MSB verification may be higher than that of the LSB and CSB verifications. That is, the verification mode may be selected based on the level of the verify voltage. The program voltage (e.g., an initial program voltage) of the MSB program may be higher than that of the LSB and CSM programs. That is, the verification mode may be selected based on the level of the program voltage. The verification mode may be selected according to received addresses.

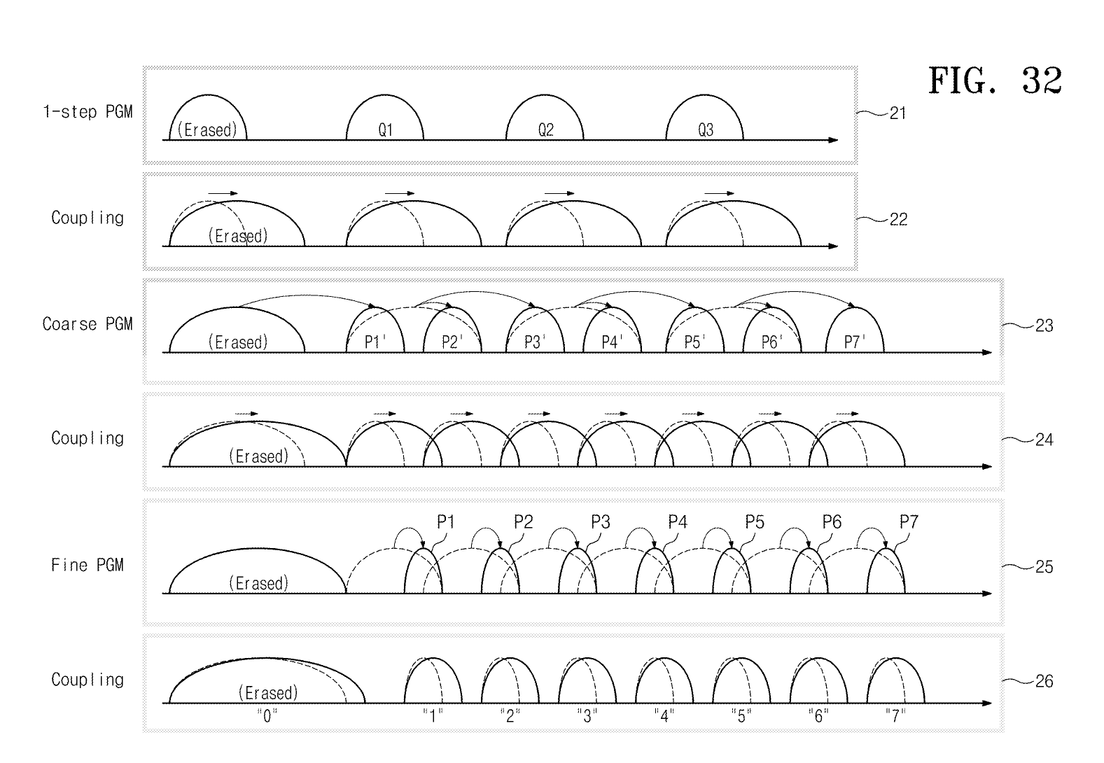

FIG. 32 is a diagram illustrating a second embodiment of logic states programmed to the memory cells according to inventive concepts. Referring to FIG. 32, the memory cells may be programmed according to a 3-step program.

A 1-step program is executed on a first word line. 2 page data (e.g., first and second page data) may be programmed into memory cells of the first word line. As shown in box 21, memory cells may be programmed to have threshold voltages included in threshold voltage distributions corresponding to erase state E and program states Q1, Q2 and Q3.

After the 1-step program of the first word line, the 1-step program may be performed on a second word line adjacent to the first word line. When the 1-step program is executed on the second word line, threshold voltage distributions of the 1-step programmed memory cells of the first word line may be broadened due to a coupling of the 1-step program on the second word line as shown in a box 22.

After the 1-step program on the second word line, a 2-step program (or coarse program) may be executed on the first word line. 1 page data, that is, third page data may be programmed into memory cells of the first word line. As shown in box 23, memory cells included in the threshold voltage distributions corresponding each state may be programmed to have threshold voltages included in corresponding threshold voltage distributions.

For example, memory cells included in the threshold voltage distribution corresponding to the erase state E may be programmed to have threshold voltages included in threshold voltage distributions corresponding to the erase state E or a program state P1′ respectively according to data to be programmed. Memory cells included in the threshold voltage distribution corresponding to the program state Q1 may be programmed to have threshold voltages included in threshold voltage distributions corresponding to the program states P2′ and P3′ respectively according to data to be programmed. Memory cells included in the threshold voltage distribution corresponding to the program state Q2 may be programmed to have threshold voltages included in threshold voltage distributions corresponding to the program states P4′ and P5′ respectively according to data to be programmed. Memory cells included in the threshold voltage distribution corresponding to the program state Q3 may be programmed to have threshold voltages included in threshold voltage distributions corresponding to the program states P6′ and P7′ respectively according to data to be programmed.

After the 2-step program (or the coarse program) on the first word line, the 2-step program (or the coarse program) may be performed on the second word line. When the 2-step program (or the coarse program) is executed on the second word line, threshold voltage distributions of the 2-step programmed memory cells of the first word line may be broadened due to a coupling of the 2-step program on the second word line as shown in a box 24.

After the 2-step program on the second word line, a 3-step program (or a fine program) may be executed on the first word line. The memory cells of the first word line may be programmed to have final threshold voltage distributions P1 through P7 as shown in a box 25.

The fine program may need pre-programmed data (e.g., the first through third page data). For example, the pre-programmed data may be programmed into a specific area of the memory cell array 105 to be maintained. The specific area may be configured to have single level cells SLC. The specific area may be a buffer area configured to have the SLC. The specific area may be an On Chip Buffer area.

As shown in a box 26, the threshold voltage distributions of the fine programmed memory cells may be broadened due to a coupling of the 3-step program (or the fine program) on the memory cells of the second word line.

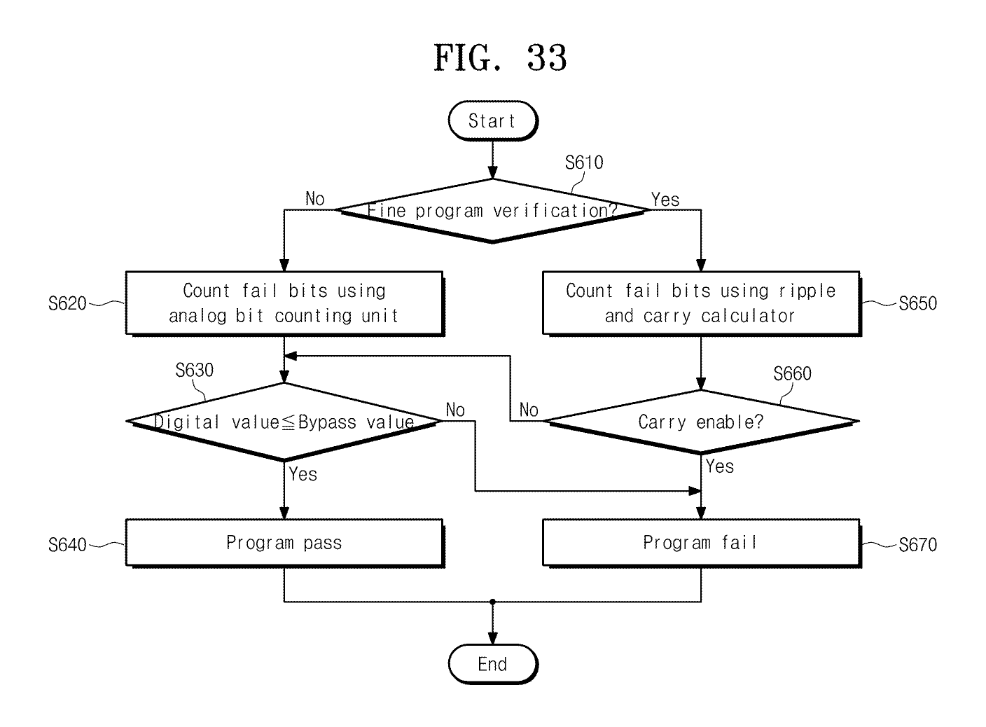

FIG. 33 is a flow chart illustrating a second embodiment of the verification method according to the inventive concepts. Referring to FIGS. 27 and 33, it is determined whether a verification of the fine program is executed in a step S610. When the verification the fine program is not executed, a step S620 is performed. When the verification of the fine program is executed, a step S650 is performed. Steps S620 through S670 may be performed in the same manner with the steps S520 thorough S570 shown in FIG. 31. That is, when a verification of the 1-step program or the 2-step program (or the coarse program) is executed, the counting is performed using the analog bit counting unit 160. When the verification of the 3-step program (or the fine program) is executed, the counting is performed using the ripple and carry calculator RCC (shown in FIGS. 28 and 29).

An increment of a program voltage during the fine program may be lower than an increment of the program voltage during the 1-step or coarse programs. That is, the verification mode may be selected based on the increments of the program voltage. A verify voltage (e.g., the highest verify voltage) of the verification of the fine program may be higher than that of the 1-step or coarse program. That is, the verification mode may be selected based on the level of the verify voltage. The program voltage (e.g., an initial program voltage) of the fine program may be higher than that of the 1-step or coarse program. That is, the verification mode may be selected based on the level of the program voltage. The verification mode may be selected according to received addresses.

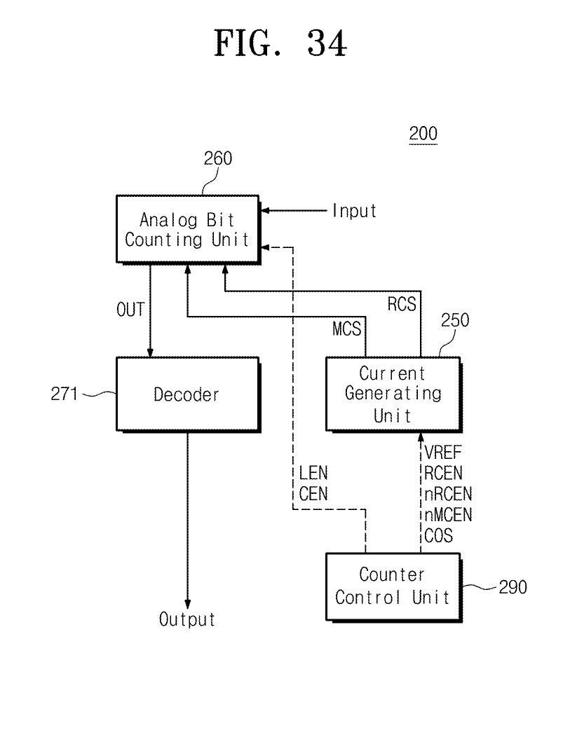

FIG. 34 is a block diagram illustrating a first embodiment of a counter 200 according to the inventive concepts. Referring to FIG. 34, the counter 200 includes a current generating unit 250, an analog bit counting unit 260, a decoder 271 and a counter control unit 290.

The current generating unit 250 may receive a reference voltage VREF, a reference current enable signal RCEN, an inverted reference current enable signal nRCEN, a maximum current enable signal nMCEN and a current option signal COS from the counter control unit 290. The current generating unit 250 may output a reference current signal RCS and a maximum current signal MCS. The current generating unit 250 may have the same structure and operate in the same manner as the current generating unit 150a shown in FIG. 21.

The analog bit counting unit 260 may receive input signal from an external device, receive the reference current signal RCS and maximum current signal MCS from the current generating unit 250 and receive a load enable signal LEN and a count enable signal CEN from the counter control unit 290. The analog bit counting unit 260 may count the input signal in a unit of a reference current RC corresponding to the reference current signal RCS, and output an output signal OUT indicating the counting result. The analog bit counting unit 260 may have the same structure and operate in the same manner as the analog bit counting unit 160, 160a or 160b shown in FIGS. 22 through 24.

The decoder 271 may receive the output signal OUT from the analog bit counting unit 260 and decoder the output signal OUT into a digital value. The decoder 271 may have the same structure and operate in the same manner as the decoder 171 shown in FIG. 7. An output of the decoder 271 may be output to an external device.

The counter control unit 290 may control various operations of the counter 200. The counter control unit 290 may control the reference voltage VREF, reference current enable signal RCEN, inverted reference current enable signal nRCEN, maximum current enable signal nMCEN, current option signal COS, load enable signal LEN and count enable signal CEN as described referring to FIGS. 1 through 24.

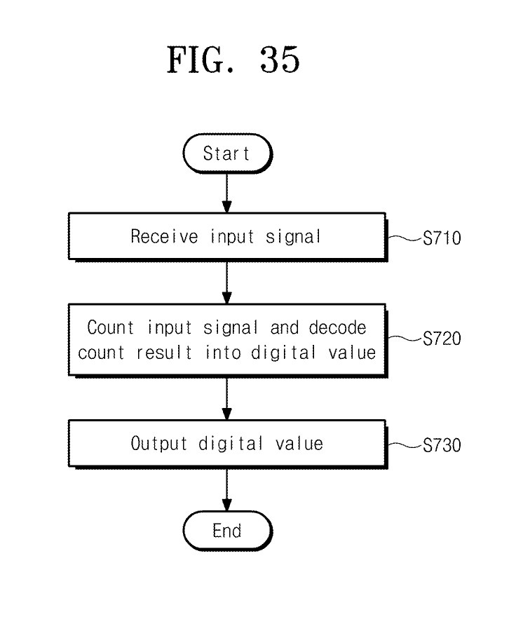

FIG. 35 is a flow chart illustrating an example of an operating method of the counter 200 shown in FIG. 34. Referring to FIGS. 34 and 35, the input signal is received in a step S710. The input signal may be a current.

In a step S720, the input signal is counted, and the counting result is decoded into the digital value. The analog bit counting unit 260 may count the input signal in an unit of the reference current RC. The decoder 271 may decode the output signal OUT of the analog bit counting unit 260 into the digital value.

In a step S730, the digital value is output.

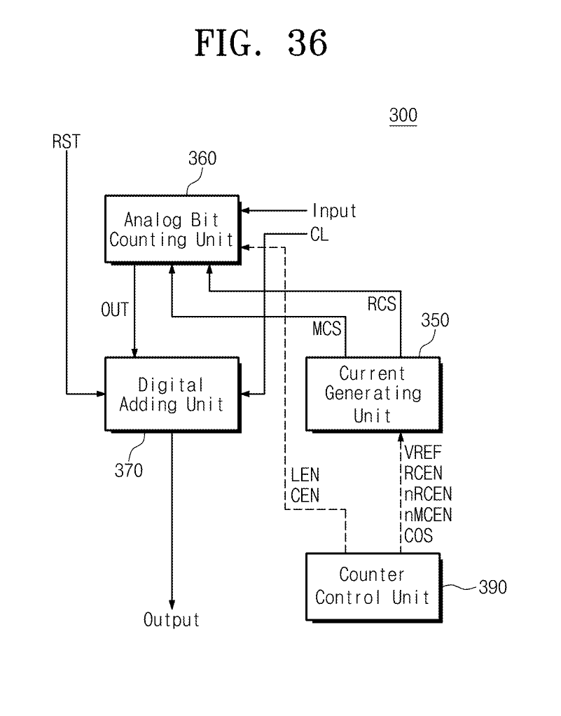

FIG. 36 is a block diagram illustrating a second embodiment of a counter 300 according to the inventive concepts. Referring to FIG. 36, the counter 300 may include a current generating unit 350, an analog bit counting unit 360, a digital adding unit 370 and a counter control unit 390.

When compared with the counter 200 shown in FIG. 34, the digital adding unit 370 is provided instead of the decoder 271. The digital adding unit 370 may decode the output signal OUT of the analog bit counting unit 360 into the digital value, and add up the digital value with a value stored in an internal latch (not shown). The digital adding unit 370 may store the added up value into the internal latch (not shown) in response to a latch signal CL. The value stored in the internal latch (not shown) may be output to an external device. The digital adding unit 370 may have the same structure and operate in the same manner as the digital adding unit 170 shown in FIG. 7.

The counter 300 may be an accumulation counter calculating an accumulated sum. When the latch signal CL is activated, the accumulated sum is calculated and output. The latch signal CL may be output from an external device. The accumulated sum may be reset in response to a reset signal RST received from an external device.

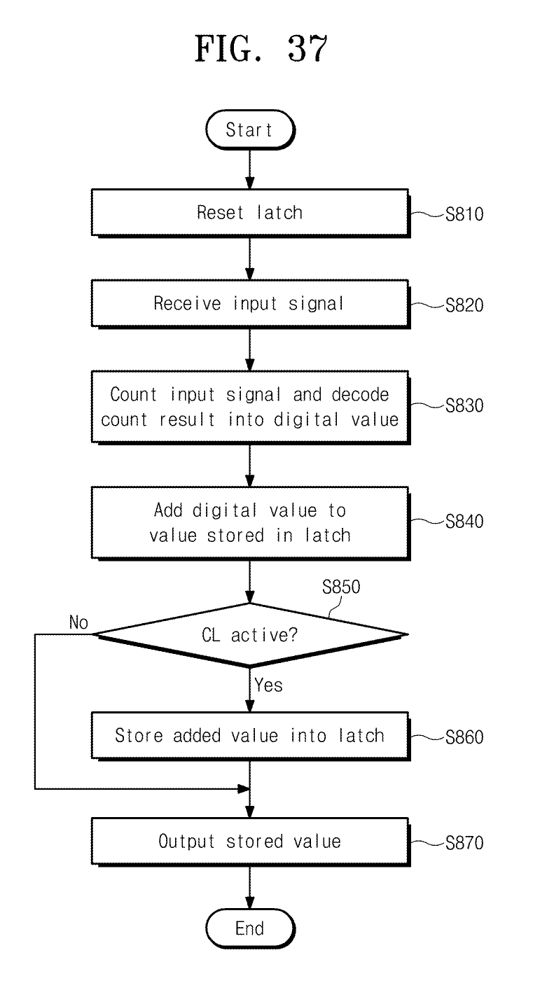

FIG. 37 is a flow chart illustrating an example of an operating method of the counter 300 shown in FIG. 36. Referring to FIGS. 36 and 37, the internal latch storing the accumulated sum is reset. For example, the internal latch of the digital adding unit 370 (the latch 175 shown in FIG. 7) may be reset.

In a step S820, the input signal is received. In a step S830, the input signal is counter, and the counting result is decoded into the digital value. The analog bit counting unit 360 may count the input signal in a unit of the reference current RC. The digital adding unit may decode the output signal OUT of the analog bit counting unit 360 into the digital value.

In a step S840, the digital value is added with the value stored in the latch. For example, the digital adding unit 370 may add up the digital value with the value stored in the internal latch.

In a step S850, it is determined whether the latch signal CL is activated. When the latch signal CL is activated, the added up value is stored in the internal latch in a step S860. Then, the value stored in the internal latch may be output in a step S870.

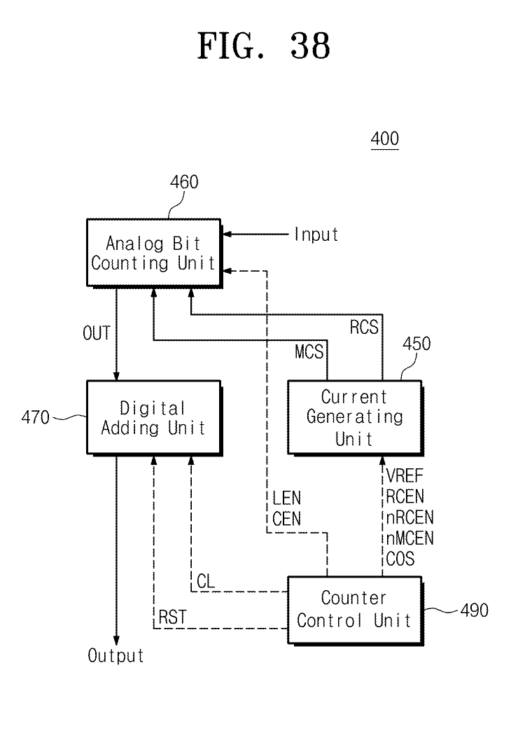

FIG. 38 is a block diagram illustrating a third embodiment of the counter 400 according to the inventive concepts. When compared with the counter 300 shown in FIG. 36, the latch signal CL and the reset signal RST may be provided to the analog bit counting unit 460 from the counter control unit 490.

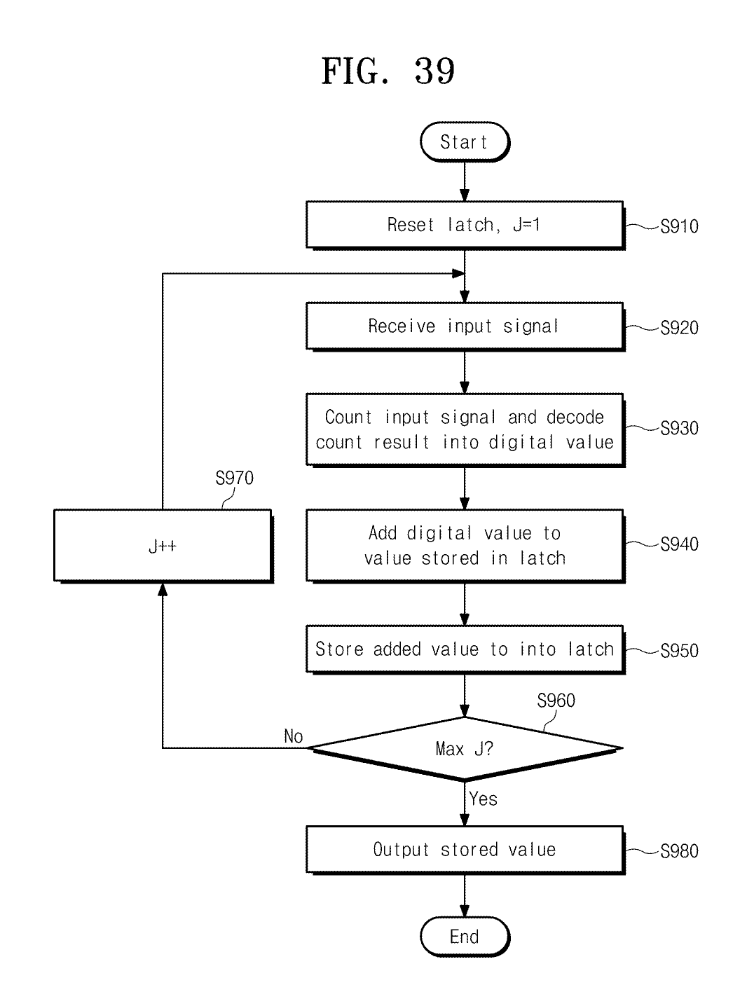

FIG. 39 is a flow chart illustrating an example of an operating method of the counter 400 shown in FIG. 38. Referring to FIGS. 38 and 39, the internal latch is reset and a variable J is initialized into ‘1’ in a step S910. For example, the internal latch of the digital adding unit (e.g., the latch 175 shown in FIG. 7) may be reset in response to the reset signal RST.

In a step S920, the input signal is received. In a step S930, the input signal is counted and the counting result is decoded into the digital value. The analog bit counting unit 460 may count the input signal in an unit of the reference current RC. The digital adding unit 470 may decode the output signal OUT of the analog bit counting unit 460 into the digital value.

In a step S940, the digital value is added with the value stored in the internal latch. For example, the digital adding unit 470 may add the digital value with the value stored in the internal latch (e.g., the latch 175 shown in FIG. 7).

In a step S950, the added value is stored in the internal latch. For example, the digital adding unit 470 may store the added value into the internal latch (e.g., the latch 175 shown in FIG. 7) in response to the latch signal CL.

In a step S960, it is determined whether the variable J is max. For example, a maximum value of the variable J may be a preset value in the counter control unit 490. The maximum value of the variable J may be stored in a program circuit like the mode register set MRS. When the variable J is not max, the variable J increases in a step S970 and the step S920 is reexecuted. When the variable J is max, the counter 400 may output the value stored in the internal latch (e.g., the latch 175 shown in FIG. 7) as a final output value in a step S980.

That is, the counter 400 may calculate an accumulated sum of the input signal for specific iterations.

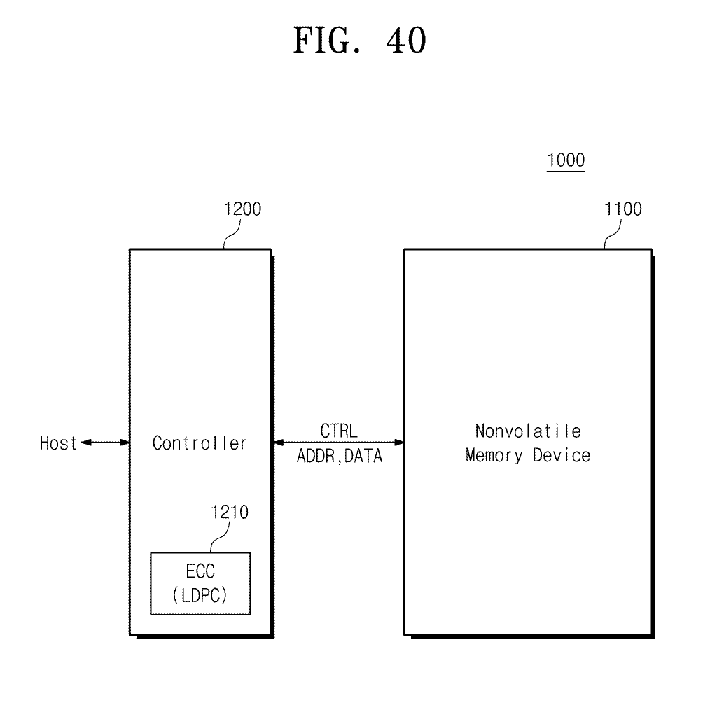

FIG. 40 is a block diagram illustrating memory systems according to example embodiments of the inventive concepts. Referring to FIG. 40, a memory system 1000 may include a nonvolatile memory device 1100 and a controller 1200. The nonvolatile memory device 1100 may have the same structure and operate in the same manner as the nonvolatile memory according to the inventive concepts. That is, the nonvolatile memory device 1100 may generate a current corresponding to fail bits and count the generated current to count a number of the fail bits.

The controller 1200 may be coupled with a host Host and the nonvolatile memory device 1100. The controller 1200 may be configured to access the nonvolatile memory device 1100 in response to a request from the host Host. The controller 1200 may be configured to control read, program, erase, and background operations of the nonvolatile memory portion 1100, for example. The controller 1200 may be configured to provide an interface between the nonvolatile memory portion 1100 and the host. The controller 1200 may be configured to drive firmware for controlling the nonvolatile memory portion 1100.

The controller 1200 may be configured to provide a control signals CTRL and an address ADDR to the nonvolatile memory portion 1100. The nonvolatile memory portion 1100 may perform read, program, and erase operations according to the control signal CTRL and the address ADDR provided from the controller 1200. The controller 1200 may further include a RAM, a processing unit, a host interface and a memory interface. The RAM may be used as at least one of a working memory of the processing unit, a cache memory between the nonvolatile memory portion 1100 and the host Host and/or a buffer memory between the nonvolatile memory portion 1100 and the host Host. The processing unit may control an overall operation of the controller 1200.

The host interface may include the protocol for executing data exchange between the host Host and the controller 1200. For example, the host interface may communicate with an external device (e.g., the host Host) via at least one of various protocols (e.g., a USB (Universal Serial Bus) protocol, an MMC (multimedia card) protocol, a PCI (peripheral component interconnection) protocol, a PCI-E (PCI-express) protocol, an ATA (Advanced Technology Attachment) protocol, a Serial-ATA protocol, a Parallel-ATA protocol, a SCSI (small computer small interface) protocol, an ESDI (enhanced small disk interface) protocol, and/or an IDE (Integrated Drive Electronics) protocol). The memory interface may interface with the nonvolatile memory device 1100. The memory interface may include a NAND interface or a NOR interface.

The memory system 1000 may further include an ECC block. The ECC block may be configured to detect and correct an error of data read from the nonvolatile memory device 1100 using ECC. The ECC block may be provided as an element of the controller 1200 and/or as an element of the nonvolatile memory device 1100. The controller 1200 and the nonvolatile memory device 1100 may be integrated into a single semiconductor device. The controller 1200 and the nonvolatile memory device 1100 may be integrated into a single semiconductor device to be, for example, a memory card. For example, the controller 1200 and the nonvolatile memory device 1100 may be integrated into a single semiconductor device to be, for example, a PC (PCMCIA) card, a CF card, an SM (or, SMC) card, a memory stick, a multimedia card (MMC, RS-MMC, MMCmicro), a security card (SD, miniSD, microSD, SDHC), a universal flash storage (UFS) device, and/or the like.

The controller 1200 and the nonvolatile memory device 1100 may be integrated into a single semiconductor device to form a solid state drive (SSD). The SSD may include a storage device configured to store data in a semiconductor memory. If the memory system 1000 is used as the SSD, it may be possible to remarkably improve an operating speed of a host Host coupled with the memory system 1000.

According to some example embodiments, the memory system 1000 may be used as, for example, a computer, portable computer, Ultra Mobile PC (UMPC), workstation, net-book, PDA, web tablet, wireless phone, mobile phone, smart phone, e-book, PMP (portable multimedia player), digital camera, digital audio recorder/player, digital picture/video recorder/player, portable game machine, navigation system, black box, 3-dimensional television, a device capable of transmitting and receiving information at a wireless circumstance, one of various electronic devices constituting home network, one of various electronic devices constituting computer network, one of various electronic devices constituting telematics network, RFID, and/or one of various electronic devices constituting a computing system.

A nonvolatile memory device 1100 or a memory system 1000 may be packed by various types of packages, for example, PoP (Package on Package), Ball grid arrays (BGAs), Chip scale packages (CSPs), Plastic Leaded Chip Carrier (PLCC), Plastic Dual In-Line Package (PDI2P), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), Thin Quad Flatpack (TQFP), System In Package (SIP), Multi Chip Package (MCP), Wafer-level Fabricated Package (WFP), Wafer-Level Processed Stack Package (WSP), and/or the like.

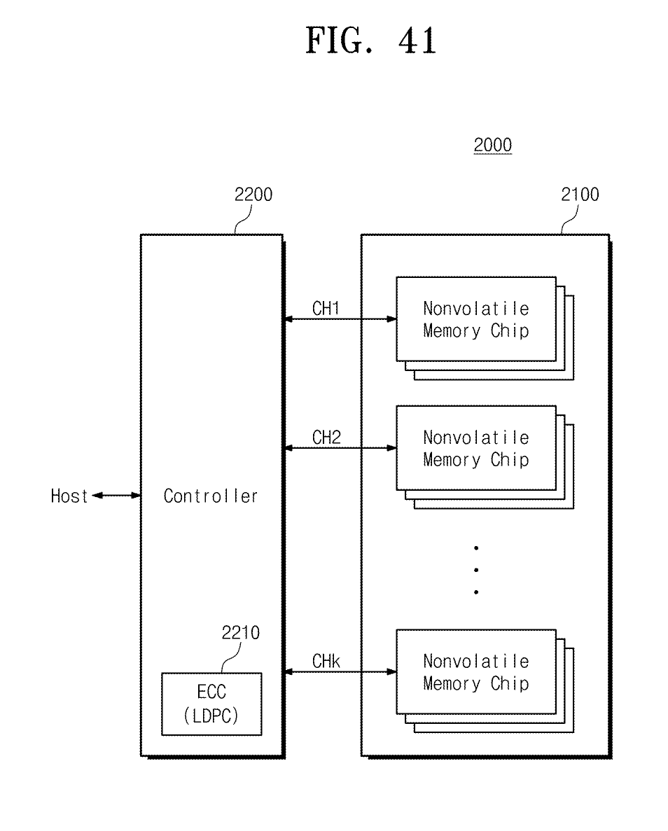

FIG. 41 is a block diagram illustrating applications of memory systems in FIG. 40. Referring to FIG. 41, a memory system 2000 may include a nonvolatile memory device 2100 and a controller 2200. The nonvolatile memory device 2100 may include a plurality of nonvolatile memory chips, which may be classified into a plurality of groups. Nonvolatile memory chips in each group may communicate with the controller 2200 via a common channel. In FIG. 41, an example may be illustrated in which a plurality of memory chips communicate with the controller 2200 via K channels CH1 to CHk.

Each of the nonvolatile memory chips may have the same structure and operate in the same manner as the nonvolatile memory device according to the inventive concepts. That is, the nonvolatile memory device 1100 may generate a current corresponding to fail bits and count the generated current to count a number of the fail bits.

As illustrated in FIG. 41, one channel may be connected with a plurality of nonvolatile memory chips. However, the memory system 2000 may be modified such that one channel is connected with one nonvolatile memory chip.

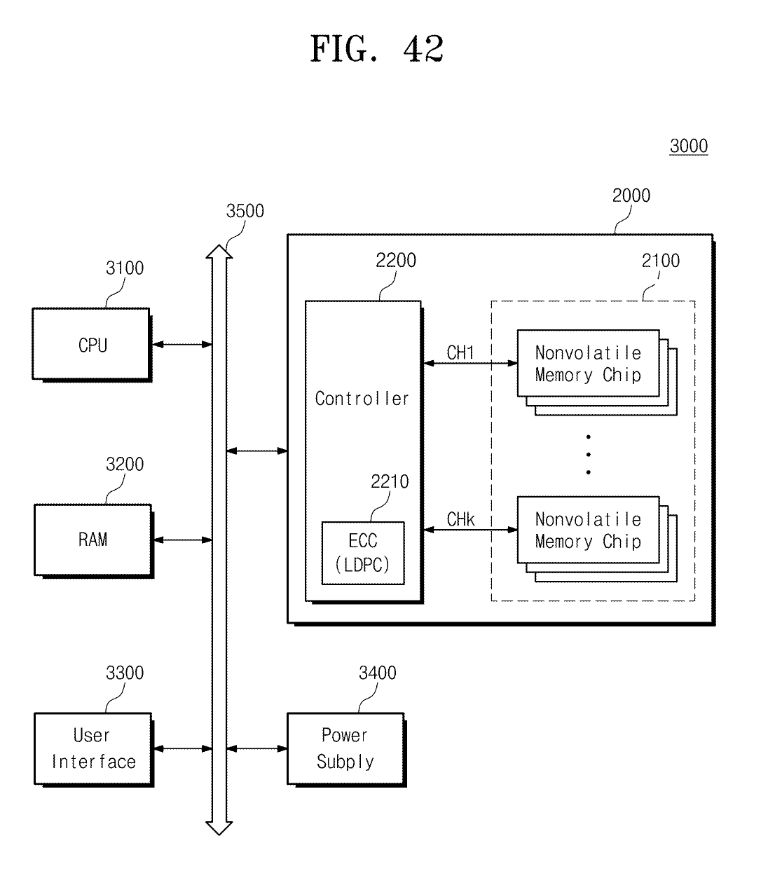

FIG. 42 is a block diagram illustrating computing systems including memory systems illustrated in FIG. 41. Referring to FIG. 42, a computing system 3000 may include a CPU 3100, a RAM 3200, a user interface 3300, a power supply 3400 and a memory system 2000.

The memory system 2000 may be electrically connected with the CPU 3100, the RAM 3200, the user interface 3300 and the power supply 3400. Data provided via the user interface 3300 and/or processed by the CPU 3100 may be stored in the memory system 2000.

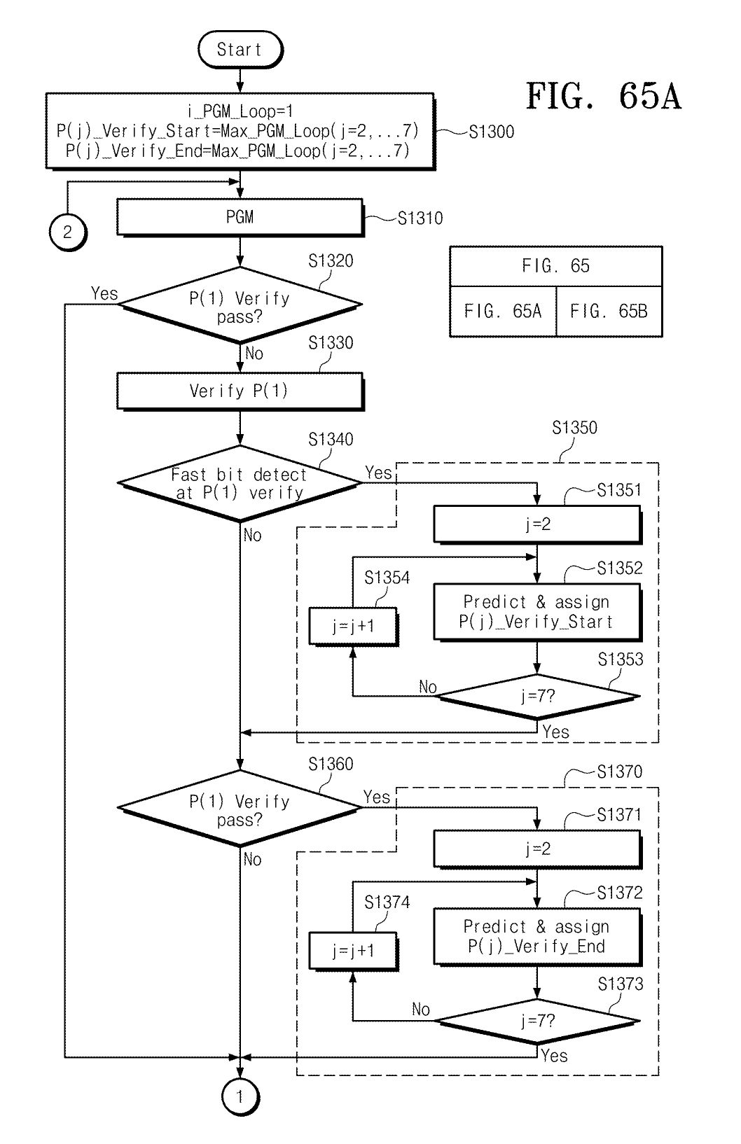

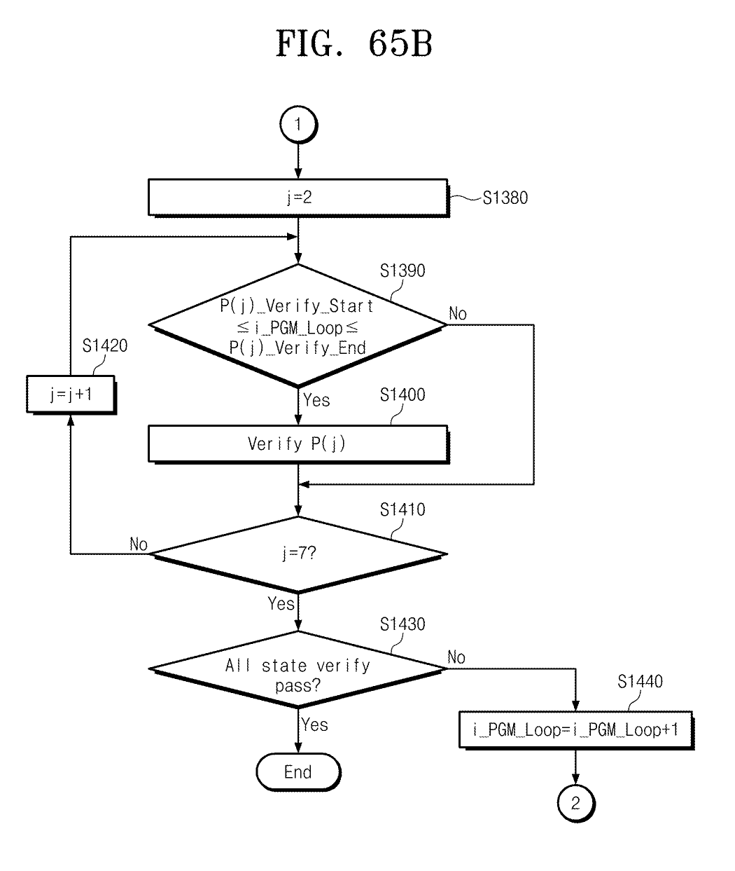

As illustrated in FIG. 42, a nonvolatile memory device 2100 may be connected with a system bus 3500 via a controller 2200. The nonvolatile memory device 2100 may be connected directly with the system bus 3500. The memory system 2000 in FIG. 65 may be a memory system described in FIG. 41. However, the memory system 2000 may be replaced with a memory system 1000 in FIG. 40. The computing system 3000 may be configured to include all memory systems 1000 and 2000 described in FIGS. 40 and 41.

As understood from the above description, as a cross-sectional area of a pillar varies, a voltage applying time and/or a voltage level of program and erase voltages may vary. Because a threshold voltage distribution of memory cells becomes narrow, the reliability may be improved.

FIG. 43 is a block diagram illustrating a flash memory device according to an embodiment of the inventive concept. For explanation purposes, it will be assumed that the flash memory device of FIG. 43 is a NAND flash memory device. However, embodiments of the inventive concept are not limited to NAND flash memory devices.

Referring to FIG. 43, the flash memory device comprises a memory cell array 4100 comprising memory cells arranged in rows connected to wordlines WL and columns connected to bitlines BL. Each memory cell stores 1-bit data or M-bit data, where M is an integer greater than one. Each memory cell can store information using a charge storage layer such as a floating gate or a charge trapping layer, a variable resistor, or another type of memory element.

Memory cell array 4100 can be implemented with a single-layer array structure (called a two-dimensional array structure) or a multi-layer array structure (called a three-dimensional array structure). Examples of a three-dimensional array structure are disclosed in U.S. Patent Publication No. 42008/0023747 entitled “SEMICONDUCTOR MEMORY DEVICE WITH MEMORY CELLS ON MULTIPLE LAYERS” and U.S. Patent Publication No. 42008/0084729 entitled “SEMICONDUCTOR DEVICE WITH THREE-DIMENSIONAL ARRAY STRUCTURE”, the respective disclosures of which are hereby incorporated by reference.

A row decoder 4200 performs selection and driving operations for the rows of memory cell array 4100. A voltage generator 4300 is controlled by a control logic 4400 and generates voltages (for example, a program voltage, a pass voltage, an erase voltage, and a read voltage) for program, erase, and read operations. A read/write circuit 4500 is controlled by control logic 4400 and operates as a sense amplifier or a write driver according to various operation modes of the flash memory device. For example, in a read operation, read/write circuit 4500 operates as a sense amplifier for sensing data from selected memory cells of a selected row. An input/output circuit 4600 receives read data from read/write circuit 4500 and transmits the read data to an external destination. In a programming operation, read/write circuit 4500 operates as a write driver to drive selected memory cells of a selected row according to program data. Read/write circuit 4500 comprises page buffers that correspond to respective bitlines or bitline pairs. Where the selected memory cells store multi-bit/multi-level data, each page buffer of read/write circuit 4500 may include two or more latches. Input/output circuit 4600 typically interfaces with an external device, such as a memory controller or a host.

Control logic 4400 controls the overall operation of the flash memory device and comprises a pass bit detector 4410, a pass/fail determiner 4420, and a register 4430.

Pass bit detector 4410 receives data that has been read by read/write circuit 4500 in a verification operation. Pass bit detector 4410 then determines whether a threshold voltage of at least one of the selected memory cells is greater than or equal to a verification level of a first program state (i.e., whether the at least one selected memory cell is “program passed” with respect to the first program state), based on the data read by read/write circuit 4500. Where at least one of the selected memory cells is determined to be program passed with respect to the first program state, control logic 4400 determines verification start points for performing verification operations with respect to further program states.

A verification start point is a point of a program operation, such as a specific program loop, where a verification operation is first performed for a particular program state. For instance, a verification start point for a program state P2 of selected memory cells can be a first program loop in which a verification operation is performed to determine whether the selected memory cells are successfully programmed to state P2. In program loops that precede the verification start point for program state P2, verification operations for program state P2 are omitted.

In certain embodiments, the verification start point for a program state P2 is determined according to a saved value of a program voltage at which a first selected memory cell is detected to be successfully programmed to program state P1. For instance, in some embodiments, the verification start point is a program loop where the value of the program voltage equals a sum of the saved value and a predetermined value.

Register 4430 stores pass bit information from control logic 4400 to indicate a program-passed loop. The program-passed loop is a program loop where at least one selected memory cell is program passed with respect to a particular program state. The pass bit information determines the start points of verification operations for subsequent program states, as will be described below. The pass bit information can also be provided to an external device, such as a memory controller. Pass/fail determiner 4420 determines whether all the selected memory cells are successfully programmed on the basis of read data provided from read/write circuit 4500 during the verification operation.

In other words, pass/fail determination determines whether all of the selected memory cells to be programmed to a particular program state have reached that state. Meanwhile, pass bit detection detects whether at least one of the selected memory cell to be programmed to the particular program state have reached that state. The order of pass/fail determination and pass bit detection can be changed in various alternative embodiments. For example, in some embodiments, pass bit detection is performed before pass/fail determination, and in other embodiments, pass bit detection is performed after pass/fail determination.

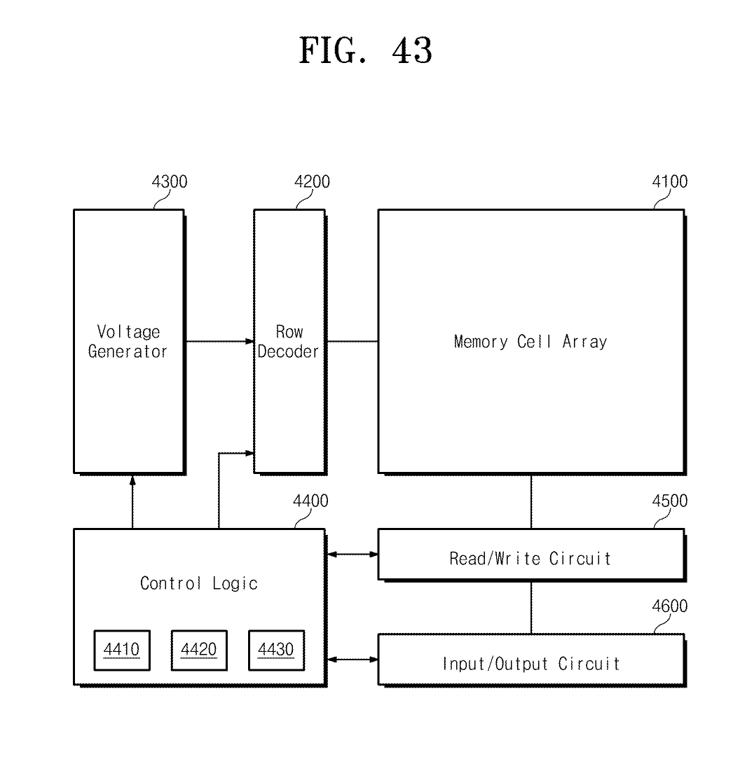

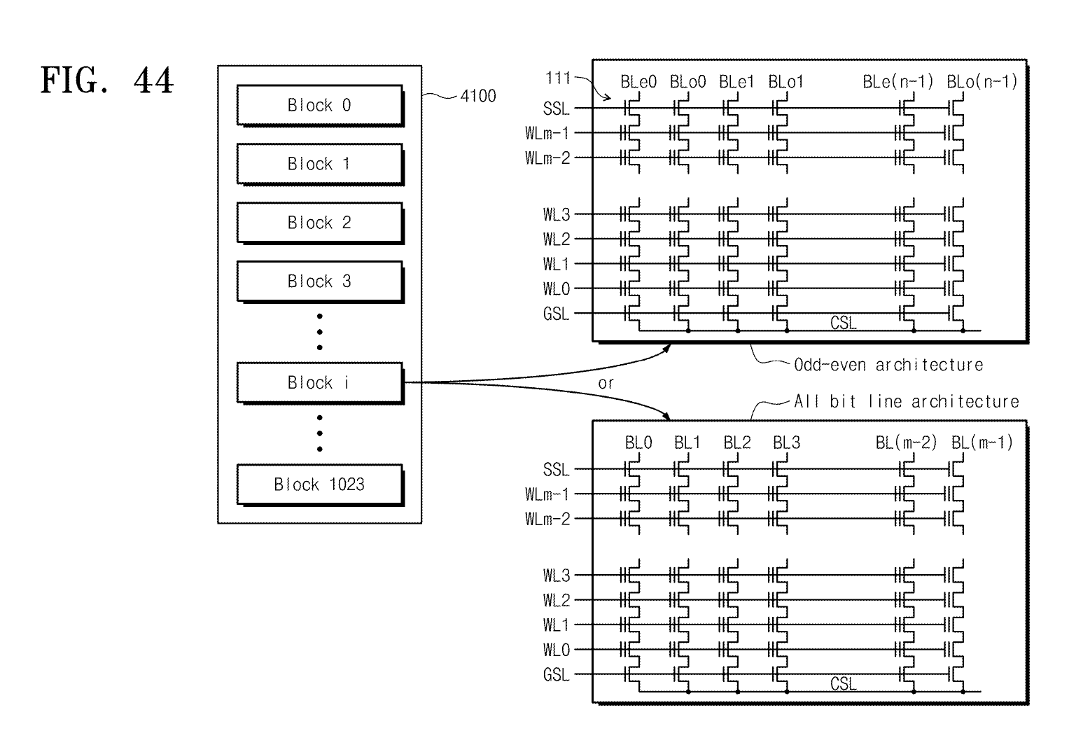

FIG. 44 is a diagram illustrating a flash memory device comprising a memory cell array with memory blocks having an all bitline architecture or an odd-even bitline architecture. In the example of FIG. 44, a NAND flash memory device comprises memory cell array 4100 having 1024 memory blocks. In memory cell array 4100, data stored in the same memory block is erased simultaneously. In each memory block, memory cells are arranged in columns connected to the same bitline (e.g., 1 KB bitlines).

In the all bitline architecture, all bitlines of a memory block are simultaneously selected during read and programming operations. Accordingly, memory cells connected to a common wordline and connected to all the bitlines are simultaneously programmed. In the example of FIG. 44, memory cells in the same column are serially connected to form NAND string 111. One end of NAND string 111 is connected to a corresponding bitline through a selection transistor controlled by a string selection line SSL, and another end is connected to a common source line CSL through a selection transistor controlled by a ground selection line GSL.

In the odd-even architecture, bitlines are divided into even bitlines BLe and odd bitlines BLo. Memory cells connected to a common wordline and connected to odd bitlines are programmed together, while memory cells connected to the common wordline and connected to even bitlines are programmed together. Data can be programmed in different memory blocks and read from different memory blocks. These operations can be performed at the same time.

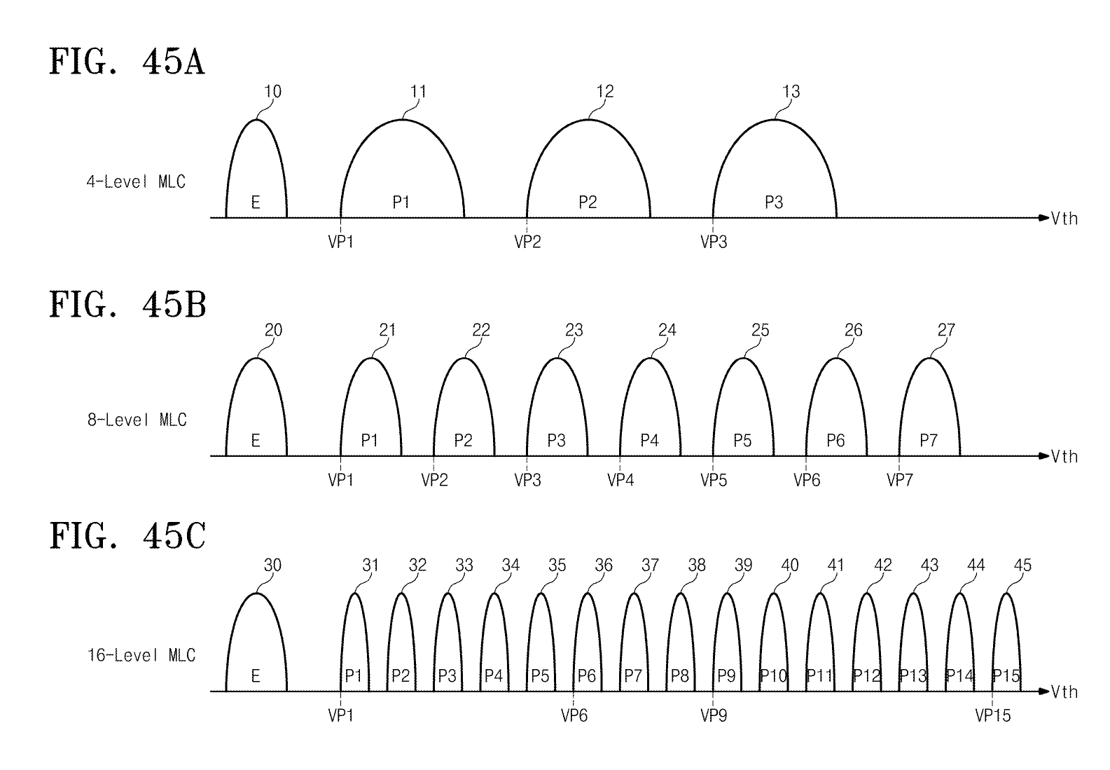

FIGS. 45A through 45C are diagrams illustrating threshold voltage distributions for memory cells storing different numbers of bits. In particular, FIG. 45A shows threshold voltage distributions for memory cells storing 2-bit data, FIG. 45B shows threshold voltage distributions for memory cells storing 3-bit data, and FIG. 45C shows threshold voltage distributions for memory cells storing 4-bit data. The threshold voltage distributions of FIGS. 45A through 45C correspond to program states of memory cells. Accordingly, the threshold voltage distributions will at times be referred to as program states in the description that follows.

Where 2-bit data (4-level data or 2-page data) is stored in a group of memory cells, as shown in FIG. 45A, each of the memory cells has a threshold voltage within one of four threshold voltage distributions 10 through 13. Threshold voltage distribution 10 encompasses threshold voltages of erased memory cells, and threshold voltage distributions 11 through 13 encompass threshold voltages of programmed memory cells. Voltages VP1 through VP3 are verification voltages for determining whether memory cells are programmed into respective threshold voltage distributions 11 through 13.

Where 3-bit data (8-level data or 3-page data) is stored in a group of memory cells, as shown in FIG. 45B, each of the memory cells has a threshold voltage within one of eight threshold voltage distributions 20 through 27. Threshold voltage distribution 20 comprises threshold voltages of erased memory cells, and threshold voltage distributions 21 through 27 comprise threshold voltages of programmed memory cells. Voltages VP1 through VP7 are verification voltages for determining whether memory cells are respectively programmed into threshold voltage distributions 21 through 27.

Where 4-bit data (16-level data or 4-page data) is stored in a group of memory cells, as shown in FIG. 45C, each of the memory cells has a threshold voltage within one of sixteen threshold voltage distributions 30 through 45. Threshold voltage distribution 30 comprises threshold voltages of erased memory cells, and threshold voltage distributions 31 through 45 comprise threshold voltages of programmed memory cells. Voltages VP1 through VP15 are verification voltages for determining whether selected memory cells are programmed into threshold voltage distributions 31 through 45.

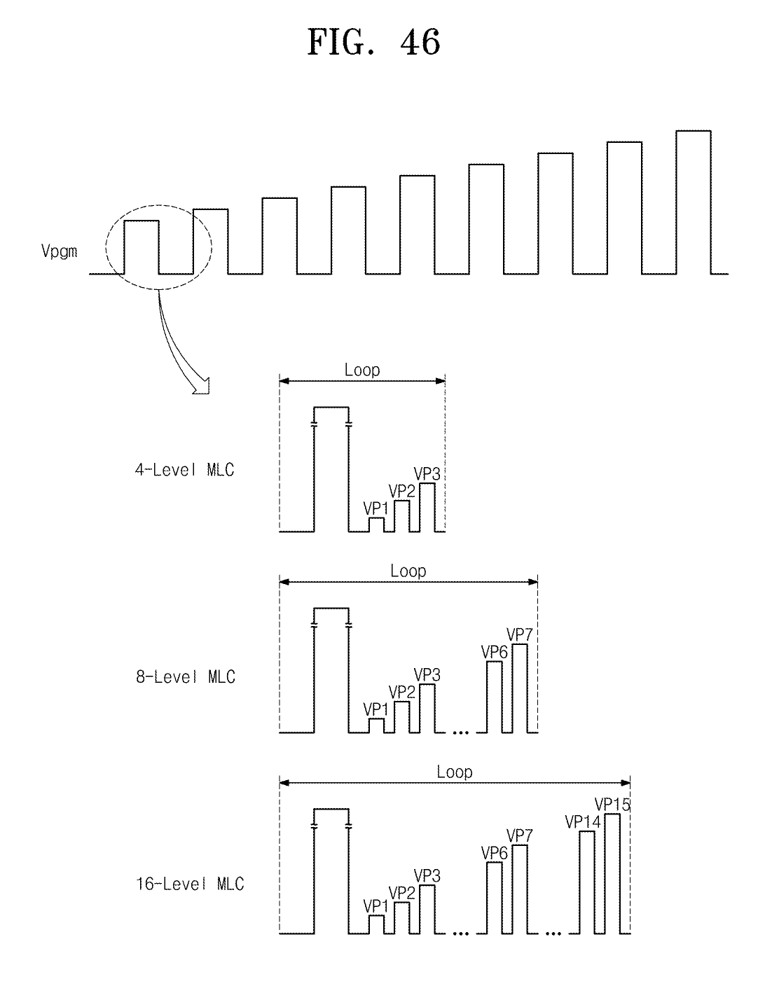

FIG. 46 is a diagram illustrating a series of programming pulses used to program selected memory cells connected to a selected wordline. The example of FIG. 46 uses a general ISPP scheme. Certain embodiments of the inventive concept use a programming scheme that is modified relative to the general ISPP scheme of FIG. 46.

In the general ISPP scheme, a program voltage Vpgm is applied to control gates of selected memory cells as a series of programming pulses. The level of the programming pulses increases in successive iterations.

In periods between programming pulses, verification operations (or verification read operations) are performed. The verification operations determine whether the threshold voltages of selected memory cells have reached a verification level.

In an array of multi-level flash memory cells such as those described with respect to FIG. 45, a verification operation is performed to determine whether a selected memory cell has reached a threshold voltage distribution corresponding to a desired logic state. For instance, as illustrated in FIG. 46, in a 4-level MLC, verification operations are performed using verification voltages VP1 through VP3 to determine whether a selected memory cell has been successfully programmed to a logic state corresponding to one of threshold voltage distributions 11 through 13. Similarly, in an 8-level MLC, verification operations are performed using verification voltages VP1 through VP7, and in a 16-level MLC, verification operations are performed using fifteen verification voltages VP1 through VP15.

The time required to perform programming operations using the general programming scheme of FIG. 46 tends to increase in proportion to the number of program states of the selected memory cells. Moreover, in these programming operations, verification operations tend to occupy a large portion of the total programming time. Accordingly, a flash memory device according to certain embodiments of the inventive concept applies an adaptive verification scheme that reduces the verification time even where the number of program states of the selected memory cells is relatively large.

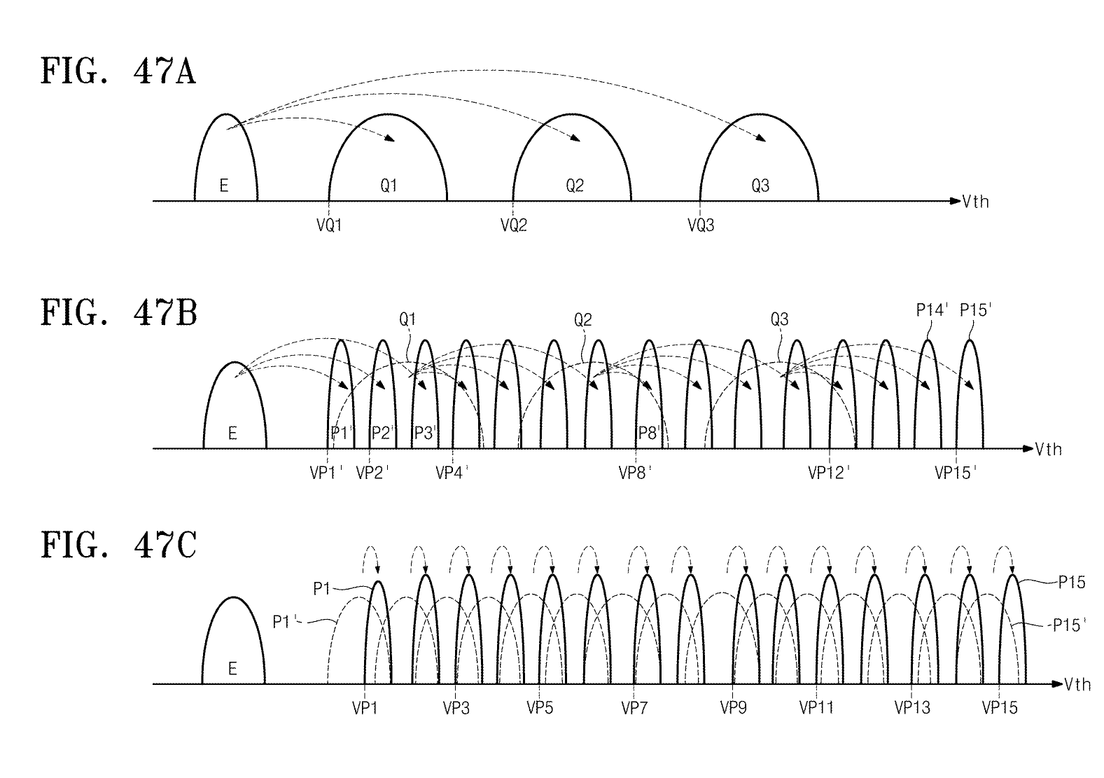

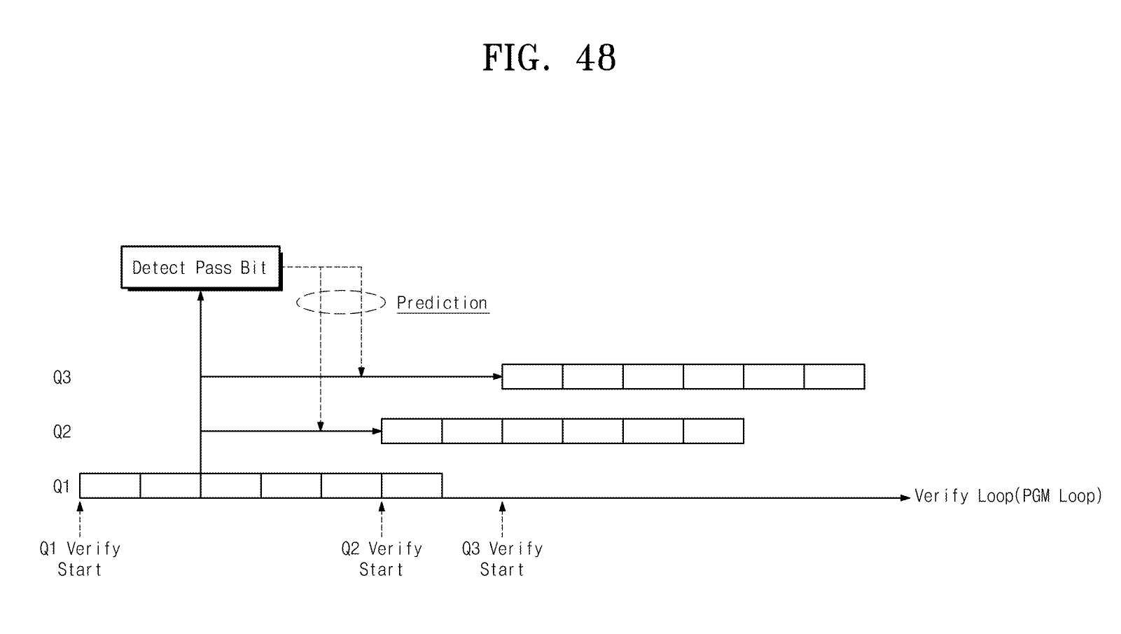

FIGS. 47A through 47C are diagrams illustrating a method of programming a flash memory device according to an embodiment of the inventive concept. In the embodiment of FIGS. 47A through 47C, it is assumed that a flash memory device stores 4-bit data in each cell and performs a programming operation according to a 3-step programming scheme.

In the method of FIGS. 47A through 47C, first and second page data is simultaneously programmed in selected memory cells connected to a selected wordline. As illustrated in FIG. 47A, selected memory cells having threshold voltage distributions corresponding to an erased state E are programmed to threshold voltage distributions corresponding to program states Q1 through Q3 according to data to be programmed.

Next, third and fourth page data is simultaneously stored in the selected memory cells. As illustrated in FIG. 47B, selected memory cells in erased state E are programmed to threshold voltage distributions corresponding to program states P1′ through P3′ according to data to be programmed. Selected memory cells in program state Q1 of FIG. 47A are programmed to threshold voltage distributions corresponding to program states P4′ through P7′ according to data to be programmed. Selected memory cells in program state Q2 of FIG. 47A are programmed to threshold voltage distributions corresponding to program states P8′ through P11′ according to data to be programmed. Selected memory cells in program state Q3 of FIG. 47A are programmed to threshold voltage distributions corresponding to program states P12′ through P15′ according to data to be programmed.

Verification voltages VP1′ through VP15′, which are used to determine program states P1′ through P15′, are lower than verification voltages VP1 through VP15, which are used to determine final program states P1 through P15 (see FIG. 47C). For example, a verification voltage VP1 ‘, which is used to determine a program state P1’, is lower than a verification voltage VP1, which is used to determine a corresponding final threshold voltage distribution P1 (see FIG. 47C). An operation that programs selected memory cells to the threshold voltage distributions of FIG. 47B, is referred to as a coarse programming operation.

Selected memory cells in program states P1′ through P15′ are programmed to have final program states P1 through P15 in a fine programming operation (or a reprogramming operation).

The programming operations of FIGS. 47A through 47C can be successively or non-successively performed. These programming operations can have verification operations for determining whether selected memory cells are programmed to target threshold voltage distributions.

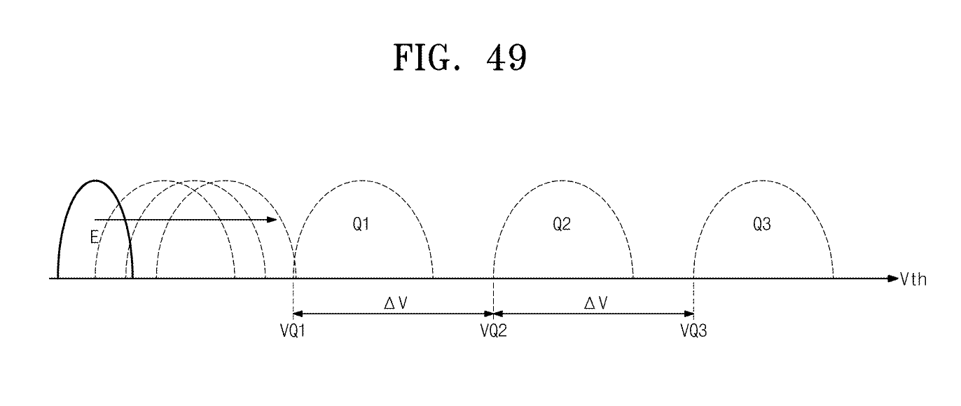

FIGS. 48 and 49 are diagrams illustrating a method of verifying the programming operation of FIG. 47A.

Referring to FIG. 48, after a program voltage Vpgm is applied to selected memory cells connected to a selected wordline, a verification voltage for verifying a program state Q1 is applied to the selected wordline. At this point, as illustrated in FIG. 48, verification operations for other program states Q2 and Q3 are not performed. A verification voltage is then applied to the selected wordline, and read/write circuit 4500 reads data from the memory cells. Subsequently, pass bit detector 4410 of control logic 4400 detects whether a threshold voltage of at least one selected memory cell is greater than or equal to a verification voltage VQ1 of program state Q1 on the basis of read data. Where no selected memory cell has a threshold voltage greater than or equal to verification voltage VQ1, program voltage Vpgm increases by a predetermined amount and the programming operation proceeds to a next program loop. Otherwise, the flash memory device determines verification start points for program states Q2 and Q3.

Referring to FIG. 49, where at least one selected memory cell is detected to have a threshold voltage greater than or equal to verification voltage VQ1, control logic 4400 sets a verification start point of program state Q2 according to a present value of program voltage Vpgm. In particular, control logic 4400 sets the verification start point as a program loop having a value of program voltage Vpgm equal to a sum of the present value of program voltage Vpgm and a voltage difference ΔV between verification voltages VQ1 and VQ2. In addition, assuming that a voltage difference between verification voltages VQ2 and VQ3 is also ΔV, control logic 4400 sets a verification start point of program state Q3 as a program loop having a value of program voltage Vpgm equal to the sum of the present value of program voltage Vpgm and 2ΔV. As illustrated in FIG. 48, verification operations of program states Q2 and Q3 are not performed until the determined verification start point.

In some embodiments, a program loop where a pass bit is detected (or a program voltage applied to selected memory cell(s) determined as a pass bit) is stored in register 4430 of control logic 4400. Alternatively, the program loop (or program voltage) is provided to an external device, such as a memory controller, under the control of control logic 4400.

As indicated above, pass/fail determination can be performed by pass/fail determiner 4420 before or after pass bit detection is performed. Where a selected memory cell is successfully programmed to its target state, a program-inhibition voltage is applied to the selected memory cell in subsequent program loops.

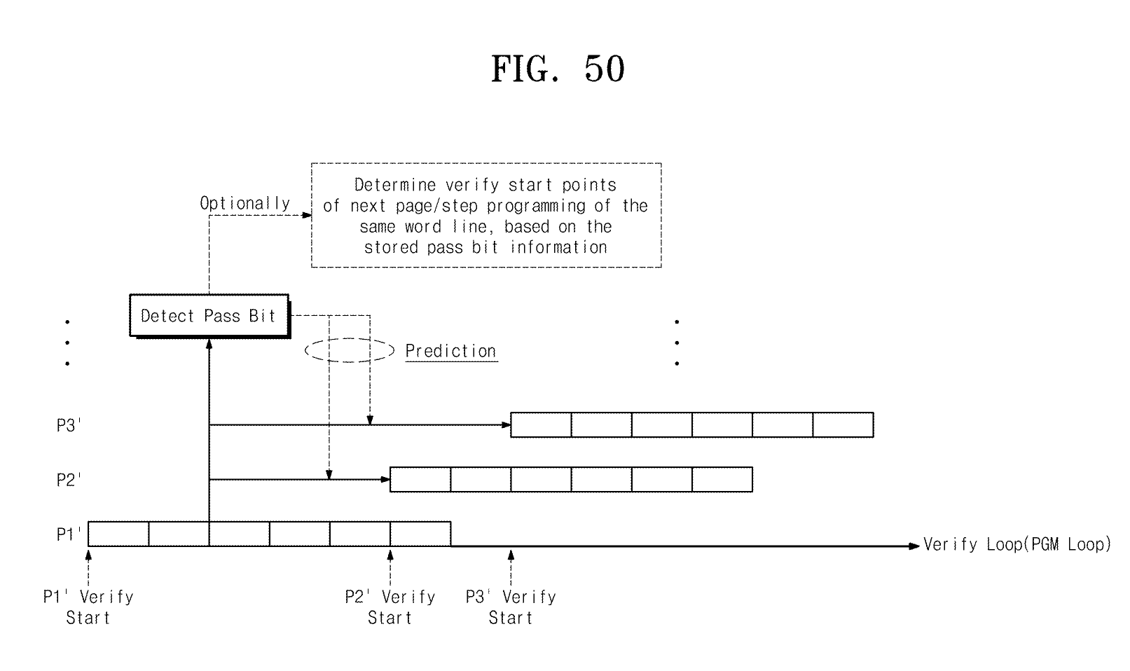

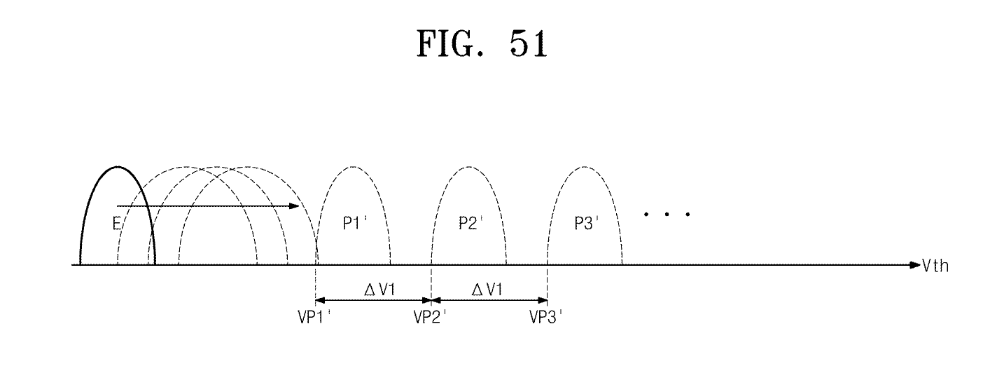

FIGS. 50 and 51 are diagrams illustrating a method of verifying a programming operation of FIG. 47B.

Referring to FIG. 50, after program voltage Vpgm is applied to selected memory cells connected to a selected wordline, a verification voltage for verifying program state P1′ is applied to the selected wordline. At this point, as illustrated in FIG. 50, verification operations for other program states P2′ through P15′ are not performed. A verification voltage is then applied to the selected wordline, and read/write circuit 4500 reads data from the selected memory cells. Subsequently, pass bit detector 4410 of control logic 4400 detects whether a threshold voltage of at least one selected memory cell is greater than or equal to verification voltage VP1′ of program state P1′ on the basis of the read data. Where no selected memory cell has a threshold voltage greater than or equal to verification voltage VP1′ of program state P1′, program voltage Vpgm is increased by a predetermined amount, and the programming operation proceeds to a next program loop. Otherwise, the flash memory device determines verification start points for program states P2′ through P15′.

Referring to FIG. 51, where at least one selected memory cell is detected to have a threshold voltage greater than or equal to verification voltage VP1′, control logic 4400 sets a verification start point of program state P2′ according to a present value of program voltage Vpgm. In particular, control logic 4400 sets the verification start point as a program loop having a value of program voltage Vpgm equal to a sum of the present value of program voltage Vpgm and a voltage difference ΔV1 between verification voltages VP1′ and VP2′. In addition, assuming that a voltage difference between verification voltages VP2′ and VP3′ is also ΔV1, control logic 4400 sets a verification start point of program state P3′ as a program loop having a value of program voltage Vpgm equal to the sum of the present value of program voltage Vpgm and 2ΔV1. As illustrated in FIG. 50, verification operations of program states P2′ through P15′ are not performed until corresponding verification start points.

In some embodiments, register 4430 of control logic 4400 stores pass bit information, such as a program loop where a pass bit is detected, or a program voltage of the loop, during a coarse programming operation. The pass bit information stored in register 4430 can then be used to determine verification start points of final program states P1 through P15 for a fine programming operation.

In some embodiments, pass bit information is output to an external device, such as a memory controller. The pass bit information can be used to perform a fine programming operation for selected memory cells.

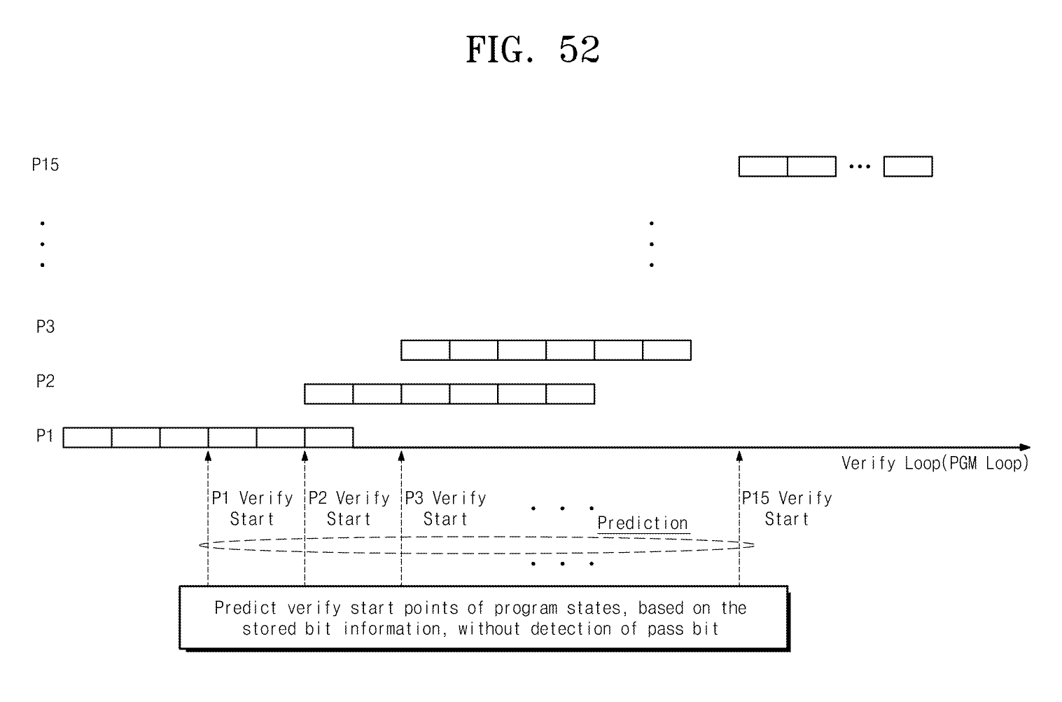

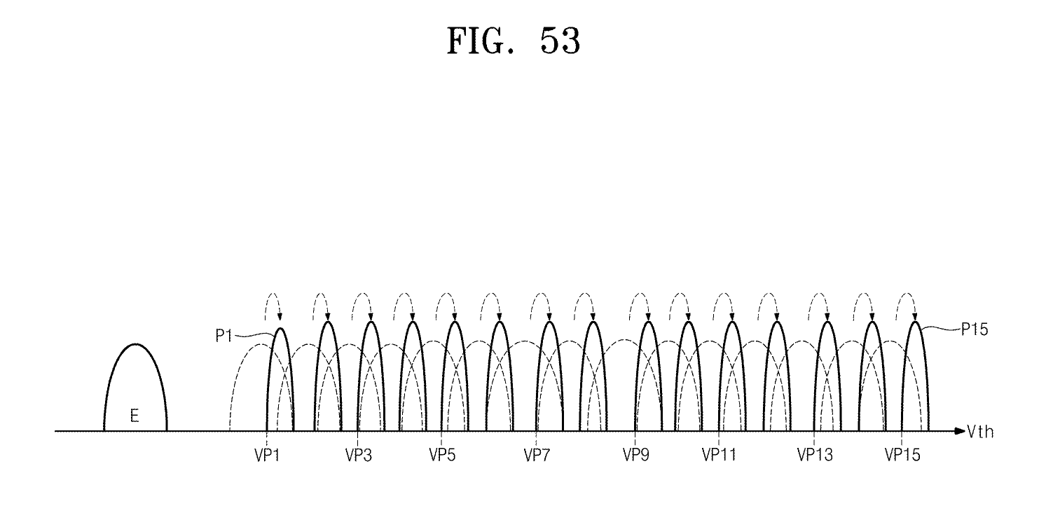

FIGS. 52 and 53 are diagrams illustrating a method of verifying the programming operation of FIG. 47C.

Referring to FIG. 52, control logic 4400 determines verification start points of program states P1 through P15 based on pass bit information detected in a previous programming operation. The pass bit information can be accessed, for instance, from register 4430. Referring to FIG. 53, control logic 4400 determines the verification start point of program state P1 on the basis of pass bit information indicating a pass bit detected in a previous page programming operation of a selected wordline. Control logic 4400 determines the verification start point of program state P2 as a program loop where program voltage Vpgm equals a sum of a voltage difference ΔV2 between verification voltages VP1 and VP2, and a program voltage Vpgm corresponding to the pass bit information detected in the previous programming operation. In addition, assuming that a voltage difference between verification voltages VP2 and VP3 is also ΔV2, control logic 4400 sets a verification start point of program state Q3 as a program loop having a value of program voltage Vpgm equal to the sum of the present value of program voltage Vpgm and 2ΔV2. As illustrated in FIG. 52, verification operations of program states P2 through P15 are not performed until the corresponding verification start points.

In the programming method described above with reference to FIG. 47, the verification operations for program states P1 through P15 are not performed until corresponding verification start points. For example, verification voltages for verifying program states P1 through P15 are applied to selected wordlines only after a current loop reaches a verification start point for the corresponding program state.

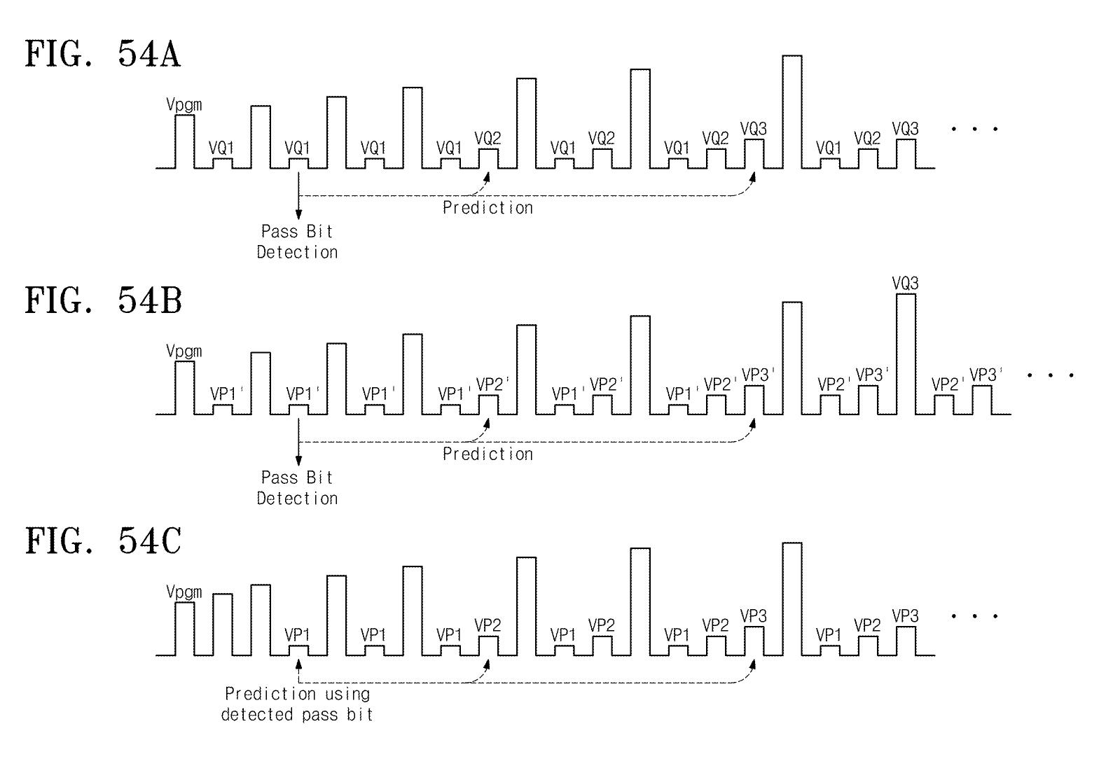

FIG. 54A is a voltage diagram showing program voltages and verification voltages for the method of FIG. 47A. FIG. 54B is a voltage diagram showing program voltages and verification voltages for the method of FIG. 47B. FIG. 54C is a voltage diagram showing program voltages and verification voltages for the method of FIG. 47C.

As illustrated in FIG. 54A, a pass bit is detected during a verification operation of program state Q1. Once the pass bit is detected, verification start points of other program states Q2 and Q3 are determined by control logic 4400. As illustrated in FIG. 54B, a pass bit is detected during a verification operation of program state P1′. Once the pass bit is detected, verification start points of other program states P2′ and P15′ are determined by control logic 4400. At this point, pass bit information is stored in register 4430 of control logic 4400 to determine verification start points of subsequent page programming operations, such as fine programming stages. Finally, as illustrated in FIG. 54C, verification start points of final program states P1 through P15 are determined on the basis of information stored in register 4430.

In the programming operations described with reference to FIGS. 5 through 54, programming speed is increased by eliminating certain verification operations.

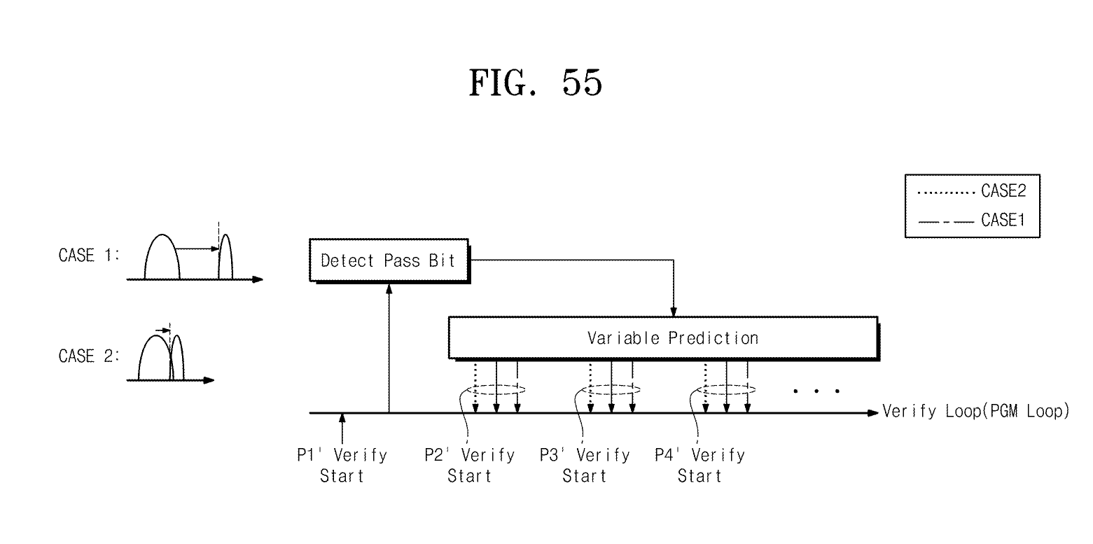

FIG. 55 is a diagram illustrating a method of programming a flash memory device according to another embodiment of the inventive concept. In the method of FIG. 55, memory cells are programmed using different techniques according to different cases shown on the left side of FIG. 55.

In the two different cases of FIG. 55, verification start points of program states are variably set according to previous states and target states of selected memory cells. In a first case, the previous state and the target state do not overlap because the threshold voltage distribution of the previous state does not exceed the verification voltage of the target state. In a second case, the previous state and the target state overlap because the threshold voltage distribution of the previous state exceeds the verification voltage of the target state.

Where a target state to be verified corresponds to the first case, the verification start point of the target state uses a verification voltage illustrated by a dashed line to the right of a solid line in FIG. 55. On the other hand, where a target state to be verified corresponds to the second case, the verification start point of the target state uses a verification voltage illustrated as a dotted line to the left of the solid line in FIG. 55. In the example of FIG. 55, the verification start point corresponding to the solid line is determined according to the method of FIG. 48 or FIG. 50.

Applying the method of FIG. 55 to the example of FIG. 47A, the first case can be realized by previous state E and target states Q1 through Q3. In the example of FIG. 47A, the second case does not arise because memory cells are not programmed between threshold voltage distributions that overlap each other. Applying the method of FIG. 55 to the example of FIG. 47B, the first case can be realized by previous state E and target states P1′ through P3′, a previous state Q1 and target states P5′ through P7′, a previous state Q2 and target states P9′ through P11′, and a previous state Q3 and target states P13′ through P15′. The second case can be realized by a previous state Q1 and a target state P4′, a previous state Q2 and a target state P8, and a previous state Q3 and a target state P12. Applying the method of FIG. 55 to the example of FIG. 47C, the second case can be realized by previous states P1′ through P15′ and target states P1 through P15.

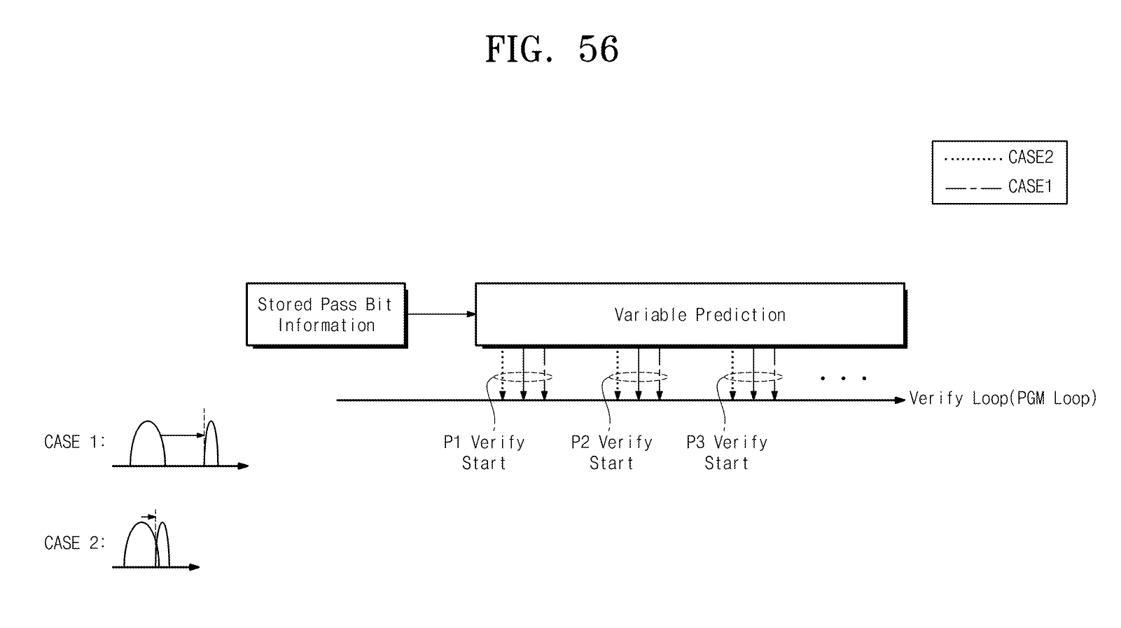

FIG. 56 is a diagram illustrating a method of programming a flash memory device according to another embodiment of the inventive concept.

The method of FIG. 56 is substantially the same as the method of FIG. 55, except that the determination of verification start points is performed on the basis of pass bit information from a previous page programming operation of the same wordline instead of pass bit detection for first programming state P1.

As indicated in the above descriptions of FIGS. 55 and 56, the verification start point of each program state is determined on the basis of a detected pass bit, a stored pass bit, or a relationship between the detected pass bit or the stored pass bit and a previous state and a target state.

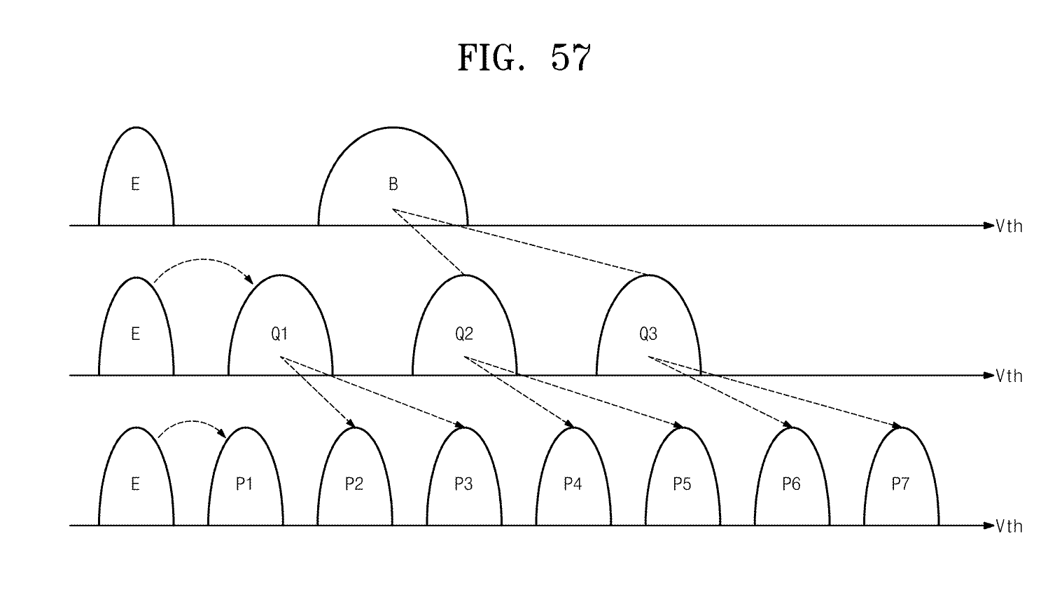

FIG. 57 is a diagram illustrating a method of programming a flash memory device according to another embodiment of the inventive concept.

In the method of FIG. 57, selected memory cells are programmed according to a shadow programming scheme. Even when performing a programming operation using the shadow programming scheme, the above described methods can be used to determine verification start points. For example, the verification start point of each program state can be determined on the basis of a detected pass bit, a stored pass bit, or a relationship between the detected pass bit or the stored pass bit and a previous state and a target state.

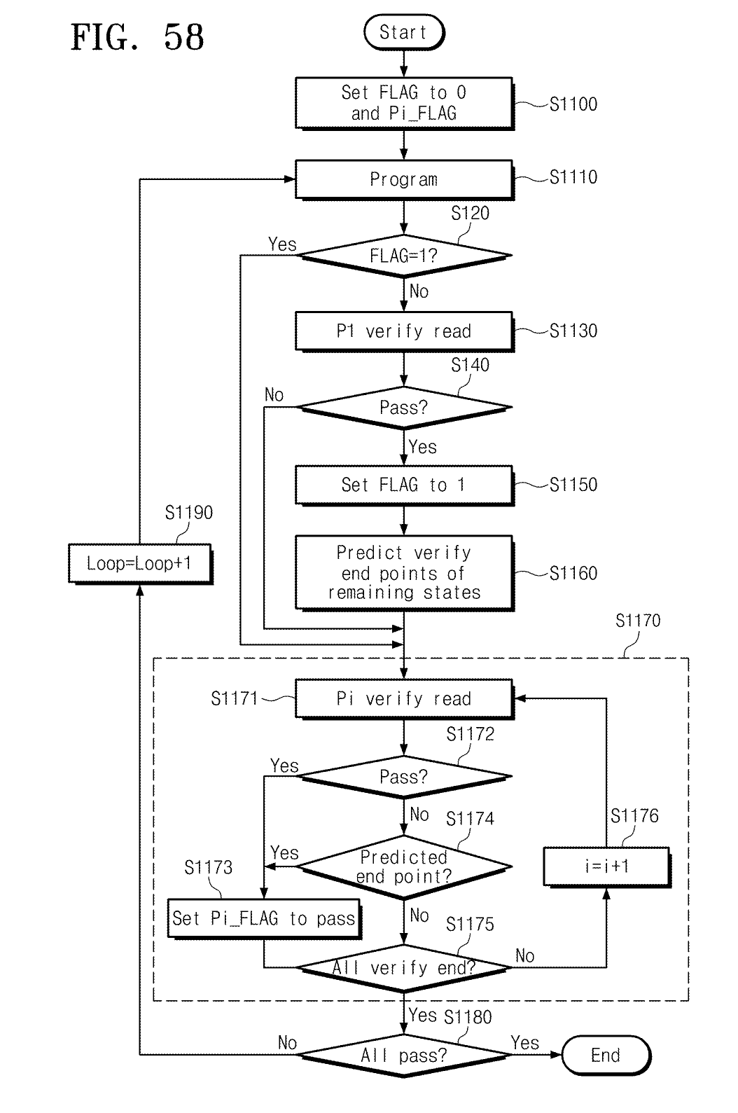

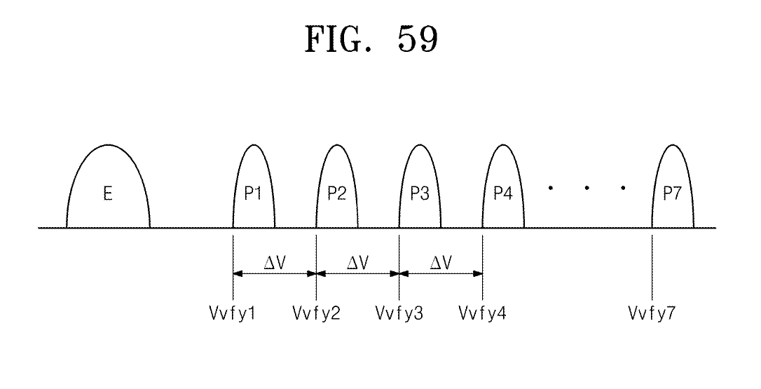

FIG. 58 is a flowchart illustrating a method of programming a flash memory device according to another embodiment of the inventive concept. FIG. 59 is a diagram showing the threshold voltage distributions of multi-bit data programmed by the method of FIG. 58.

In the method of FIG. 58, the flash memory device is programmed using a programming operation comprising a programming execution section and a verification section. The programming execution section changes threshold voltages of selected memory cells of a selected wordline, and the verification section determines whether the threshold voltages of the selected memory cells, which have changed during the programming execution section, have reached corresponding target voltages. A program voltage is applied to the selected wordline during the programming execution section, and a series of verification voltages are sequentially applied to the selected wordline during the verification section. The series of verification voltages correspond to threshold voltage distributions representing multi-bit data in the selected memory cells. Data to be programmed is loaded to the flash memory device before the programming execution section. Previously programmed data can be read before loading of data to be programmed.

Referring to FIG. 58, variables FLAG and Pi_FLAG are set to ‘0’ in operation S1100. The variable FLAG is used to indicate whether the lowest program state (for example, state P1 of FIG. 44) is passed, and the variable Pi_FLAG is used to indicate whether other program states are passed. A “passed” status of a program state indicates that all threshold voltages of selected memory cells corresponding to the program state are greater than or equal to a verification voltage of the program state. A passed status of a program state differs from the program pass of a programming operation.

A programming operation is performed in operation S1110. Operation S1110 corresponds to the programming execution section. Then, operation S1120 determines whether the variable FLAG is set to ‘1’. Where the variable FLAG is not set to ‘1’ (S1120=No), the method proceeds to operation S1130. In operation S1130, a verification operation is performed for program state P1. Then, in operation S1140, the method determines whether all of the selected memory cells corresponding to program state P1 have threshold voltages that are greater than or equal to the verification voltages. In other words, operation S1140 determines whether program state P1 is passed.

Where program state P1 is determined to be passed (S1140=Yes), the method proceeds to operation S1150, where the variable FLAG is set to ‘1’. Thereafter, a verification operation for program state P1 is omitted during the verification section of further program loops. The last point, such as a last program loop, where verification is performed for program state P1 is referred to as a verification end point, or verification end loop. Next, operation S1160 predicts verification end points of remaining program states. The verification end points of the remaining program states are predicted as follows.

Where program state P1 is detected as being passed, the method determines or predicts a pass point for each of the remaining program states, where a pass point indicates a program loop or program voltage where a program state is passed. The pass points can then be used to determine verification end points for the remaining program states.

The pass points of the remaining program states are determined by an equation “Vpgm(i)=Vpgm(pass)+Vdiff”, where Vdiff indicates a difference voltage “N*ΔV” (where N≧1) between verification voltage VP1 of program state P1 and the verification voltage of another program state, Vpgm(i) (i≧2) indicates the programmed voltage of the pass point of each of remaining program states (for example, program states P2 through P7) other than program state P1, and Vpgm(pass) indicates the program voltage of a point where program state P1 is passed.

Assuming that 3-bit data is stored in each memory cell, as illustrated in FIG. 44, each memory cell has any one of eight threshold voltage distributions corresponding to states E and P1 through P7. Program states P1 through P7 are determined by corresponding verification voltages Vvfy1 through Vvfy7. The state distribution diagram of FIG. 44 is illustrated under a condition where a difference voltage “ΔV” is identical between verification voltages (for example, Vvfy1 and Vvfy2) corresponding to adjacent program states (for example, P1 and P2). However, the voltage differences between verification voltages can vary in other embodiments.

The pass points of remaining program states other than program state P1 are determined as illustrated above. Verification end points of the remaining program states are determined on the basis of the determined pass points. The verification end points are determined through an equation “Vpgm(i)_VE=Vpgm(i)−Voffset(i)”, where Vpgm(i)_VE indicates a program voltage corresponding to the verification end point of each of the remaining program states, and Voffset(i) indicates the offset voltage of each of the remaining program states. The offset voltages of the remaining program states can be set to the same value or different values in various embodiments.

In some embodiments, a flash memory device determines whether a verification end point has been reached for a particular program state by comparing a program voltage of a current program loop with a program voltage associated with the verification end point. Alternatively, the flash memory device can determine whether the verification end point has been reached for the particular program state by comparing an index or other identifier of a current program loop with a program loop identifier of the verification end point.

In some embodiments, the verification end point for a program state may occur before all of the relevant memory cells are programmed to that state. This can occur because the verification end point may be determined according to a prediction as described above. Where this occurs, the memory cells that have not been successfully programmed include fail bits. The fail bits can be corrected by an error correction code (ECC) unit of a memory controller during read bits. The fail bits are typically associated with memory cells having a slow programming speed and are called slow bits.

Once the verification end points are determined for the remaining program states P2 through P7, the method proceeds to operation S1170. In operation S1170, verification operations are performed for the remaining program states P2 through P7, as will be described below. The method also proceeds to operation S1170 where operation S1120 determines that the variable FLAG is set as ‘1’(S1120=Yes), or where operation S1140 determines that program state P1 is not passed (S1140=No).

The verification operations of the remaining program states, which are performed in operation S1170, are automatically ended based on the verification end points determined in operation S1160. As an example, a verification operation is performed for a next program state (e.g., state P2) in operation S1171. Operation S1172 determines whether the threshold voltages of memory cells corresponding to program state P2 are greater than or equal to verification voltage Vvfy2. That is, operation S1172 determines whether all memory cells corresponding to program state P2 are program passed. Where all of the memory cells corresponding to program state P2 are determined as being program passed (S1172=Yes), the method proceeds to operation S1173. Otherwise (S1172=No), the method proceeds to operation S1174.

In operation S1174, the method determines whether the current program loop has reached a verification end point for program state P2. If so (S1174=Yes), the method proceeds to operation S1173. Otherwise (S1174=No), the method proceeds to operation S1175.

In operation S1173, the variable Pi_FLAG is set to a passed state to indicate that a verification operation for program state P2 is to be omitted in a next program loop.

In operation S1175, the method determines whether all verification operations for remaining program states P2 through P7 have been performed. Where not all of the verification operations for program states P2 through P7 have been performed (S1175=No), the method proceeds to operation S1176. Otherwise (S1175=Yes), the method proceeds to operation S1180. In operation S1176, the variable T is increased by 1 and the method returns to operation S1171.

In operation S1180, the method determines whether all program states (e.g., P1 through P7) are passed. Where one or more of the program states is determined as not being passed (S1180=No), the method operation proceeds to operation S1190. Otherwise (S1180=Yes), the method ends.

In operation S1190, a variable LOOP indicating a program loop is increased by 1 and the method returns to operation S1110. Subsequent program loops are performed until all the program states are determined as being passed.

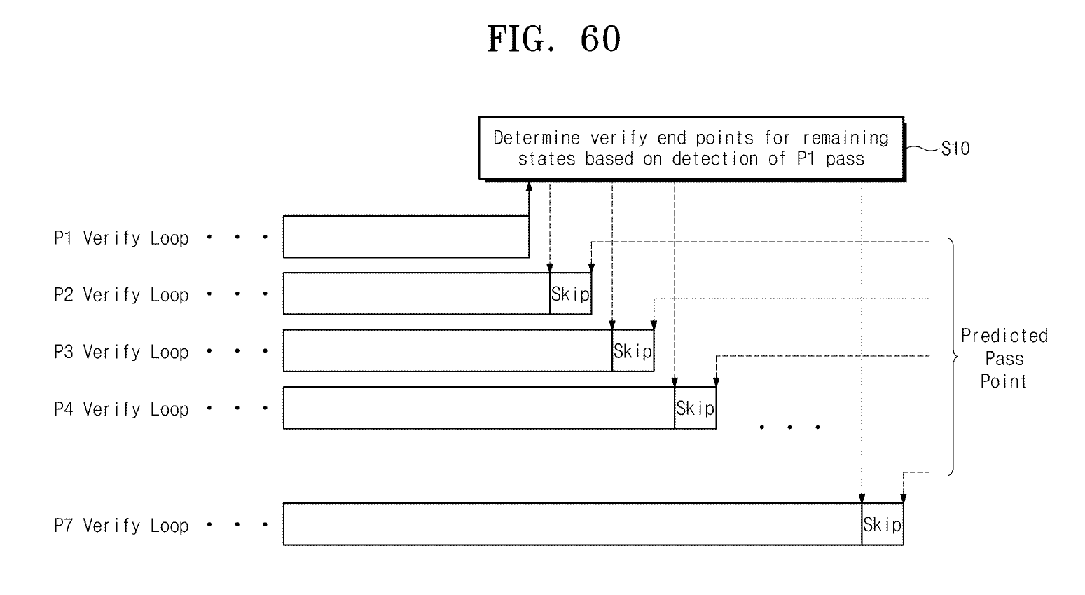

FIG. 60 is a diagram illustrating a verification scheme used in the method of FIG. 58 according to an embodiment of the inventive concept.

Referring to FIG. 60, where program state P1 is passed, verification end points for remaining program states P2 to P7 are predicted. Where a current program loop (or program voltage) corresponds to a predicted verification end point of program state, the program state is passed, and verification operations of the program state are ended. As illustrated in FIG. 60, verification operations are omitted for each program state after it reaches a corresponding predicted verification end point.

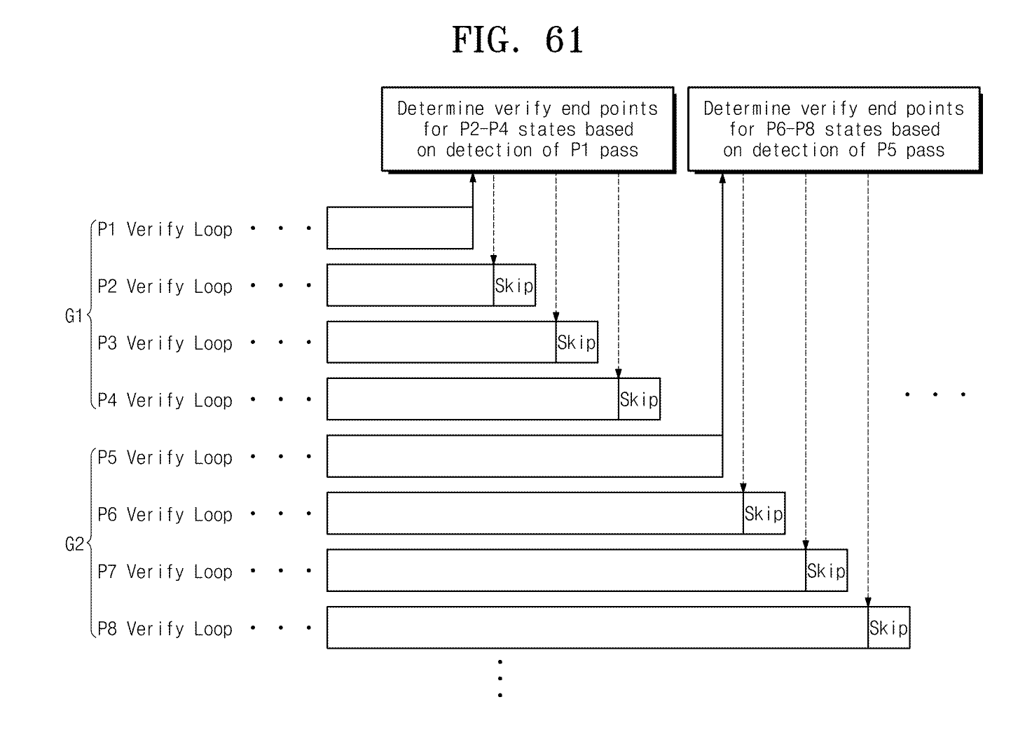

FIG. 61 is a diagram illustrating a verification scheme used in the method of FIG. 58 according to another embodiment of the inventive concept.

In the method of FIG. 61, the verification end points of the remaining program states are determined with respect to the pass points of at least two program states among a plurality of program states. For example, program states are divided into “n” groups G1 through Gn. The verification end points of remaining program states belonging to each group are determined with respect to the pass point of a lowest program state belonging to the group. The verification end points can be determined as described above. As an example, in a first group G1, the verification end points of remaining program states P2 through P4 are determined with respect to a pass point of program state P1. In a second group G2, the verification end points of remaining program states P6 through P8 are determined with respect to a pass point of program state P5.

In other embodiments, the number of program states belonging to each group can be varied. Moreover, offset voltages applied to different groups can be set identically or differently, and the offset voltages of the program states belonging to the same group can be set identically or differently.

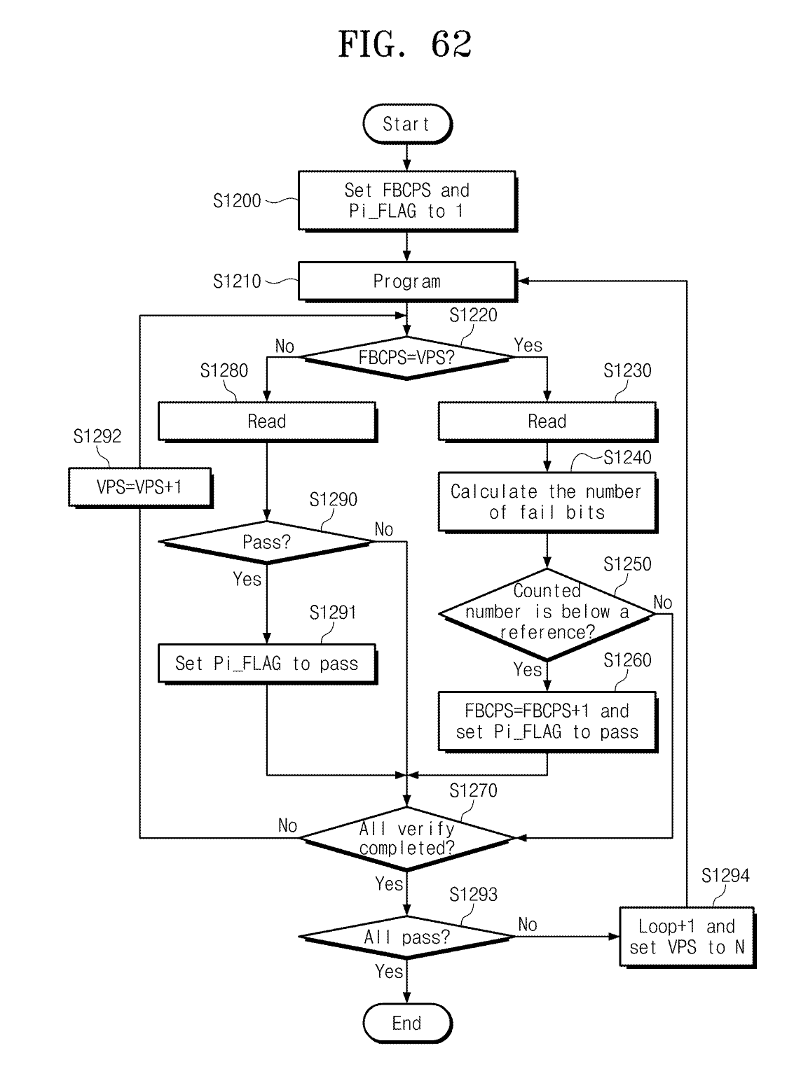

FIG. 62 is a flowchart illustrating a method of programming a flash memory device according to another embodiment of the inventive concept.

In the method of FIG. 62, variables FBCPS, VPS, and Pi_FLAG are set to ‘1’ in operation S1200. The variable FBCPS indicates a program state where a fail bit count is performed, and the variable VPS indicates a program state where a verification operation is performed. The variable Pi_FLAG is used to indicate the passed status of a program state where a verification operation has been performed.

A programming operation is performed in operation S1210. Operation S1210 corresponds to a programming execution section. Next, operation S1220 determines whether the value of the variable FBCPS is equal to the value of the variable VPS. Assuming that a current program loop is a first program loop, the value of the variable FBCPS is equal to the value of the variable VPS (S1220=Yes). Consequently, the method proceeds to operation S1230. In operation S1230, a verification operation is performed for program state P1, and the method proceeds to operation S1240.

Operation S1240 counts the number of fail bits among data bits that are read in a verification operation of program state P1. The counting of fail bits can be implemented in various ways. For example, the number of fail bits can be counted based on the amount of a current that flows in selected memory cells during a verification operation. Alternatively, the number of fail bits can be counted using a counter.

Next, in operation S1250, the method determines whether the counted number of fail bits is less than a predetermined reference value. Where the counted number of fail bits is less than the predetermined reference value (S1250=Yes), the method proceeds to operation S1260. Otherwise (S1250=No), the method proceeds to operation S1270. In operation S1250, the reference value is determined according to the error correction capability of an ECC unit of the memory controller. In operation S1260, the value of the variable FBCPS is increased by 1 and the variable Pi_FLAG is set to indicate a passed status. In other words, first program state P1 is determined to have a passed status, and consequently, a verification operation for program state P1 is omitted in successive program loops. Following operation, the method proceeds to operation S1270.

As indicated by the above description, where the number of fail bits among data bits corresponding to a program state is less than the predetermined reference value, a program state is determined to have a passed status. Consequently, verification operations of the program state can be omitted even where the data bits corresponding to the program state include the fail bits. The fail bits are slow bits. In other words, where the number of fail bits among the data bits corresponding to the program state is less than the predetermined reference value, a verification operation for a slow bit is omitted.

Returning to operation S1220, where the value of the variable FBCPS is not equal to that of the variable VPS (S1220=No), the method proceeds to operation S1280. Where the counted number of fail bits for program state P1 is greater than the reference value, the value of the variable FBCPS is not changed. In this case, assuming that a present verification operation is associated with a verification operation for second program state P2 or another higher program state, the value of the variable FBCPS, which indicates a program state where the number of fail bits has been counted, is not equal to the value of the variable VPS, which indicates a program state where the verification operation is performed.

In operation S1280, a verification operation is performed for a current program state corresponding to the value of the variable VPS, and the method proceeds to operation S1290. In operation S1290, the method determines whether all read data bits are passed data bits. Where all of the read data bits are passed data bits (S1290=Yes), the variable Pi_FLAG is set to indicate a passed status for the current program state, and the method proceeds to operation S1291. Otherwise (S1290=No), the method proceeds to operation S1270. In operation S1270, the method determines whether all verification operations for the program states have been performed. If not (S1270=No), the method proceeds to operation S1292. Otherwise (S1270=Yes), the method proceeds to operation S1293.

In operation S1292, the value of the variable VPS, which indicates a program loop where a verification operation is to be performed, is increased by 1, and the method returns to operation S1220. In operation S1293, the method determines whether all program states are passed. Where at least one of the program states is not passed (S1293=No), operation S1294 increases the value of a program loop by 1, and sets the variable VPS to ‘N’. In operation S1294, “N” has a value indicating a lowest program state among the program states that are not passed. Following operation S1294, the method returns to operation S1210. Where all the program states are determined as being passed (S1293=Yes), the method ends.

In certain embodiments, the method of FIG. 62 can be modified so that it determines, between operations S1230 and S1240, whether a program state is passed.

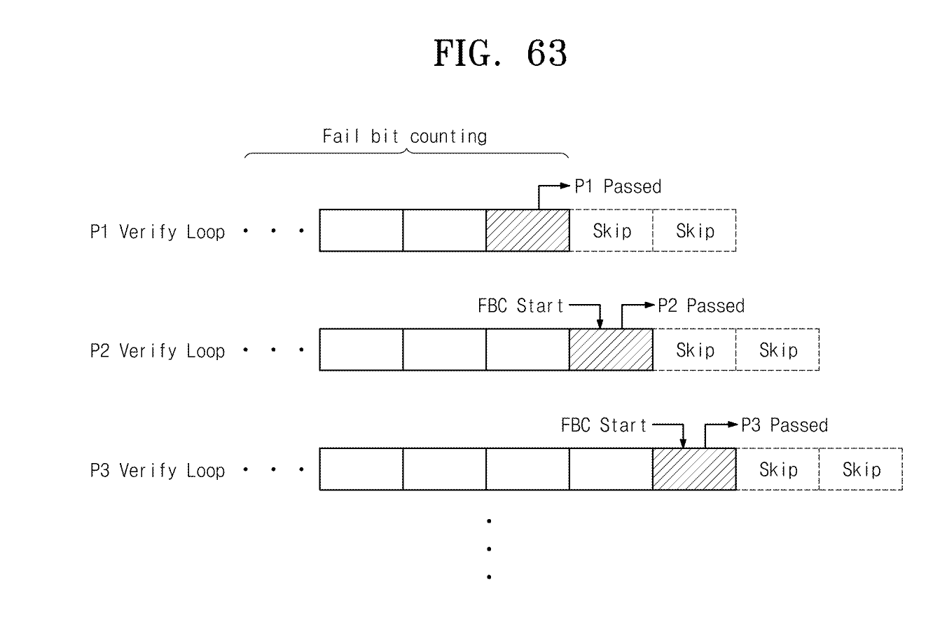

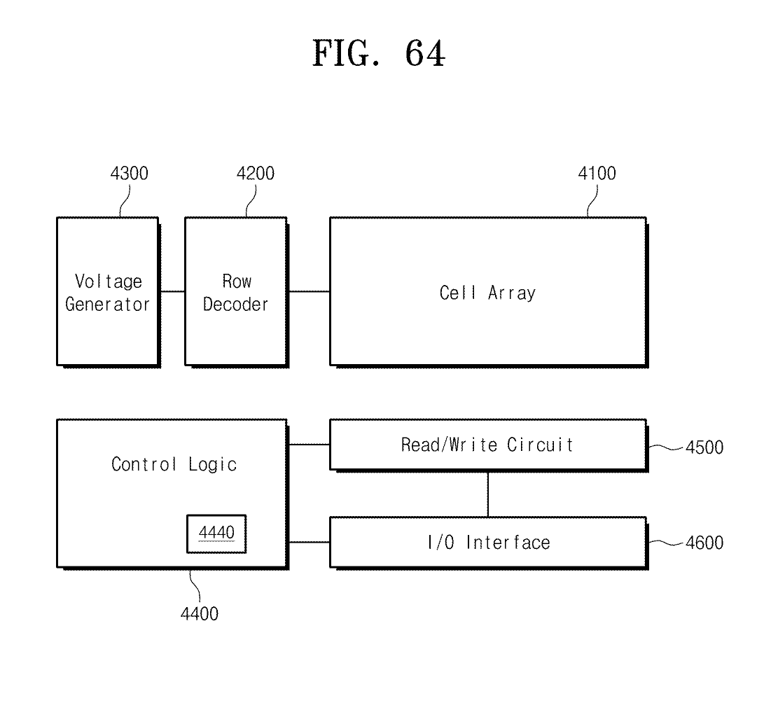

FIG. 63 is a diagram illustrating a verification scheme used in the method of FIG. 62 according to an embodiment of the inventive concept.

Referring to FIG. 63, a bit count operation for first program state P1 is performed until the number of fail bits becomes less than a predetermined reference value. At this point, a fail bit count operation for remaining program states is not performed. Once the number of fail bits of first program state P1 becomes less than the predetermined reference value, a verification operation for first program state P1 is ended, and a fail bit count operation for second program state P2 is started. At this point, a fail bit count operation is not performed for remaining program states (i.e., the upper program states of the second program state). Where the number of fail bits of second program state P2 becomes less than the predetermined reference value, a verification operation for second program state P2 is ended, and a fail bit count operation for third program state P3 is started. A fail bit count operation for remaining program states is determined through the substantially same scheme as shown in FIG. 63.

FIG. 64 is a block diagram illustrating a flash memory device capable of performing the method of FIG. 62.

The device of FIG. 64 is substantially the same the device of FIG. 43, except that that the device of FIG. 64 further comprises a circuit 4440 within control logic 4400 for counting the number of fail bits using current sensing. The counting of the number of fail bits is not limited to current sensing, and can be implemented using other techniques, such as a counter.

FIGS. 65A and 65B are flowcharts illustrating a method of programming a flash memory device according to another embodiment of the inventive concept.

In the example of FIGS. 65A and 65B, it is assumed that 3-bit data is stored in each memory cell using one erased state E and seven program states P1 through P7. In addition, the method of FIG. 65 can incorporate the scheme for determining the verification start point as described above with reference to FIG. 48 or FIG. 50 and the scheme for determining the verification end point as described above with reference to FIG. 58. Verification operations for fast bits can be skipped using verification start point determination, and verification operations for slow bits can be skipped through the verification end point determining scheme.

Referring to FIG. 65A, in operation S1300, upon initiation of a programming operation, a variable i_PGM_Loop is set as ‘1’, and variables P(j)_Verify_Start and P(j)_Verify_End are respectively set as maximum program loop times Max_PGM_Loop. The variable i_PGM_Loop indicates a current program loop, the variable P(j)_Verify_Start indicates a verification start point for a j-th program state, and the variable P(j)_Verify_End indicates a verification end point for a j-th program state. Next, in operation S1310, a programming operation is executed under the control of control logic 4400.

Thereafter, in operation S1320, upon completion of the programming operation, the method determines whether program state P1 is passed. Where the verification operation determines that program state P1 is not passed (S1320=No), the method proceeds to operation S1330.

In operation S1330, a verification operation is performed for program state P1 to determine whether at least one selected memory cell has been successfully programmed to program state P1. In other words, operation S1330 determines whether the selected memory cells include a pass bit.

Where a pass bit is detected during the verification operation of program state P1 (S1340=Yes), the method proceeds to operation S1350. Otherwise (S1340=No), the method proceeds to operation S1360.

Operation S1350 implements a method such as those described with reference to FIG. 48 and FIG. 50 to predict verification start points P(j)_Verify_Start of remaining program states P2 through P7 on the basis of a detected pass bit. In particular, operation S1350 comprises setting a variable ‘j’ to 2 in operation S1351; predicting a verification start point P(j)_Verify_Start of a j-th program state in operation S1352; determining whether ‘j’ has reached 7 indicating a most significant bit (MSB) program state P7 in operation S1353; and increasing ‘j’ by 1 where ‘j’ has not reached 7 (S1353=No) in operation S1354.

Verification start points can also be predicted according to the scheme that has been described above with reference to FIGS. 55 and 56. After the verification start points P(j)_Verify_Start of the remaining program states P2 through P7 are predicted in operation S1350, the method proceeds to operation S1360.

In operation S1360, the method determines whether program state P1 is passed. Upon determining that program state P1 is passed (S1360=Yes), the method proceeds to operation S1370. Otherwise (S1360=No), the method proceeds to operation S1380.

Operation S1370 uses a method similar to that described with reference to FIG. 58 to predict verification end points P(j)_Verify_End of the remaining program states P2 through P7. In particular, operation S1370 comprises setting ‘j’ to indicate program state P2 in operation S1371; predicting a verification end point P(j)_Verify_End of the j-th program state in operation S1372; determining whether ‘j’ has reached 7 in operation S1373; and increasing ‘j’ by 1 where ‘j’ has not reached 7 (S1373=No) in operation S1374. After the verification end points P(j)_Verify_End of the remaining program states P2 through P7 are predicted in operation S1370, the method proceeds to operation S1380.

In operation S1380, the method sets ‘j’ to 2 to indicate program state P2. Next, in operation S1390, the method determines whether a current program loop i_PGM_Loop is between the verification start point P(j)_Verify_Start and the verification end point P(j)_Verify_End of program state P(j). If so, the verification operation of program state P(j) is performed. Otherwise, the verification operation is omitted.

Where operation S1390 determines that the current program loop i_PGM_Loop is greater than or equal to the verification end point P(j)_Verify_End of program state P(j) or is less than or equal to the verification end point P(j)_Verify_End of program state P(j) (S1390=Yes), the method proceeds to operation S1400. Otherwise (S1390=No), the method proceeds to operation S1410.

In operation S1400, the method performs the verification operation of program state P(j) and proceeds to operation S1410. In operation S1410, the method determines whether ‘j’ has reached 7 indicating program state P7. Where ‘j’ has not reached 7 (S1410=No), ‘j’ is increased by 1 in operation S1420 and the method returns to operation S1390. Otherwise (S1410=Yes), the method proceeds to operation S1430. In operation S1430, the method determines whether all program states are passed. If not (S1430=No), operation S1440 is performed to increase variable i_PGM_Loop by 1. Otherwise (S1430=Yes), the method ends. After operation S1440, the method returns to operation S1310.

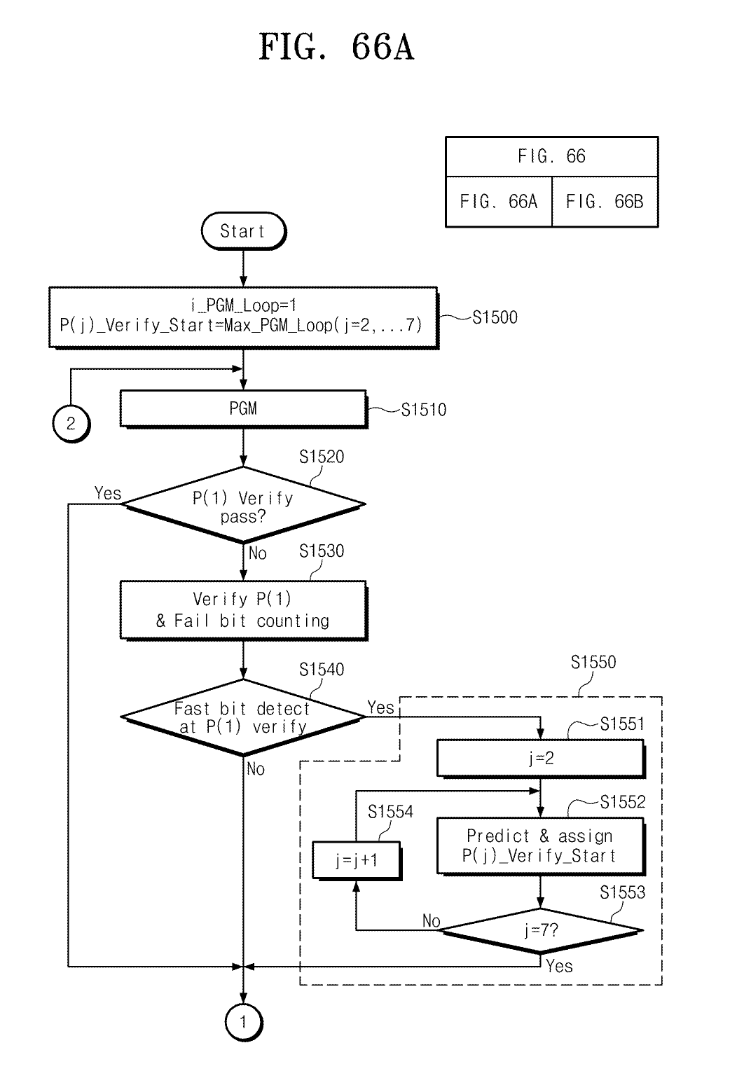

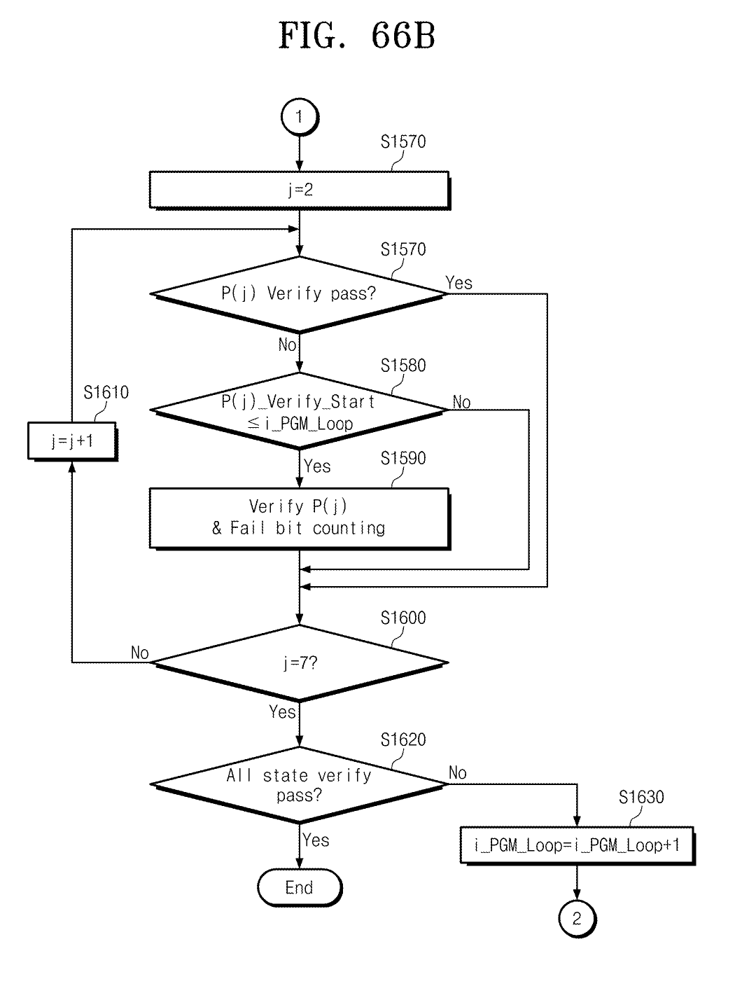

FIGS. 66A and 66B are flowcharts illustrating a method of programming a flash memory device according to another embodiment of the inventive concept.

In the method of FIGS. 66A and 66B, it is assumed that 3-bit data is stored in each memory cell using one erased state E and seven program states P1 through P7. In addition, the method of FIG. 66 can include the scheme for predicting verification start points as described above with reference to FIG. 48 or FIG. 50 and the scheme of predicting verification end points as described above with reference to FIG. 62. In the method of FIGS. 66A and 66B, verification operations for fast bits are skipped according to the verification start point predicting scheme, and verification operations for slow bits are skipped according to the verification end point predicting scheme.

Referring to FIG. 66A, operation S1500 is performed upon initiation of a programming operation to set a variable i_PGM_Loop is to ‘1’, and to set variables P(j)_Verify_Start and P(j)_Verify_End as maximum program loop times Max_PGM_Loop. The variable i_PGM_Loop indicates a current program loop, and the variable P(j)_Verify_Start indicates a verification start point for a j-th program state. Next, in operation S1510, a programming operation is executed under the control of control logic 4400.

After the programming operation, operation S1520 determines whether program state P1 is passed. Where program state P1 is not passed (S1520=No), the method proceeds to operation S1530. Otherwise (S1520=Yes), the method proceeds to operation S1560. In operation S1530, the method performs a verification operation for program state P1 and determines the number of fail bits for program state P1. As described above with reference to FIG. 62, where the number of fail bits for program state P1 is less than or equal to a reference value, program state P1 is set as being passed.

Next, in operation S1540, the method determines whether at least one pass bit (i.e., a fast bit) is detected during the verification operation of program state P1. Where a pass bit is detected (S1540=Yes), the method proceeds to operation S1550. Otherwise (S1540=No), the method proceeds to operation S1560. Operation S1560 comprises operations similar to those described above with reference to FIG. 48 or FIG. 50, in which the verification start points P(j)_Verify_Start of remaining program states P2 through P7 are predicted on the basis of a detected pass bit. Accordingly, operation S1550 comprises setting a variable ‘j’ to 2 in operation S1551; predicting a verification start point P(j)_Verify_Start of a j-th program state in operation S1552; determining whether ‘j’ has reached 7 in operation S1553; and increasing ‘j’ by 1 where ‘j’ has not reached 7 (S1553=No) in operation S1554. Verification start points can be predicted according to the scheme that has been described above with reference to FIGS. 55 and 56. After the verification start points P(j)_Verify_Start of the remaining program states P2 through P7 are predicted in operation S1550, the method proceeds to operation S1560.

In operation S1560, the method sets ‘j’ to 2 to indicate program state P2. Then, in operation S1570, the method determines whether program state P(j) is passed. Where program state P(j) is not passed (S1570=No), the method proceeds to operation S1580. Otherwise (S1570=Yes), the method proceeds to operation S1600. In operation S1580, the method determines whether the predicted verification start point of program state P(j) is less than or equal to a current program loop i_PGM_Loop. Where the current program loop i_PGM_Loop is less than the verification start point P(j)_Verify_Start of program state P(j), the verification operation of program state P(j) is omitted. Where the current program loop i_PGM_Loop is greater than the verification start point P(j)_Verify_Start of program state P(j), the verification operation of program state P(j) is performed.

Where the current program loop i_PGM_Loop is greater than or equal to the verification start point P(j)_Verify_Start of program state P(j), the method proceeds to operation S1590. In operation S1590, a verification operation is performed for program state P(j) and the number of fail bits for program state P(j) is counted. As described above with reference to FIG. 62, where the number of fail bits for program state P(j) is less than or equal to a reference value, program state P(j) is set as being passed. In other embodiments, as described above with reference to FIG. 62, a fail bit detecting operation for program state P(j) is performed after program state P1 is passed. Following operation S1590, the method proceeds to operation S1600.

In operation S1600, the method determines whether ‘j’ has reached 7 indicating program state P7. Where ‘j’ has not reached 7 (S1600=No), ‘j’ is increased by 1 in operation S1610. Otherwise (S1600=Yes), the method proceeds to operation S1620.

In operation S1620, the method determines whether all of program states P1 through P7 are passed. If so (S1620=Yes), the method ends. Otherwise (S1620=No), operation S1630 is performed to increase the variable i_PGM_Loop by 1, and the method returns to operation S1510.

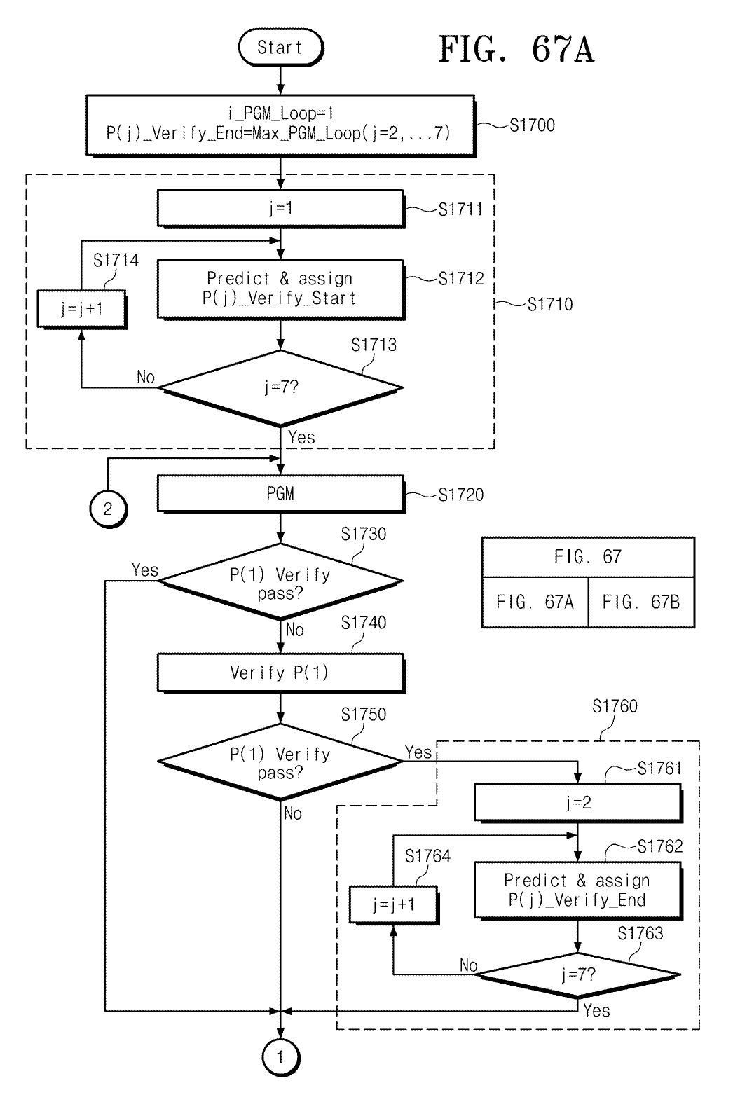

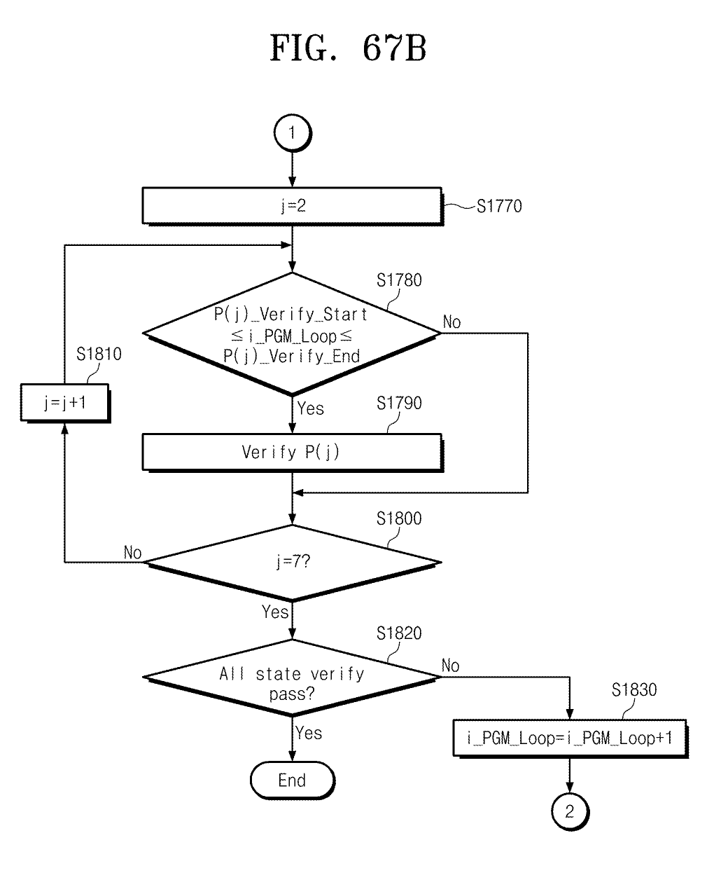

FIGS. 67A and 67B are flowcharts illustrating a method of programming a flash memory device according to still another embodiment of the inventive concept.

In the method of FIGS. 67A and 67B, it is assumed that 3-bit data is stored in each memory cell using one erased state E and seven program states P1 through P7. In addition, the method of FIGS. 67A and 67B use the scheme for predicting the verification start point as described above with reference to FIG. 52 and the scheme for predicting the verification end point as described above with reference to FIG. 58. A verification operation for fast bits can be skipped according to the verification start point predicting scheme, and a verification operation for slow bits can be skipped according to the verification end point predicting scheme.

Referring to FIG. 67A, upon initiation of a programming operation, operation S1700 is performed to set a variable i_PGM_Loop to ‘1’, and to set variables P(j)_Verify_Start and P(j)_Verify_End as maximum program loop times Max_PGM_Loop. The variable i_PGM_Loop is used to indicate a current program loop, and the variable P(j)_Verify_End is used to indicate a verification end point for a j-th program state. Next, in operation S1710, the verification start points of program states P1 through P7 are predicted on the basis of pass bit information (e.g., a program voltage or a program loop) from a previous page or previous step programming operation. In particular, operation S1710 comprises setting a variable ‘j’ to 1 in operation S1711; predicting a verification start point of program state P(j) in operation S1712; determining whether ‘j’ has reached 7 indicating program state P7 in operation S1713; increasing ‘j’ by 1 where ‘j’ has not reached 7 (S1713=No) in operation S1714. Where ‘j’ has reached 7 (S1713=Yes), the method proceeds to operation S1720. In operation S1720, a programming operation is performed under the control of control logic 4400.

After the programming operation, operation S1730 determines whether program state P1 is passed. Where program state P1 is not passed (S1730=No), a verification operation is performed for program state P1 in operation S1740. Otherwise (S1730=Yes), the method proceeds to operation S1770.

In operation S1750, the method determines whether program state P1 is passed. Where program state P1 is passed (S1750=Yes), the method proceeds to operation S1760. Otherwise (S1750=No), the method proceeds to operation S1770.

Operation S1760 is performed similar to the method of FIG. 58, in which the verification end points P(j)_Verify_End of remaining program states P2 through P7 are predicted. In particular, operation S1760 comprises setting ‘j’ to 2 in operation S1761; predicting a verification end point P(j)_Verify_End of a j-th program state in operation S1762; determining whether ‘j’ has reached 7 in operation S1763; and increasing ‘j’ by 1 in operation S1764 if ‘j’ has not reached 7 (S1763=No). After the verification end points P(j)_Verify_End of the remaining program states P2 through P7 are predicted in operation S1760, the method proceeds to operation S1770.

In operation S1770, ‘j’ is set to 2 to indicate program state P2. Then, in operation S1780, the method determines whether a current program loop i_PGM_Loop is between the verification start point P(j)_Verify_Start of program state P(j) and the verification end point P(j)_Verify_End of program state P(j). If so, the verification operation of program state P(j) is performed in the current program loop. Otherwise, it is omitted. Where operation S1780 determines that the current program loop i_PGM_Loop is greater than or equal to the verification start point P(j)_Verify_Start of program state P2 and less than or equal to the verification end point P(j)_Verify_End of program state P2 (S1780=Yes), the method proceeds to operation S1790. Otherwise, the method proceeds to operation S1800. In operation S1790, the verification operation of program state P2 is performed, and the method proceeds to operation S1800.

Operation S1800 determines whether ‘j’ has reached 7 indicating program state P7. Where ‘j’ has not reached 7 (S1800=No), ‘j’ is increased by 1 in operation S1810, and the method returns to operation S1780. Otherwise (S1800=Yes), the method proceeds to operation S1820. Operation S1820 determines whether the all program states are passed. Where not all program states are passed (S1820=No), operation S1830 is performed to increase the variable i_PGM_Loop by 1, and the method then returns to operation S1720. Otherwise (S1820=Yes), the method ends.

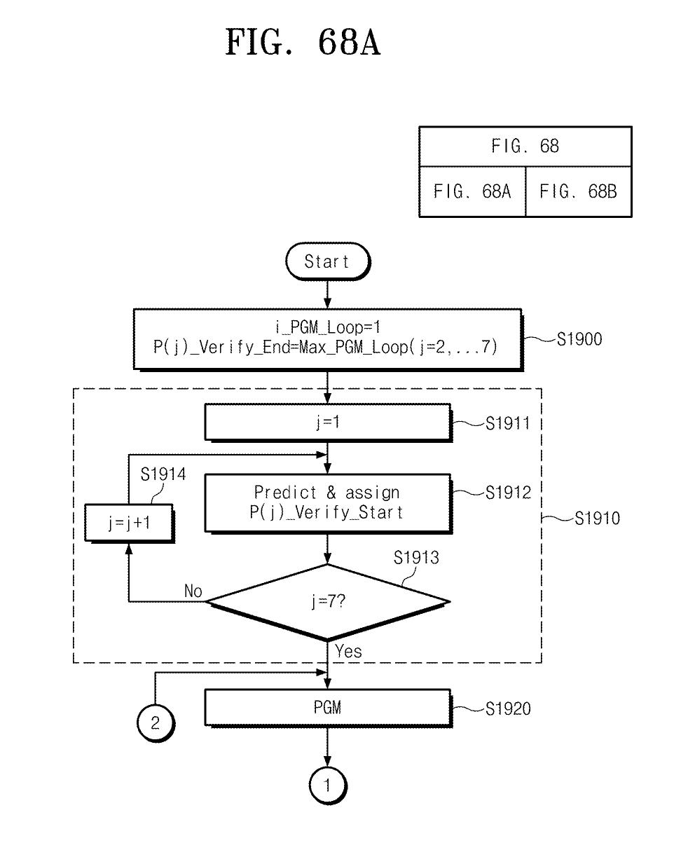

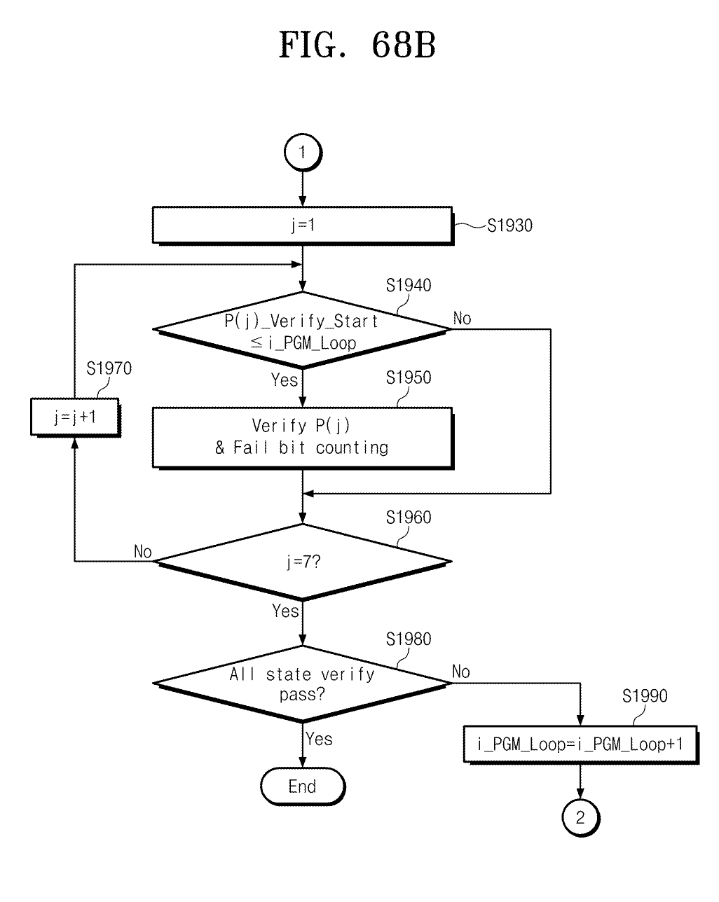

FIGS. 68A and 68B are flowcharts illustrating a method of programming a flash memory device according to yet another embodiment of the inventive concept.

In the method of FIGS. 68A and 68B, it is assumed that 3-bit data is stored in each memory cell using one erased state E and seven program states P1 through P7. In addition, the method of FIGS. 68A and 68B can use the scheme for predicting the verification start point as described above with reference to FIG. 52 and the scheme for predicting the verification end point as described above with reference to FIG. 62. A verification operation for fast bits is skipped according to the verification start point predicting scheme, and a verification operation for slow bits is skipped according to the verification end point predicting scheme.

Referring to FIG. 68A, operation S1900 is performed upon initiation of a programming operation. Operation S1900 sets a variable i_PGM_Loop to ‘1’, and sets variables P(j)_Verify_Start and P(j)_Verify_End as maximum program loop times Max_PGM_Loop. The variable i_PGM_Loop indicates a current program loop, and the variable P(j)_Verify_End indicates a verification end point for a j-th program state. Next, in operation S1910, the verification start points of the program states (e.g., P1 through P7) are predicted on the basis of pass bit information (e.g., a program voltage or a program loop) that is detected in a previous page or step programming operation. More specifically, operation S1910 comprises setting a variable ‘j’ as 1 in operation S1911; predicting a verification start point of program state P2 in operation S1912; determining whether ‘j’ has reached 7 indicating program state P7 in operation S1913; and increasing ‘j’ by 1 where ‘j’ has not reached 7 (S1913=No) in operation S1914. Where ‘j’ has reached 7 (S1913=Yes), the method proceeds to operation S1920.

In operation S1920, a programming operation is performed on selected memory cells. Then, in operation S1930, ‘j’ is set to 1. Next, in operation S1940, the method determines whether the predicted verification start point of program state P1 is less than or equal to a current program loop i_PGM_Loop. Where the current program loop i_PGM_Loop is less than the verification start point P(j)_Verify_Start of program state P1, the verification operation of program state P1 is omitted. Where the current program loop i_PGM_Loop is greater than or equal to the verification start point P(j)_Verify_Start of program state P1, the verification operation of program state P2 is performed.

Where the current program loop i_PGM_Loop is greater than or equal to the verification start point P(j)_Verify_Start of program state P1 (S1940=Yes), the method proceeds to operation S1950. Otherwise (S1940=No), the method proceeds to operation S1960.

In operation S1950, a verification operation is performed for program state P1 and the number of fail bits for program state P1 is counted. Like the method of FIG. 62, where the number of fail bits for program state P1 is less than or equal to a reference value, program state P1 is deemed to be passed. Following operation S1950, the method proceeds to operation S1960.

In operation S1960, the method determines whether T has reached a value of 7 indicating program state P7. Where ‘j’ has not reached 7 (S1960=No), operation S1970 is performed to increase ‘j’ by 1, and the method returns to operation S1940. Otherwise, (S1960=Yes), the method proceeds to operation S1980. In operation S1980, the method determines whether all of program states P1 through P7 are passed. Where not all of program states are passed (S1980=No), the variable i_PGM_Loop is increased by 1 in operation S1990 and the method returns to operation S1920. Otherwise (S1980=Yes), the method ends.

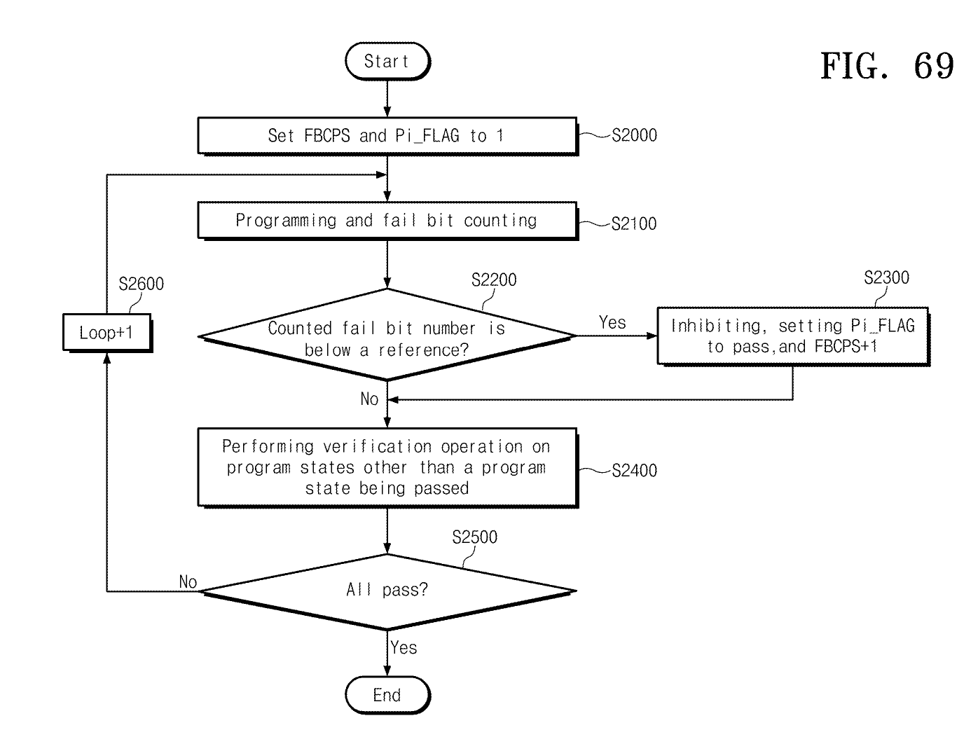

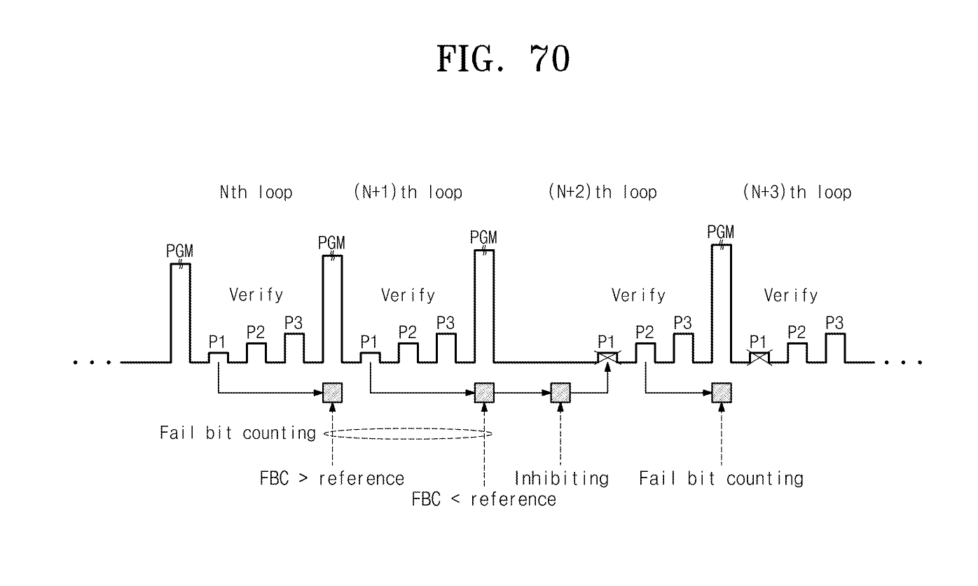

FIG. 69 is a flowchart illustrating a method of programming a flash memory device according to yet another embodiment of the inventive concept.

First of all, in operation S2000, variables FBCPS and Pi_FLAG are set to ‘1’. The variable FBCPS indicates a program state where a fail bit count operation is performed, and the variable Pi_FLAG is used to indicate the passed status of a program state where a verification operation has been performed.

A programming operation is performed in operation S2100. Further, in operation S2100, fail bit counting on a program state corresponding to a value of the variable FBCPS may be made. Assuming that a current program loop is a first program loop, the fail bit counting may be made with respect to a first program state P1. Since a current program is a first program loop, the fail bit counting may be made based on program data bits stored in a read/write circuit 4500 (refer to FIG. 43). If a current program loop is a second program loop, the fail bit counting may be made based on data bits read at a verification operation of a previous program loop.

In operation S2200, there is checked whether the counted fail bit number is less than a predetermined reference value. If the counted fail bit number is less than the predetermined reference value, the method proceeds to operation S2300. In operation S2300, fail bits corresponding to the program state P1 are set to a program-inhibit value (for example, ‘1’). This means that memory cells corresponding to the program state P1 are program inhibited at a next program loop although a program voltage is applied to the memory cells of fail bits corresponding to the program state P1. Further, in operation S2300, the variable Pi_FLAG is set to indicate a pass status, and the variable FBCPS is increased by 1. As the variable FBCPS is increased, fail bit counting may be made with respect to a next program state P2, instead of the program state P1. Where the variable Pi_FLAG is set to indicate a pass status, a verification operation is omitted with respect to a program state (for example, P1) corresponding to a value of the variable Pi_FLAG. Afterwards, the method proceeds to operation S2400.

Returning to operation S2200, if the counted fail bit number is not less than the predetermined reference value, the method proceeds to operation S2400. In operation S2400, a verification operation is performed with respect to program states other than a program state being passed, respectively. For example, in the event that P1_FLAG is set to a pass status, a verification operation is performed with respect to remaining program states other than a program state P1 corresponding to the P1_FLAG, respectively. Where no program state being passed exists, a verification operation is performed with respect to all program states in operation S2400, respectively.

Operation S2500 determines whether all program states are passed. If at least one program state is not passed, the method proceeds to operation S2600, in which a program loop number is increased by 1. Afterwards, the method proceeds to operation S2100. Where all program states are passed, the method ends.

With the above-described method, a fail bit count operation is performed using a verification result of a previous program loop while a programming operation is being performed at a current program loop (or, while a program voltage is being applied to a selected word line). For this reason, although a counted fail bit number is determined to be less than a predetermined reference value, a program voltage is applied once more to memory cells corresponding to fail bits at the current program loop. As a result, that the number of fail bits corresponding to a program state to be omitted (or, skipped) is decreased.

In an exemplary embodiment, the same reference value is utilized with respect to all program states in order to judge whether each program state is passed. But, it is possible to apply different reference values to program states (or, pages in each row) in order to judge whether corresponding program states are passed.

FIG. 70 is a diagram illustrating a verification scheme used in the method of FIG. 69 according to an embodiment of the inventive concept.

As described above, a bit count operation on a first program state P1 is performed until the number of fail bits (or, called slow bits) becomes less than a predetermined reference value. At this point, a fail bit count operation on remaining program states is not performed. A bit counting operation on a program state corresponding to a variable FBCPS is performed during a programming operation in which a program voltage is applied to selected memory cells.

For example, as illustrated in FIG. 70, a verification operation is performed with respect to program states P1, P2, and P3 at an Nth program loop. A fail bit count operation on the program state P1 is performed during a programming operation of a (N+1)th program loop, based on data bits corresponding to the program state P1 read at a verification operation of the Nth program loop. If a counted fail bit number FBC is more than a predetermined reference value, a fail bit count operation on the program state P1 is again performed during a programming operation of a (N+2)th program loop. If the counted fail bit number FBC is determined to be less than the predetermined reference value at the (N+2)th program loop, fail bits among data bits corresponding to the program state P1 are set to a program-inhibit value, and a verification operation on the program state P1 is omitted after the following program loops including a current program loop (for example, the (N+2)th program loop). When the program state P1 is passed, as illustrated in FIG. 70, a fail bit count operation is performed with respect to a next program state P2.

As understood from the above description, a program voltage is applied to memory cells corresponding to fail bits once more after a counted fail bit number is determined to be less than a predetermined reference value. This means that the number of fail bits corresponding to a program state to be omitted (or, skipped) is decreased.

In an exemplary embodiment, in case of the highest program state, if a counted fail bit number is determined to be less than a predetermined reference value, it is possible to prevent a further program voltage from being applied to memory cells corresponding to fail bits.

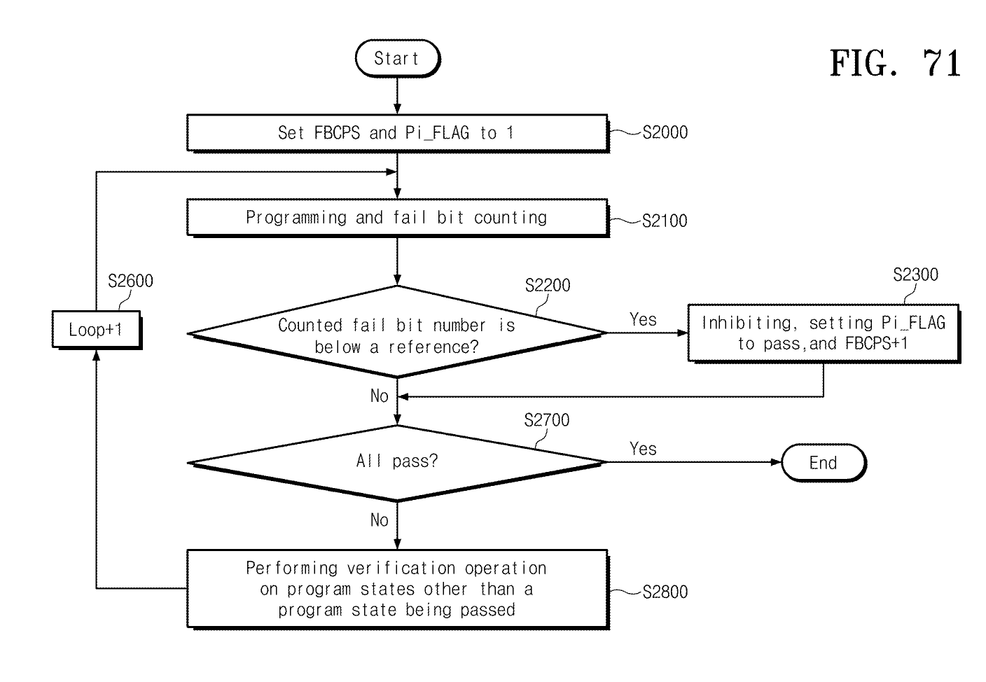

FIG. 71 is a flowchart illustrating a method of programming a flash memory device according to yet another embodiment of the inventive concept.

A program method in FIG. 71 is substantially identical to that illustrated in FIG. 69 except that step S2700 of judging whether all program states are passed can be made before step S2800 of performing verification operation on program states other than a program state being passed. Description for a program method in FIG. 71 is thus omitted.

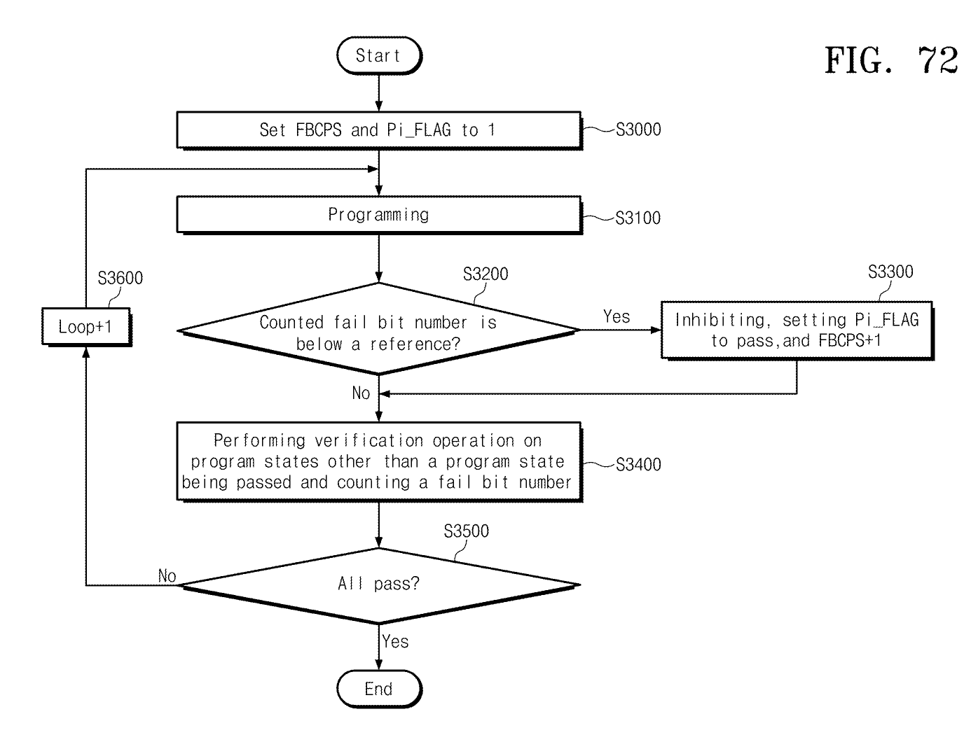

FIG. 72 is a flowchart illustrating a method of programming a flash memory device according to yet another embodiment of the inventive concept.

First of all, in operation S3000, variables FBCPS and Pi_FLAG are set to ‘1’. The variable FBCPS indicates a program state where a fail bit count operation is performed, and the variable Pi_FLAG is used to indicate the passed status of a program state where a verification operation has been performed.

A programming operation is performed in operation S3100. In operation S3200, there is checked whether a counted fail bit number is less than a predetermined reference value. As will be described later, the counted fail bit number is maintained by control logic 4400 in FIG. 43. As a fail bit number of a previous program loop, for example, the counted fail bit number may be set to a default value more than a predetermined reference value. If the counted fail bit number is less than the predetermined reference value, the method proceeds to operation S3300. In operation S3300, fail bits corresponding to the program state P1 are set to a program-inhibit value (for example, ‘1’). This means that memory cells corresponding to the program state P1 are program inhibited at a next program loop although a program voltage is applied to the memory cells of fail bits corresponding to the program state P1. Further, in operation S3300, the variable Pi_FLAG is set to indicate a pass status, and the variable FBCPS is increased by 1. As the variable FBCPS is increased, a fail bit counting may be made with respect to a next program state P2, instead of the program state P1. Where the variable Pi_FLAG is set to indicate a pass status, a verification operation is omitted with respect to a program state (for example, P1) corresponding to a value of the variable Pi_FLAG. Afterwards, the method proceeds to operation S3400.

Returning to operation S3200, if the counted fail bit number is not less than the predetermined reference value, the method proceeds to operation S3400. In operation S3400, a verification operation is performed with respect to program states other than a program state being passed, respectively. For example, in the event that P1_FLAG is set to a pass status, a verification operation is performed with respect to remaining program states other than a program state P1 corresponding to the P1_FLAG, respectively. Where no program state being passed exists, a verification operation is performed with respect to all program states in operation S3400, respectively. Further, in operation S3400, a fail bit count operation is performed on a program state corresponding to the variable FBCPS. The counted fail bit number is stored in the control logic 4400. The counted fail bit number is used as a fail bit number of a previous program loop in operation S3200.

Operation S3500 determines whether all program states are passed. If at least one program state is not passed, the method proceeds to operation S3600, in which a program loop number is increased by 1. Afterwards, the method proceeds to operation S3100. Where all program states are passed, the method ends.

With the above-described method, a verification operation on a program state is omitted using a verification result of a previous program loop after a programming operation is performed at a current program loop. For this reason, although a counted fail bit number is determined to be less than a predetermined reference value, a program voltage is further applied to memory cells corresponding to fail bits at the current program loop. As a result, that the number of fail bits corresponding to a program state to be omitted (or, skipped) is decreased.

In an exemplary embodiment, the same reference value is utilized with respect to all program states in order to judge whether each program state is passed. But, it is possible to apply different reference values to program states (or, pages in each row) in order to judge whether corresponding program states are passed.

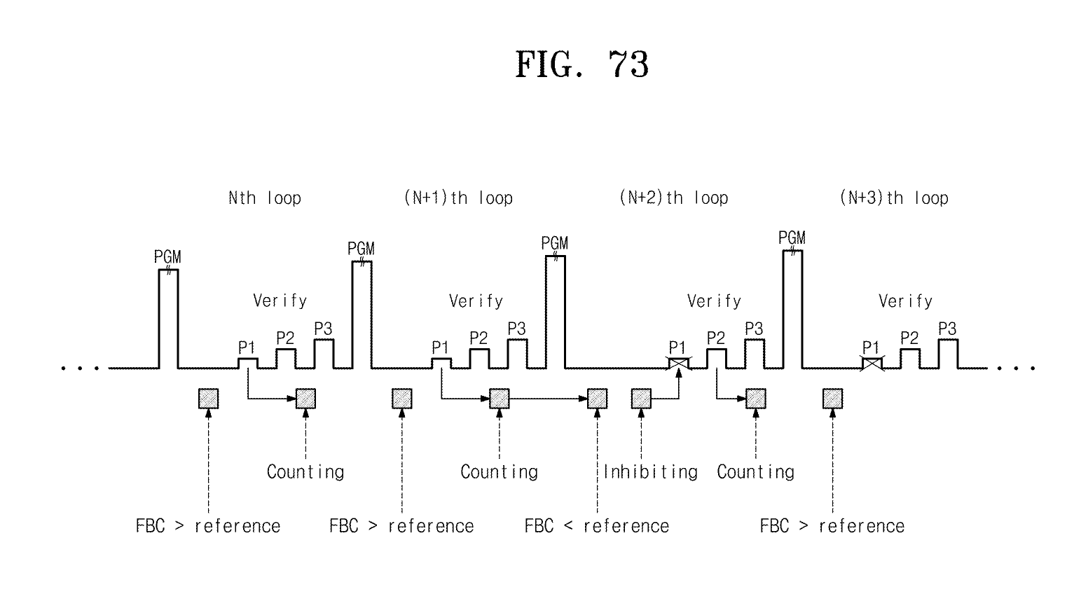

FIG. 73 is a diagram illustrating a verification scheme used in the method of FIG. 71 according to an embodiment of the inventive concept.

As described above, a bit count operation on a first program state P1 is performed until the number of fail bits (or, called slow bits) becomes less than a predetermined reference value. At this point, a fail bit count operation on remaining program states is not performed. A bit counting operation on a program state corresponding to a variable FBCPS is performed during a programming operation in which a program voltage is applied to selected memory cells.

For example, first of all, a program voltage is applied to selected memory cells. And then, as illustrated in FIG. 73, whether a fail bit number is less than a predetermined reference value is checked before a verification operation is performed. If the fail bit number is not less than the predetermined reference value, a verification operation is performed with respect to program states P1, P2, and P3 at an Nth program loop. A fail bit count operation on the program state P1 is performed during the Nth program loop, based on data bits corresponding to the program state P1 read at a verification operation of the Nth program loop. The counted fail bit number may be retained by control logic 4400 in FIG. 43.

If a (N+1)th program loop is performed, a program voltage is applied to selected memory cells. And then, whether a fail bit number is less than a predetermined reference value is checked before a verification operation of the (N+1)th program loop is performed. The counted fail bit number may be retained by the control logic 4400 in FIG. 43.

If the counted fail bit number FBC is determined to be less than the predetermined reference value at the (N+2)th program loop, fail bits among data bits corresponding to the program state P1 are set to a program-inhibit value, and a verification operation on the program state P1 is omitted after the following program loops including a current program loop (for example, the (N+2)th program loop). As the program state P1 is passed, as illustrated in FIG. 73, a fail bit count operation is performed with respect to a next program state P2.

As understood from the above description, a program voltage is applied to memory cells corresponding to fail bits once more after a counted fail bit number is determined to be less than a predetermined reference value. This means that the number of fail bits corresponding to a program state to be omitted (or, skipped) is decreased.

In an exemplary embodiment, in case of the highest program state, if a counted fail bit number is determined to be less than a predetermined reference value, it is possible to prevent a further program voltage from being applied to memory cells corresponding to fail bits.

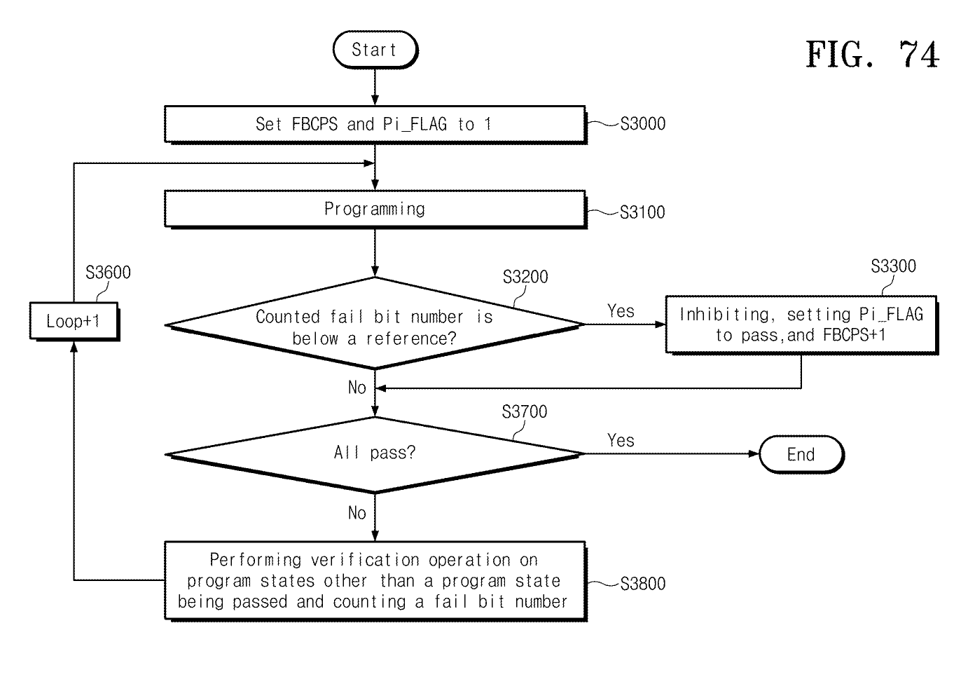

FIG. 74 is a flowchart illustrating a method of programming a flash memory device according to yet another embodiment of the inventive concept.

A program method in FIG. 74 is substantially identical to that illustrated in FIG. 72 except that operation S3700 of judging whether all program states are passed can be made before operation S3800 of performing verification operation on program states other than a program state being passed. Description for a program method in FIG. 74 is thus omitted.

As described in FIGS. 58 to 63 and 69 to 72, there is omitted (or, skipped) a verification operation for a program state determined to be passed. This means that although a program voltage is applied to a word line, memory cells corresponding to the program state(s) determined to be passed are program inhibited. In other words, program Inhibiting of memory cells corresponding to a slow bit (or a fail bit) may be made in two manners: the first program inhibiting manner being described in FIGS. 58 to 63 and the second program inhibiting manner being described in FIGS. 69 to 72.

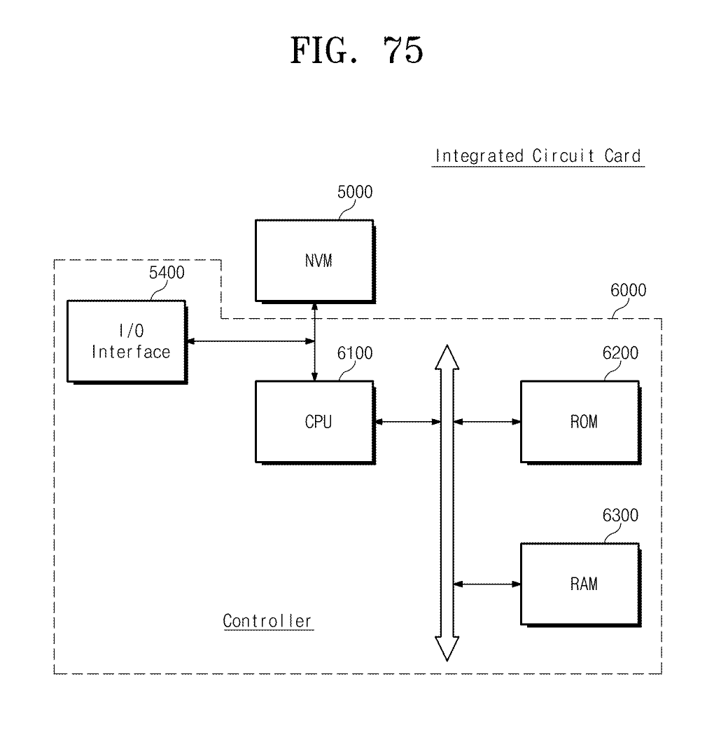

FIG. 75 is a block diagram illustrating an integrated circuit card comprising a flash memory device according to an embodiment of the inventive concept.

Referring to FIG. 75, an integrated circuit, such as a smart card, comprises a nonvolatile memory device 4500 and a controller 4600. Nonvolatile memory device 4500 is the substantially same as that illustrated in FIG. 43, and so a detailed description thereof will be omitted in order to avoid redundancy. Controller 4600 controls nonvolatile memory device 4500 and comprises a central processing unit (CPU) 6100, a read only memory (ROM) 6200, a random access memory (RAM) 6300, and an input/output (I/O) interface 6400. CPU 6100 controls the overall operation of the integrated circuit card according to various programs stored in ROM 6200, and input/output interface 6400 interfaces with external devices. Controller 4600 stores information indicating a pass bit that is detected during the programming operation of nonvolatile memory device 4500 and provides the information indicating the detected pass bit to nonvolatile memory device 4500. The information can be used to determine verification start points in one or more of the above-described methods.

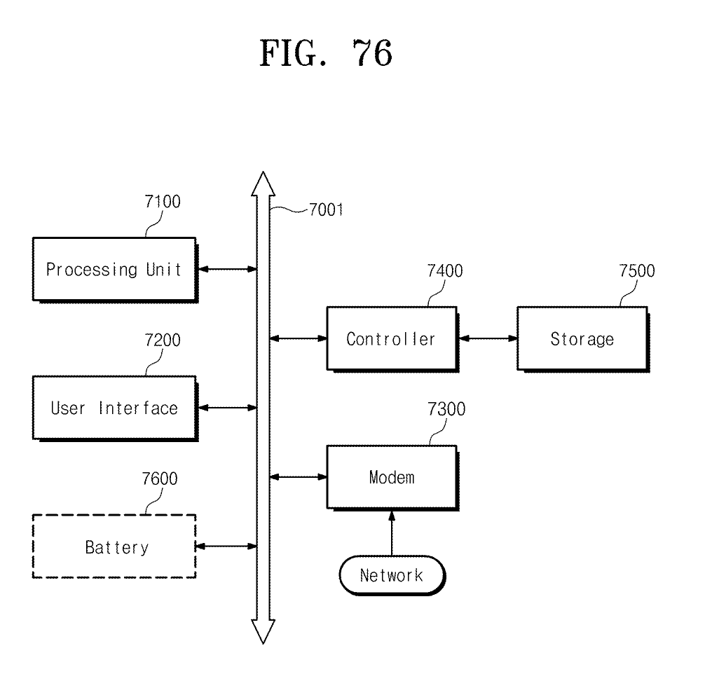

FIG. 76 is a diagram illustrating a computing system comprising a flash memory device according to an embodiment of the inventive concept. The computing system can take a variety of forms, such as a cellular phone, personal digital assistant, digital camera, portable game console, MP3 player, high definition television, digital video disk, router, global positioning system (GPS), and many others.

Referring to FIG. 76, the computing system comprises a processing unit 7100, a user interface 7200, a modem 7300 such as a baseband chipset, a memory controller 7400, and a flash memory device 7500, which are electrically connected to each other via a bus 7001. Flash memory device 7500 is substantially the same as the flash memory device of FIG. 43 and performs a programming operation using an adaptive verification scheme, such as those described above. Accordingly, a further description of flash memory device 7500 will be omitted to avoid redundancy. N-bit data (N≧1), which has been processed or is to be processed by processing unit 7100, is stored in flash memory device 7500 through memory controller 7400. Where the computing system is a mobile device, it may further comprise a battery 7600 for supplying the operation voltage of the computing system. Although not shown, the computing system can further comprise an application chipset, a camera image processor (CIS), or a mobile dynamic random access memory (DRAM). The memory controller and the flash memory device can form a solid state drive (SSD) that uses a nonvolatile memory for storing data.

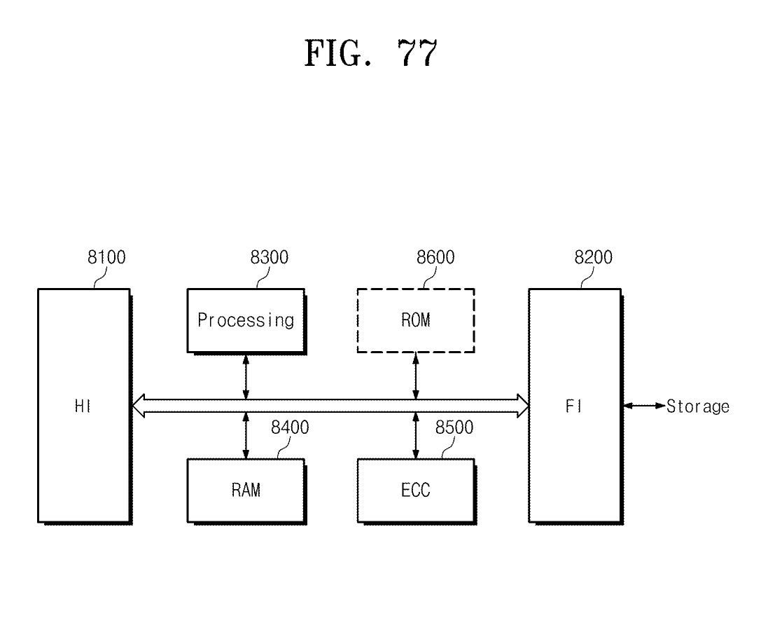

FIG. 77 is a block diagram illustrating memory controller 7400 of FIG. 74 according to an embodiment of the inventive concept.

Referring to FIG. 77, memory controller 7400 stores data in a storage medium and reads data from the storage medium. The controller comprises a host interface 8100, a memory interface 8200, a processing unit 8300, a buffer memory 8400, and an error correction code unit 8500. Host interface 8100 interfaces with external devices, such as a host, and memory interface 8200 interfaces with the storage medium. Processing unit 8300 controls the overall operation of memory controller 7400. Buffer memory 8400 temporarily stores data to be stored in the storage medium or data that is read from the storage medium. Buffer memory 8400 can also be used as the working memory of processing unit 8300. Buffer memory 8400 can be used to store pass bit information that is output from a flash memory device. Error correction code unit 8500 detects and corrects errors in data that is read from the storage medium. Memory controller 7400 further comprises a ROM 8600 for storing code data.

In some embodiments, memory cells are configured with variable resistance memory cells. Examples of variable resistance memory cells and memory devices including variable resistance memory cells are disclosed in U.S. Pat. No. 7,529,124, which is hereby incorporated by reference.

In some embodiments, memory cells are implemented using one of various cell structures having a charge storage layer. A cell structure having a charge storage layer can include, for instance, a charge trapping flash structure using a charge trapping layer, a stack flash structure comprising arrays stacked in multi layers, a flash structure having no source-drain, and a pin-type flash structure. Examples of memory devices having a charge trapping flash structure as a charge storage layer are disclosed in U.S. Pat. No. 6,858,906, U.S. Patent Publication No. 42004-0169238, and U.S. Patent Publication No. 42006-0180851, which are hereby incorporated by reference. An example of a flash structure having no source-drain is disclosed in Korea Patent No. 673,020, which is hereby incorporated by reference.

Devices according to various embodiments of the inventive concept can be mounted in any of several types of packages. For example, the above-described flash memory devices and/or memory controllers can be mounted in package types such as package on package (PoP), ball grid arrays (BGAs), chip scale package (CSP), plastic leaded chip carrier (PLCC), plastic dual in-line package (PDIP), die in waffle pack (DIWP), die in wafer form (DIWF), chip on board (COB), ceramic dual in-line package (CERDIP), plastic metric quad flat pack (MQFP), small outline package (SOP), shrink small outline package (SSOP), thin small outline package (TSOP), thin quad flat pack (TQFP), system in package (SIP), multi-chip package (MCP), wafer-level stack package (WLSP), die in wafer form (DIWF), die on waffle package (DOWP), wafer-level fabricated package (WFP) and wafer-level processed stack package (WSP).

As indicated by the foregoing, in various embodiments of the inventive concept, by omitting verification operations before verification start points corresponding to programming states, programming performance can be improved. Moreover, by omitting verification operations after verification end points of programming states, programming performance can be improved.

While example embodiments have been particularly shown and described, it will be understood by one of ordinary skill in the art that variations in form and detail may be made therein without departing from the spirit and scope of the claims.

What is claimed is:

1. A method of programming a nonvolatile memory device including a plurality of memory cells connected with a plurality of word lines and a plurality of bit lines, the method comprising:
performing a first program loop according to program data loaded in page buffers;
wherein the first program loop includes:
applying a first program voltage to a selected word line among the plurality of word lines;
applying a first verify voltage to the selected word line; and
storing a first verify result related with first memory cells targeted to a first program state which is verified using the first verify voltage;
performing a second program loop according to the program data loaded in the page buffers,
wherein the second program loop includes:
applying a second program voltage to the selected word line,
wherein a program pass or a program fail of the first program state is checked based on the first verify result during applying the second program voltage,
wherein when the first program state is program failed, the second program loop further includes:
applying the first verify voltage to the selected word line; and
storing the first verify result,
wherein when the first program state is program passed, the first verify voltage is not applied to the selected word line at the second program loop.
